(19) United States
(12) Patent Application Publication
(10) Pub. No.: US 2013/0089821 A1
(43) Pub. Date: Apr. 11, 2013

(54) RESIST PATTERN FORMATION METHOD AND PATTERN MINIATURIZATION AGENT

(71) Applicant: Isao Hirano, Kawasaki-shi (JP)

(72) Inventor: Isao Hirano, Kawasaki-shi (JP)

(73) Assignee: TOKYO OHKA KOGYO CO., LTD., Kawasaki-shi (JP)

(21) Appl. No.: 13/702,156

(22) PCT Filed: May 27, 2011
(86) PCT No.: PCT/JP2011/062214

§ 371 Date: Dec. 5, 2012

(30) Foreign Application Priority Data
Jun. 7, 2010 (JP) 2010-130341

(51) Int. Cl. G03F 7/32; G03F 7/30

(52) U.S. Cl. CPC G03F 7/32; G03F 7/30
USPC 430/326; 430/331

(57) ABSTRACT

A resist pattern formation method that includes a step (1) of forming a resist pattern on a support using a chemically amplified positive-type resist composition, a step (2) of applying a pattern miniaturization agent to the resist pattern, a step (3) of performing a bake treatment of the resist pattern to which the pattern miniaturization agent has been applied, and a step (4) of subjecting the resist pattern that has undergone the bake treatment to alkali developing, wherein the pattern miniaturization agent contains an acid generator component, and an organic solvent that does not dissolve the resist pattern formed in the step (1). Also, a pattern miniaturization agent used in the method.

### TECHNICAL FIELD

The present invention relates to a resist pattern formation method that is useful for miniaturizing a resist pattern, and a pattern miniaturization agent used in the method.

Priority is claimed on Japanese Patent Application No. 2010-130341, filed Jun. 7, 2010, the content of which is incorporated herein by reference.

### BACKGROUND ART

Techniques in which a fine pattern is formed on a support, and the pattern is then used as a mask to process the layer beneath the pattern by etching (namely, pattern formation technology) is widely employed in the field of semiconductors for fabricating IC devices and the like, and is the focus of much attention.

These fine patterns are typically formed from organic materials, and are formed, for example, using techniques such as lithography methods or nanoimprinting methods. For example, in a lithography method, a resist film composed of a resist material is formed on a support such as a substrate, the resist film is subjected to selective exposure with radiation such as light or an electron beam, and a developing treatment is then performed to form a resist pattern having a predetermined shape on the resist film. Then, using this resist pattern as a mask, a semiconductor device or the like is produced by conducting a step in which the substrate is processed by etching. A resist material in which the exposed portions of the resist film exhibit increased solubility in a developing solution is called a positive-type material, and a resist material in which the exposed portions exhibit reduced solubility in a developing solution is called a negative-type material.

In recent years, advances in lithography techniques have lead to rapid progress in the field of pattern miniaturization. Typically, these resist pattern miniaturization techniques involve shortening the wavelength (increasing the energy) of the exposure light source. Conventionally, ultraviolet radiation typified by g-line and i-line radiation has been used, but nowadays mass production of semiconductor devices using KrF excimer lasers and ArF excimer lasers has started, and for example, lithography using ArF excimer lasers is capable of pattern formation with a resolution at the 45 nm level. Furthermore, in order to further improve the resolution, research is also being conducted into techniques that use exposure sources having a shorter wavelength (higher energy) than these excimer lasers, such as electron beams, extreme ultraviolet radiation (EUV), and X rays.

Resist materials require lithography properties such as a high resolution capable of reproducing patterns of minute dimensions, and a high level of sensitivity to these types of exposure light sources. Chemically amplified resist compositions containing an acid generator component that generates acid upon exposure are typically used as resist materials that satisfy these requirements. A chemically amplified resist composition generally includes the aforementioned acid generator, and a base component that exhibits changed solubility in an alkali developing solution under the action of acid. For example, in a positive-type chemically amplified resist composition, a component that exhibits increased solubility in an alkali developing solution under the action of acid is used as the resist composition base component. A resin is generally used as the base component of a chemically amplified resist composition (for example, see Patent Document 1).

Furthermore, as a technique for resist pattern miniaturization, a resist pattern formation method has been proposed that includes forming a resist pattern using a radiation-sensitive resin composition, coating the resist pattern with a resist pattern miniaturization composition containing an acidic low-molecular weight compound and a solvent that does not dissolve the resist pattern, and then performing baking and washing to miniaturize the resist pattern (see Patent Document 2).

### DOCUMENTS OF RELATED ART

### Patent Documents

[Patent Document 1]
Japanese Unexamined Patent Application, First Publication No. 2003-241385
[Patent Document 2]
Japanese Unexamined Patent Application, First Publication No. 2010-49247

### SUMMARY OF THE INVENTION

### Problems to be Solved by the Invention

However, in the resist pattern formation method disclosed in Patent Document 2, a problem exists in that the resist pattern formed using the radiation-sensitive resin composition tends to detach from the silicon substrate upon application of the resist pattern miniaturization composition, or the resist pattern collapses and cannot be resolved.

The present invention has been developed in light of the above circumstances, and has an object of providing a resist pattern formation method that is useful for resist pattern miniaturization, and a pattern miniaturization agent that is used in the method.

### Means to Solve the Problems

In order to achieve the above object, the present invention adopts the aspects described below.

Namely, a first aspect of the present invention is a resist pattern formation method that includes a step (1) of forming a resist pattern on a support using a chemically amplified positive-type resist composition, a step (2) of applying a pattern miniaturization agent to the resist pattern, a step (3) of performing a bake treatment of the resist pattern to which the pattern miniaturization agent has been applied, and a step (4) of subjecting the resist pattern that has undergone the bake treatment to alkali developing, wherein the pattern miniaturization agent contains an acid generator component, and an organic solvent that does not dissolve the resist pattern formed in the step (1).

A second aspect of the present invention is a pattern miniaturization agent that is used in the resist pattern formation method of the first aspect, wherein the pattern miniaturization agent contains an acid generator component, and an organic solvent that does not dissolve the resist pattern formed in the step (1).

In the present description and the claims, unless specified otherwise, the term “alkyl group” includes linear, branched and cyclic monovalent saturated hydrocarbon groups.

The term “alkylene group”, unless specified otherwise, includes linear, branched and cyclic divalent saturated hydrocarbon groups.

A “lower alkyl group” describes an alkyl group of 1 to 5 carbon atoms.

A “halogenated alkyl group” is a group in which some or all of the hydrogen atoms of an alkyl group have each been substituted with a halogen atom, wherein examples of the halogen atom include a fluorine atom, chlorine atom, bromine atom and iodine atom.

The term “aliphatic” is a relative concept used in relation to the term “aromatic”, and defines a group or compound or the like that has no aromaticity.

A “structural unit” describes a monomer unit that contributes to the formation of a polymeric compound (a polymer or copolymer).

The term “exposure” is used as a general concept that includes irradiation with any form of radiation.

The term “(meth)acrylic acid” is a generic term that includes either or both of acrylic acid having a hydrogen atom bonded to the α-position and methacrylic acid having a methyl group bonded to the α-position.

The term “(meth)acrylate ester” is a generic term that includes either or both of the acrylate ester having a hydrogen atom bonded to the α-position and the methacrylate ester having a methyl group bonded to the α-position.

The term “(meth)acrylate” is a generic term that includes either or both of the acrylate having a hydrogen atom bonded to the α-position and the methacrylate having a methyl group bonded to the α-position.

### Effects of the Invention

The present invention is able to provide a resist pattern formation method that is useful for resist pattern miniaturization, and a pattern miniaturization agent that is used in the method.

### EMBODIMENTS OF THE INVENTION

### <<Resist Pattern Formation Method>>

The resist pattern formation method of the present invention includes a step (1) of forming a resist pattern on a support using a chemically amplified positive-type resist composition, a step (2) of applying a pattern miniaturization agent to the resist pattern, a step (3) of performing a bake treatment of the resist pattern to which the pattern miniaturization agent has been applied, and a step (4) of subjecting the resist pattern that has undergone the bake treatment to alkali developing.

The pattern miniaturization agent contains an acid generator component, and an organic solvent that does not dissolve the resist pattern formed in the step (1).

Specific examples of the acid generator component include thermal acid generators that generate acid upon heating, and photo-acid generators that generate acid upon exposure.

Specific examples of preferred forms of the resist pattern formation method are described below.

Method (I): a method including a step (I-1) of forming a resist pattern on a support using a chemically amplified positive-type resist composition, a step (I-2) of applying a pattern miniaturization agent containing a thermal acid generator that generates acid upon heating to the resist pattern, a step (I-3) of performing a bake treatment of the resist pattern to which the pattern miniaturization agent has been applied, and a step (I-4) of subjecting the resist pattern that has undergone the bake treatment to alkali developing.

Method (II): a method including a step (II-1) of forming a resist pattern on a support using a chemically amplified positive-type resist composition, a step (II-2) of applying a pattern miniaturization agent containing a photo-acid generator that generates acid upon exposure to the resist pattern, a step (II-5) of exposing the resist pattern to which the pattern miniaturization agent has been applied, a step (II-3) of performing a bake treatment of the resist pattern that has undergone exposure, and a step (II-4) of subjecting the resist pattern that has undergone the bake treatment to alkali developing.

### <Method (I)>

[Step (I-1)]

In the step (I-1), a resist pattern is formed on a support using a chemically amplified positive-type resist composition.

There are no particular limitations on the support, and conventionally known materials may be used. For example, substrates for electronic components, and such substrates having wiring patterns formed thereon can be used. Specific examples include substrates composed of metals such as silicon wafer, copper, chromium, iron and aluminum, as well as glass substrates. Suitable materials for the wiring pattern include copper, aluminum, nickel, and gold.

Further, any one of the aforementioned substrates provided with an inorganic and/or organic film on the surface thereof may also be used as the support. Examples of the inorganic film include inorganic antireflection films (inorganic BARC). Examples of the organic film include organic antireflection films (organic BARC) and the lower layer films from multilayer resist methods. If an organic film is provided, then a pattern having a high aspect ratio can be formed on the substrate, which is particularly desirable in the production and the like of semiconductors.

Here, a “multilayer resist method” is a method in which at least one layer of an organic film (a lower layer film) and at least one layer of a resist film are provided on a substrate, and a resist pattern formed in the upper layer resist film is used as a mask to conduct patterning of the lower layer, and is regarded as a method that is capable of forming patterns having a high aspect ratio. Multilayer resist methods can be basically classified as either methods that yield a double-layer structure composed of an upper layer resist film and a lower layer film, or methods that yield a multilayer structure of three or more layers in which one or more intermediate layers (such as thin metal films) are provided between the resist film and the lower layer film. According to a multilayer resist method, by using the lower layer film to ensure the desired level of thickness, the resist film can be formed as a very thin film, enabling the formation of a very fine pattern having a high aspect ratio.

An inorganic film can be formed, for example, by applying an inorganic antireflective film composition such as a silicon-based material to the substrate, and then performing baking or the like.

An organic film can be formed, for example, by using a spinner or the like to apply an organic film-forming material, prepared by dissolving a resin component or the like that forms the organic film in an organic solvent, to the surface of the substrate, and then conducting a bake treatment under conditions that include heating at a temperature that is preferably within a range from 200 to 300° C., for a period that is preferably within a range from 30 to 300 seconds, and more preferably from 60 to 180 seconds.

There are no particular limitations on the chemically amplified positive-type resist composition (hereafter also referred to as simply the “positive-type resist composition”), and the composition may be selected appropriately from among known chemically amplified positive-type resist compositions.

In this description, the “chemically amplified resist composition” is a composition that contains an acid generator component that generates acid upon exposure as an essential component, and has a property wherein the solubility in an alkali developing solution of the entire chemically amplified resist composition changes under the action of the generated acid. For example, in the case of a positive-type composition, the solubility in the alkali developing solution increases.

The chemically amplified positive-type resist composition in step (I-1) contains an acid generator component (B) that generates acid upon exposure, and a base component (A) having an acid-dissociable, dissolution-inhibiting group. When a resist film formed using this chemically amplified positive-type resist composition is subjected to exposure and post-exposure baking, the action of the acid generated from the acid generator component (B) causes dissociation of the acid-dissociable, dissolution-inhibiting group from the base component (A).

This acid-dissociable, dissolution-inhibiting group is a group that has an alkali dissolution-inhibiting effect that renders the entire base component (A) substantially insoluble in an alkali developing solution prior to dissociation, but then dissociates under the action of the acid generated from the acid generator component (B), and the dissociation of this acid-dissociable, dissolution-inhibiting group causes an increase in the solubility of the base component (A) within an alkali developing solution. Accordingly, when a resist film formed using the chemically amplified positive-type resist composition is subjected to selective exposure and post-exposure baking, the exposed portions of the resist film develop increased solubility in an alkali developing solution due to the action of the acid generated from the acid generator component (B), whereas the unexposed portions undergo no change in solubility within an alkali developing solution, and as a result, alkali developing can then be used to dissolve and remove only the exposed portions, thereby forming a resist pattern.

Specific examples of the chemically amplified positive-type resist composition are presented below in further detail.

There are no particular limitations on the method used for applying the positive-type resist composition to the support to form a resist film, and conventional methods may be used.

For example, a resist film can be formed by applying the positive-type resist composition of the present invention to a support using a conventional method that employs a spinner, and then performing a bake treatment (prebake) under temperature conditions of 80 to 150° C. for 40 to 120 seconds, and preferably 60 to 90 seconds, to evaporate the organic solvent and form a resist film.

The thickness of the resist film is preferably within a range from 30 to 500 nm, and more preferably from 50 to 450 nm. By ensuring the thickness satisfies this range, a resist pattern with superior resolution can be formed, and satisfactory resistance to etching can be obtained.

Next, the resist film formed in the manner described above is selectively exposed through a photomask, and is then subjected to a PEB treatment and developing to form a resist pattern.

There are no particular limitations on the wavelength used for exposure, and the exposure can be conducted using radiation such as a KrF excimer laser, ArF excimer laser, F₂ excimer laser, extreme ultraviolet radiation (EUV), vacuum ultraviolet radiation (VUV), electron beam (EB), X-rays, and soft X-rays. In order to facilitate formation of a fine resist pattern, the use of an ArF excimer laser, EUV or EB is preferred, and an ArF excimer laser is particularly desirable.

There are no particular limitations on the photomask, and conventional photomasks may be used. Specific examples of photomasks that can be used include a binary mask in which the transmittance of the light-shielding portions is 0%, and a halftone phase shift mask (HT-mask) in which the transmittance of the light-shielding portions is 6%.

The binary mask generally employs a quartz glass substrate with a chromium film or chromium oxide film or the like formed thereon as the light-shielding portions.

The halftone phase shift mask generally employs a quartz glass substrate with a MoSi (molybdenum silicide) film, chromium film, chromium oxide film or silicon oxynitride film or the like formed thereon as the shielding portions.

The present invention is not limited to exposure treatments performed through a photomask, and the selective exposure may be performed by an exposure treatment that does not use a photomask, such as direct patterning using an EB or the like.

The exposure of the first resist film may be conducted either using a normal exposure process (dry exposure), which is performed within air or an inert gas such as nitrogen, or using immersion exposure.

In immersion exposure, the exposure is conducted in a state where the region between the lens and the resist film formed on the support, which is conventionally filled with air or an inert gas such as nitrogen, is filled with a solvent (a liquid immersion medium) having a larger refractive index than the refractive index of air.

More specifically, immersion exposure can be performed by filling the region between the resist film obtained in the manner described above and the lens at the lowermost point of the exposure apparatus with a solvent (immersion medium) that has a larger refractive index than the refractive index of air, and then performing exposure (immersion exposure) through a desired photomask in this state.

The immersion medium is preferably a solvent that has a refractive index that is larger than the refractive index of air but smaller than the refractive index of the resist film undergoing exposure in the immersion exposure process (namely, the resist film formed in the step (I-1)). The refractive index of the solvent is not particularly limited provided it satisfies this range.

Examples of this solvent having a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids that contain a fluorine-based compound such as C₃HCl₂F₅, C₄F₉OCH₃, C₄F₉OC₂H₅ or C₅H₃F₇ as the main component, and have a boiling point that is preferably within a range from 70 to 180° C. and more preferably from 80 to 160° C. A fluorine-based inert liquid having a boiling point within the above-mentioned range is advantageous in that the removal of the immersion medium following completion of the exposure can be conducted by a simple method.

As the fluorine-based inert liquid, a perfluoroalkyl compound in which all of the hydrogen atoms of an alkyl group are substituted with fluorine atoms is particularly desirable. Examples of these perfluoroalkyl compounds include perfluoroalkyl ether compounds and perfluoroalkylamine compounds.

Specifically, one example of a perfluoroalkyl ether compound is perfluoro(2-butyl-tetrahydrofuran) (boiling point: 102° C.), whereas an example of a perfluoroalkylamine compound is perfluorotributylamine (boiling point: 174° C.).

In the step (I-1), the exposure dose and the PEB temperature are set so as to ensure an increase in the solubility of the exposed portions of the resist film in an alkali developing solution. In other words, the exposure and the PEB are performed so that the amount of energy supplied to the exposed portions of the resist film during the exposure and PEB is sufficient to increase the solubility of the exposed portions in the alkali developing solution, while ensuring that the solubility of the unexposed portions in the alkali developing solution does not increase.

More specifically, subjecting the resist film formed from the chemically amplified positive-type resist composition to exposure and PEB causes the generation of acid from the acid generator component (B), diffusion of the generated acid through the resist film, and an increase in the solubility of the resist film in an alkali developing solution due to the action of the acid. At this time, if the exposure dose and the PEB bake temperature (PEB temperature) are insufficient, and the amount of energy supplied is inadequate, then the generation and diffusion of the acid do not proceed satisfactorily, and the solubility of the exposed portions within an alkali developing solution does not increase sufficiently.

As a result, the difference in the solubility rates of the exposed portions and the unexposed portions within the alkali developing solution (namely, the solubility contrast) is small, and even if developing is performed, a favorable resist pattern cannot be formed. In other words, when performing exposure, PEB and developing of the resist film in order to form a resist pattern, it is necessary to ensure that the exposure and the PEB are performed using an exposure dose and a PEB temperature that cause the exposed portions of the resist film to develop a level of solubility within an alkali developing solution that is sufficient to enable dissolution and removal of those exposed portions within the alkali developing solution.

In order to ensure an increase in the solubility within an alkali developing solution of the resist film, both the exposure dose and the PEB temperature must be at least as larger as certain predetermined values. For example, if the exposure dose is too small, then even if the PEB temperature is increased, a satisfactory increase in the solubility within an alkali developing solution is not observed. Further, even if the exposure dose is large, if the PEB temperature is too low, then a satisfactory increase in the solubility within an alkali developing solution is not observed.

Hereafter, this PEB temperature that causes the exposed portions of the resist film to develop a level of solubility within an alkali developing solution that is sufficient to enable dissolution and removal of those exposed portions within the alkali developing solution may also be referred to as the “effective PEB temperature”.

In terms of the exposure dose, any exposure dose that yields an increase in the solubility of the resist film in an alkali developing solution may be used, but usually, the optimum exposure dose (Eop₁) for the resist film is used. In this description, the term “optimum exposure dose” describes the dose which, when the resist film is selectively exposed, subjected to PEB at a predetermined PEB temperature and then developed, yields a resist pattern that faithfully reproduces the dimensions of the designed pattern.

The PEB temperature (T_{pcb1}) in the step (I-1) is the temperature that yields an increase in the solubility in an alkali developing solution of the exposed portions of the resist film upon exposure at the above exposure dose, and may be any temperature not less than the minimum value (Tₘᵢₙ₁) for the effective PEB temperature for the resist film. In other words, Tₘᵢₙ≦T_{peb1}.

T_{pcb1} varies depending on the composition of the positive-type resist composition that is used, but is typically within a range from 70 to 150° C., preferably from 80 to 140° C., and more preferably from 85 to 135° C.

The bake time in the PEB treatment is typically within a range from 40 to 120 seconds, and preferably from 60 to 90 seconds.

A determination as to whether or not a proposed exposure dose and PEB temperature are capable of increasing the solubility of the resist film in an alkali developing solution can be made in the manner described below.

The resist film is exposed with various exposure doses, using the exposure source (such as an ArF excimer laser, EB or EUV or the like) used in the step (I-1), the PEB treatment is conducted at a predetermined bake temperature for a period of 30 to 120 seconds, and developing is then performed using a 2.38% by weight aqueous solution of tetramethylammonium hydroxide (23° C.) as the developing solution.

In those cases where, as the exposure dose is increased at a predetermined bake temperature, the dissolution rate of the exposed portions of the resist film in the alkali developing solution reaches a level of 1 nm/second or higher once the exposure dose has reached or exceeded a predetermined value, the bake temperature used is deemed to be a bake temperature that increases the solubility of the resist film in the alkali developing solution (namely, a temperature that is at least as high as Tₘᵢₙ₁ for the resist film). On the other hand, in those cases where, even when the exposure dose is increased, the dissolution rate of the exposed portions of the resist film in the developing solution does not reach a level of 1 nm/second or higher, but rather becomes saturated at a lower dissolution rate, the bake temperature used is deemed to be a bake temperature that does not increase the solubility of the resist film in the alkali developing solution (namely, a temperature that is less than Tₘᵢₙ₁ for the resist film).

Further, at this time, an exposure dose that is equal to or greater than the exposure dose at the point where the dissolution rate in the alkali developing solution has changed sufficiently to reach a dissolution rate of at least 1 nm/second is deemed to be an exposure dose that increases the solubility of the resist film in the alkali developing solution at that particular PEB temperature.

Following the PEB treatment, alkali developing of the resist film is performed. Alkali developing can be conducted by a conventional method, using the types of alkali aqueous solutions typically used as developing solutions, such as an aqueous solution of tetramethylammonium hydroxide (TMAH) with a concentration of 0.1 to 10% by weight. This alkali developing removes the exposed portions of the resist film, forming a resist pattern.

Following the alkali developing, a rinse treatment may be conducted using pure water or the like.

Further, an additional bake treatment (post bake) may be performed following the alkali developing. The post bake (which is performed mainly to remove any residual moisture following the alkali developing and the rinse treatment) is typically performed at a treatment temperature of 120 to 160° C., and the treatment time is preferably within a range from 30 to 90 seconds.

[Step (I-2)]

In the step (I-2), a pattern miniaturization agent containing a thermal acid generator that generates acid upon heating is applied to the resist pattern formed in the step (I-1).

In the present invention, a “thermal acid generator that generates acid upon heating” describes a component that generates acid upon heating, preferably at a temperature of 130° C. or higher, and more preferably at a temperature of 130 to 200° C. By using a thermal acid generator that generates acid upon heating at 130° C. or higher, the resist pattern can be miniaturized favorably without performing exposure.

Specific examples of the pattern miniaturization agent containing a thermal acid generator are described below in detail.

Examples of the method used for applying the pattern miniaturization agent to the resist pattern formed in the step (I-1) include methods that involve spraying the pattern miniaturization agent from a nozzle or the like onto the surface of the resist pattern, methods that involve spin coating the pattern miniaturization agent onto the surface of the resist pattern, and methods that involve dipping the resist pattern in the pattern miniaturization agent.

[Step (I-3)]

In the step (I-3), a bake treatment is performed of the resist pattern to which the pattern miniaturization agent has been applied in the step (I-2).

The time from application of the pattern miniaturization agent to the resist pattern formed in the step (I-1) until performing of the bake treatment (namely, the contact time between the resist pattern and the pattern miniaturization agent) may be set appropriately in accordance with the type of chemically amplified positive-type resist composition being used, the type of pattern miniaturization agent, and the intended application, but is preferably within a range from 5 to 90 seconds, and more preferably from 5 to 30 seconds.

The bake treatment in the step (I-3) is performed with the temperature of the bake treatment set so that following the bake treatment, the resist pattern can be removed by the alkali developing performed in the step (I-4).

The temperature of the bake treatment varies depending on the type of thermal acid generator included within the pattern miniaturization agent, but is preferably at least 130° C., and more preferably from 130 to 200° C. When the temperature of the bake treatment is at least 130° C., the solubility of the resist pattern in the alkali developing solution can be more readily increased.

The bake time is preferably within a range from 40 to 120 seconds, and more preferably from 60 to 90 seconds.

By performing this bake treatment, acid is generated from the thermal acid generator contained within the pattern miniaturization agent that has been applied to the surface of the resist pattern and has penetrated into the surface region of the resist pattern. This generated acid diffuses through the surface region of the resist pattern and reacts with the components that constitute the surface region of the resist pattern (for example, causing dissociation of the acid-dissociable, dissolution-inhibiting group in the component (A1) described below). As a result, the solubility in an alkali developing solution of the surface region of the resist pattern increases. When alkali developing is then performed in the subsequent step (I-4), this surface region of the resist pattern is removed.

The proportion of the surface region of the resist pattern that undergoes an increase in solubility in an alkali developing solution (namely, the thickness of the resist pattern surface layer) can be controlled by adjusting the composition of the pattern miniaturization agent (such as the type and amount of the thermal acid generator), the temperature of the bake treatment, the bake time, and the composition of the chemically amplified positive-type resist composition and the like.

[Step (I-4)]

In the step (I-4), the resist pattern that has undergone a bake treatment in the step (I-3) is subjected to alkali developing. As a result, the resist pattern surface region is removed, and a resist pattern is formed that has finer dimensions than the resist pattern formed in the step (I-1).

For example, in the case where the resist pattern formed in the step (I-1) is a line pattern, a resist pattern of finer dimensions is formed in which the line width has been narrowed. Further, in the case where the resist pattern formed in the step (I-1) is a dot pattern, a resist pattern of finer dimensions is formed in which the dimensions of the dot pattern (the dot diameter) has been reduced.

The alkali developing can be performed by a conventional method, using an alkali developing solution such as an aqueous solution of tetramethylammonium hydroxide (TMAH) with a concentration of 0.1 to 10% by weight.

Following the alkali developing, a rinse treatment may be conducted using pure water or the like.

Further, an additional bake treatment (post bake) may be performed following the alkali developing. The post bake (which is performed for the purpose of removing residual moisture following the alkali developing and the rinse treatment) is typically performed at a treatment temperature of approximately 100° C., and the treatment time is preferably within a range from 30 to 90 seconds.

### <Method (II)>

[Step (II-1)]

In the step (II-1), a resist pattern is formed on a support using a chemically amplified positive-type resist composition.

The specific method used and the conditions employed and the like may be the same as those described for the step (I-1).

[Step (II-2)]

In the step (II-2), a pattern miniaturization agent containing a photo-acid generator that generates acid upon exposure is applied to the resist pattern formed in the step (II-1).

Specific examples of the pattern miniaturization agent containing a photo-acid generator are described below in detail.

Examples of the method used for applying the pattern miniaturization agent to the resist pattern formed in the step (II-1) include methods that involve spraying the pattern miniaturization agent from a nozzle or the like onto the surface of the resist pattern, methods that involve spin coating the pattern miniaturization agent onto the surface of the resist pattern, and methods that involve dipping the resist pattern in the pattern miniaturization agent.

Following application of the pattern miniaturization agent to the resist pattern, a bake treatment (prebake) is performed to volatilize the organic solvent, preferably at a temperature of 80 to 150° C. for a period of 40 to 120 seconds, and preferably 60 to 90 seconds.

[Step (II-5)]

In the step (II-5), the resist pattern to which the pattern miniaturization agent has been applied is subjected to exposure. As a result of this exposure, acid is generated from the photo-acid generator contained within the pattern miniaturization agent that has been applied to the surface of the resist pattern and has penetrated into the surface region of the resist pattern.

The wavelength and photomask used for the exposure may be the same wavelength and photomask as those used for the exposure performed in the step (I-1).

The exposure is not limited to exposure treatments performed through a photomask, and an exposure treatment that does not use a photomask, such as full surface exposure or selective exposure performed by direct patterning using an EB or the like, may also be used.

[Step (II-3)]

In the step (II-3), a bake treatment is performed of the resist pattern that has undergone exposure in the step (II-5). By performing this bake treatment, the acid generated from the photo-acid generator diffuses through the surface region of the resist pattern and reacts with the components that constitute the surface region of the resist pattern (for example, causing dissociation of the acid-dissociable, dissolution-inhibiting group in the component (A1) described below). As a result, the solubility in an alkali developing solution of the surface region of the resist pattern increases. When alkali developing is then performed in the subsequent step (II-4), this surface region of the resist pattern is removed.

The specific method and conditions employed in the bake treatment may be the same as those described for the PEB treatment in the step (I-1).

The proportion of the surface region of the resist pattern that undergoes an increase in solubility in an alkali developing solution (namely, the thickness of the resist pattern surface layer) can be controlled by adjusting the composition of the pattern miniaturization agent (such as the type and amount of the acid generator component), the exposure dose, the temperature of the bake treatment, the bake time, and the composition of the chemically amplified positive-type resist composition and the like.

[Step (II-4)]

In the step (II-4), the resist pattern that has undergone the bake treatment in the step (II-3) is subjected to alkali developing. As a result, the resist pattern surface region is removed, and a resist pattern is formed that has finer dimensions than the resist pattern formed in the step (II-1).

The specific method and conditions and the like used for the alkali developing may be the same as those described for the step (I-4).

The resist pattern formation method of the present invention includes the steps (1) to (4) described above, and provided the prescribed pattern miniaturization agent is used, is not necessarily limited to the method (I) or method (II) described above, and may be a different method.

Further, the method (I) or method (II) described above may also include one or more steps other than those described above.

### <Pattern Miniaturization Agent>

The pattern miniaturization agent used in the resist pattern formation method of the present invention contains an acid generator component and an organic solvent that does not dissolve the resist pattern formed in the aforementioned step (1).

### (Acid Generator Component)

Examples of known acid generator components are numerous, and include onium salt acid generators such as iodonium salts and sulfonium salts, oxime sulfonate acid generators, diazomethane acid generators such as bisalkyl or bisaryl sulfonyl diazomethanes and poly(bis-sulfonyl)diazomethanes, nitrobenzylsulfonate acid generators, iminosulfonate acid generators, and disulfone acid generators.

These acid generator components are generally known as photo-acid generators (PAG) that generate acid upon exposure, but they also function as thermal acid generators (TAG) that generate acid upon heating.

Accordingly, examples of compounds that can be used as the acid generator component in the pattern miniaturization agent include any of the compounds used as acid generators for conventional chemically amplified resist compositions.

As an onium salt acid generator, a compound represented by general formula (b-1) or (b-2) shown below may be used.

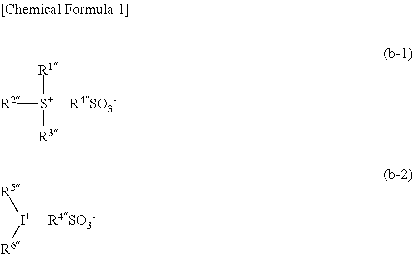

In the formulas, each of R¹″ to R³″, R⁵″ and R⁶″ independently represents an aryl group or an alkyl group, wherein two of R¹″ to R³″ in the formula (b-1) may be bonded to each other to form a ring with the sulfur atom in the formula, and R⁴″ represents an alkyl group, halogenated alkyl group, aryl group or alkenyl group which may have a substituent, provided that at least one of R¹″ to R³″ represents an aryl group, and at least one of R⁵″ and R⁶″ represents an aryl group.

In formula (b-1), each of R¹″ to R³″ independently represents an aryl group or an alkyl group. Moreover, two of R¹″ to R³″ in formula (b-1) may be bonded to each other to form a ring together with the sulfur atom in the formula.

Furthermore, at least one of R¹″ to R³″ preferably represents an aryl group. It is more preferable that at least two of R¹″ to R³″ are aryl groups, and most preferable that all of R¹″ to R³″ are aryl groups.

There are no particular limitations on the aryl group for R¹″ to R³″, and examples include aryl groups of 6 to 20 carbon atoms in which some or all of the hydrogen atoms of the aryl group may or may not each be substituted with an alkyl group, alkoxy group, halogen atom or hydroxyl group or the like.

The aryl group is preferably an aryl group of 6 to 10 carbon atoms because such groups enable synthesis to be performed at low cost. Specific examples include a phenyl group and a naphthyl group.

The alkyl group with which a hydrogen atom of the aryl group may be substituted is preferably an alkyl group of 1 to 5 carbon atoms, and most preferably a methyl group, ethyl group, propyl group, n-butyl group or tert-butyl group.

The alkoxy group with which a hydrogen atom of the aryl group may be substituted is preferably an alkoxy group of 1 to 5 carbon atoms, more preferably a methoxy group, ethoxy group, n-propoxy group, iso-propoxy group, n-butoxy group or tert-butoxy group, and most preferably a methoxy group or an ethoxy group.

The halogen atom with which a hydrogen atom of the aryl group may be substituted is preferably a fluorine atom.

There are no particular limitations on the alkyl group for R¹″ to R³″, and examples includes linear, branched and cyclic alkyl groups of 1 to 10 carbon atoms. In terms of achieving excellent resolution, the alkyl group preferably has 1 to 5 carbon atoms. Specific examples include a methyl group, ethyl group, n-propyl group, isopropyl group, n-butyl group, isobutyl group, n-pentyl group, cyclopentyl group, hexyl group, cyclohexyl group, nonyl group and decyl group, and a methyl group is most preferable because it yields excellent resolution and enables synthesis to be performed at low cost.

When two of R¹″ to R³″ in formula (b-1) are bonded to each other to form a ring together with the sulfur atom in the formula, the ring including the sulfur atom is preferably a 3- to 10-membered ring, and more preferably a 5- to 7-membered ring.

When two of R¹″ to R³″ in formula (b-1) are bonded to each other to form a ring together with the sulfur atom in the formula, the remaining one of R¹″ to R³″ is preferably an aryl group. Examples of this aryl group include the same aryl groups as those described above for the aryl group for R¹″ to R³″.

Examples of preferred cation moieties for the compound represented by formula (b-1) include the cation moieties represented by formulas (I-1-1) to (I-1-8) shown below, which include a phenylmethane structure.

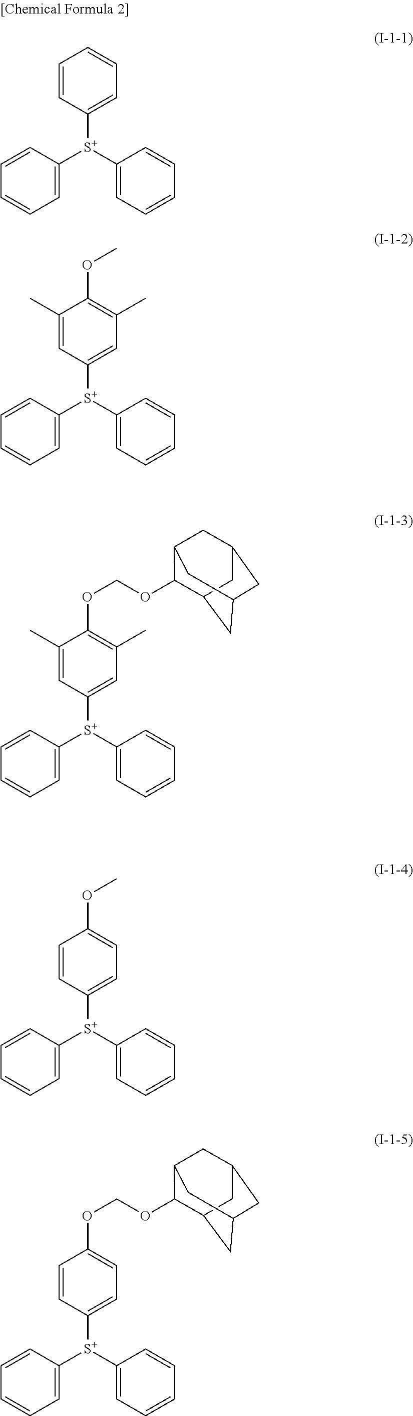 [SMILES: c1ccc([S+](c2ccccc2)c2ccccc2)cc1 ; COc1c(C)cc([S+](c2ccccc2)c2ccccc2)cc1C ; Cc1cc([S+](c2ccccc2)c2ccccc2)cc(C)c1OCOC1C2CC3CC(C2)CC1C3 ; COc1ccc([S+](c2ccccc2)c2ccccc2)cc1 ; c1ccc([S+](c2ccccc2)c2ccc(OCOC3C4CC5CC(C4)CC3C5)cc2)cc1]

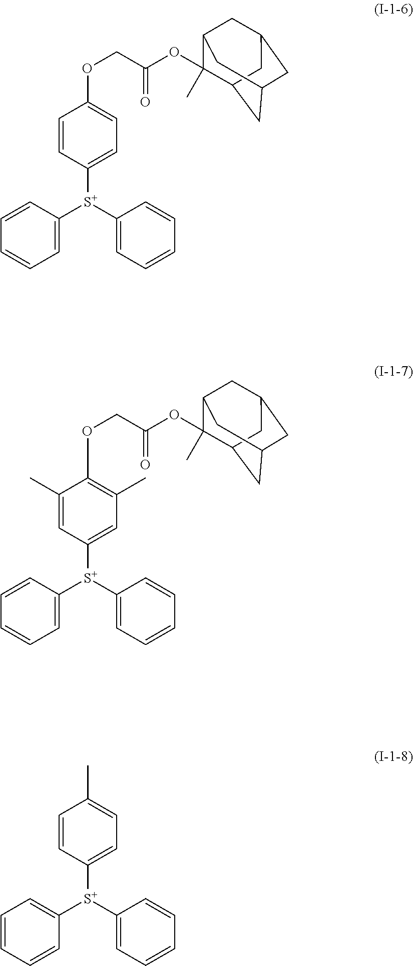 [SMILES: CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3 ; Cc1ccc([S+](c2ccccc2)c2ccccc2)cc1]

Further, as the cation moiety for the onium salt acid generator, cations represented by formulas (I-1-9) and (I-1-10) shown below are also desirable.

In formulas (I-1-9) and (I-1-10) shown below, each of R²⁷ and R³⁹ independently represents a phenyl group or naphthyl group which may have a substituent, an alkyl group or alkoxy group of 1 to 5 carbon atoms, or a hydroxyl group.

v represents an integer of 1 to 3, and is most preferably 1 or 2.

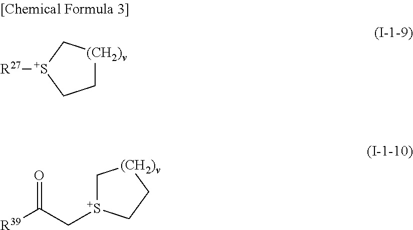

R⁴″ represents an alkyl group, halogenated alkyl group, aryl group or alkenyl group which may have a substituent.

The alkyl group for R⁴″ may be linear, branched or cyclic.

The linear or branched alkyl group preferably contains 1 to 10 carbon atoms, more preferably 1 to 8 carbon atoms, and most preferably 1 to 4 carbon atoms.

The cyclic alkyl group preferably contains 4 to 15 carbon atoms, more preferably 4 to 10 carbon atoms, and most preferably 6 to 10 carbon atoms.

Examples of the halogenated alkyl group for R⁴″ include groups in which some or all of the hydrogen atoms within an aforementioned linear, branched or cyclic alkyl group have each been substituted with a halogen atom. Examples of the halogen atom include a fluorine atom, chlorine atom, bromine atom or iodine atom. A fluorine atom is preferred.

In the halogenated alkyl group, the percentage of the number of halogen atoms relative to the total number of halogen atoms and hydrogen atoms within the halogenated alkyl group (namely, the halogenation ratio (%)) is preferably within a range from 10 to 100%, more preferably from 50 to 100%, and most preferably 100%. A higher halogenation ratio is preferable because the acid strength increases.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that some or all of the hydrogen atoms within the aforementioned linear, branched or cyclic alkyl group, halogenated alkyl group, aryl group or alkenyl group may each be substituted with a substituent (an atom other than a hydrogen atom, or a group).

R⁴″ may have one substituent, or two or more substituents.

Examples of the substituent include a halogen atom, a hetero atom, an alkyl group, and a group represented by the formula X-Q¹- (wherein Q¹ represents a divalent linking group containing an oxygen atom, and X represents a hydrocarbon group of 3 to 30 carbon atoms which may have a substituent).

Examples of the halogen atom and the alkyl group include the same halogen atoms and alkyl groups as those described above with respect to the halogenated alkyl group for R⁴″.

Examples of the hetero atom include an oxygen atom, a nitrogen atom, and a sulfur atom.

In the group represented by formula X-Q¹-, Q¹ represents a divalent linking group containing an oxygen atom.

Q¹ may also contain atoms other than the oxygen atom. Examples of these atoms other than the oxygen atom include a carbon atom, hydrogen atom, sulfur atom and nitrogen atom.

Examples of the divalent linking group containing an oxygen atom include non-hydrocarbon, oxygen atom-containing linking groups such as an oxygen atom (an ether linkage, —O—), an ester linkage (—C(═O)—O—), an amide linkage (—C(═O)—NH—), a carbonyl group (—C(═O)—), a carbonate linkage (—O—C(═O)—O—), and combinations of these non-hydrocarbon, oxygen atom-containing linking groups with an alkylene group.

Specific examples of the combinations of the aforementioned non-hydrocarbon, oxygen atom-containing linking groups and an alkylene group include —R⁹¹—O—, —R⁹²—O—C(═O)— and —C(═O)—O—R⁹³—O—C(═O)— (wherein each of R⁹¹ to R⁹³ independently represents an alkylene group).

The alkylene group for R⁹¹ to R⁹³ is preferably a linear or branched alkylene group, and preferably contains 1 to 12 carbon atoms, more preferably 1 to 5 carbon atoms, and most preferably 1 to 3 carbon atoms.

Specific examples of the alkylene group include a methylene group [—CH₂—], alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, an ethylene group [—CH₂CH₂—], alkylethylene groups such as —CH(CH₃)CH₂—, —CH(CH₃)CH(CH₃)—, —C(CH₃)₂CH₂— and —CH(CH₂CH₃)CH₂—, a trimethylene group (n-propylene group) [—CH₂CH₂CH₂—], alkyltrimethylene groups such as —CH(CH₃)CH₂CH₂— and —CH₂CH(CH₃)CH₂—, a tetramethylene group [—CH₂CH₂CH₂CH₂—], alkyltetramethylene groups such as —CH(CH₃)CH₂CH₂CH₂— and —CH₂CH(CH₃)CH₂CH₂—, and a pentamethylene group [—CH₂CH₂CH₂CH₂CH₂—].

Q¹ is preferably a divalent linking group containing an ester linkage or ether linkage, and is more preferably a group represented by —R⁹¹—O—, —R⁹²—O—C(═O)— or —C(═O)—O—R⁹³—O—C(═O)—.

In the group represented by the formula X-Q¹-, the hydrocarbon group for X may be either an aromatic hydrocarbon group or an aliphatic hydrocarbon group.

The aromatic hydrocarbon group is a hydrocarbon group having an aromatic ring. The aromatic hydrocarbon group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Here, the number of carbon atoms within substituents is not included in the number of carbon atoms of the aromatic hydrocarbon group.

Specific examples of the aromatic hydrocarbon group include aryl groups, which are aromatic hydrocarbon rings having one hydrogen atom removed therefrom, such as a phenyl group, biphenylyl group, fluorenyl group, naphthyl group, anthryl group and phenanthryl group, and arylalkyl groups such as a benzyl group, phenethyl group, 1-naphthylmethyl group, 2-naphthylmethyl group, 1-naphthylethyl group and 2-naphthylethyl group. The alkyl chain within the arylalkyl group preferably has 1 to 4 carbon atoms, more preferably 1 or 2 carbon atoms, and most preferably 1 carbon atom.

The aromatic hydrocarbon group may have a substituent. For example, some of the carbon atoms that constitute the aromatic ring within the aromatic hydrocarbon group may be substituted with a hetero atom, or a hydrogen atom bonded to the aromatic ring within the aromatic hydrocarbon group may be substituted with a substituent.

Examples of the former case include heteroaryl groups in which some of the carbon atoms that constitute the ring within an aforementioned aryl group have been substituted with a hetero atom such as an oxygen atom, a sulfur atom or a nitrogen atom, and heteroarylalkyl groups in which some of the carbon atoms that constitute the aromatic hydrocarbon ring within an aforementioned arylalkyl group have been substituted with an aforementioned hetero atom.

In the latter case, examples of the substituent for the aromatic hydrocarbon group include an alkyl group, alkoxy group, halogen atom, halogenated alkyl group, hydroxyl group or oxygen atom (═O) or the like.

The alkyl group as the substituent for the aromatic hydrocarbon group is preferably an alkyl group of 1 to 5 carbon atoms, and a methyl group, ethyl group, propyl group, n-butyl group or tert-butyl group is the most desirable.

The alkoxy group as the substituent for the aromatic hydrocarbon group is preferably an alkoxy group of 1 to 5 carbon atoms, is more preferably a methoxy group, ethoxy group, n-propoxy group, iso-propoxy group, n-butoxy group or tert-butoxy group, and is most preferably a methoxy group or an ethoxy group.

Examples of the halogen atom as the substituent for the aromatic hydrocarbon group include a fluorine atom, chlorine atom, bromine atom and iodine atom, and a fluorine atom is preferable.

Examples of the halogenated alkyl group as the substituent for the aromatic hydrocarbon group include groups in which some or all of the hydrogen atoms within an aforementioned alkyl group have each been substituted with an aforementioned halogen atom.

The aliphatic hydrocarbon group for X may be either a saturated aliphatic hydrocarbon group or an unsaturated aliphatic hydrocarbon group. Further, the aliphatic hydrocarbon group may be linear, branched or cyclic.

In the aliphatic hydrocarbon group for X, some of the carbon atoms that constitute the aliphatic hydrocarbon group may be substituted with a substituent containing a hetero atom, and/or some or all of the hydrogen atoms that constitute the aliphatic hydrocarbon group may each be substituted with a substituent containing a hetero atom.

There are no particular limitations on this “hetero atom” within X, provided it is an atom other than a carbon atom or a hydrogen atom. Examples of the hetero atom include a halogen atom, oxygen atom, sulfur atom and nitrogen atom. Examples of the halogen atom include a fluorine atom, chlorine atom, iodine atom and bromine atom.

The substituent containing a hetero atom may consist solely of the hetero atom, or may be a group that also contains a group or atom other than a hetero atom. Specific examples of the substituent for substituting some of the carbon atoms include —O—, —C(═O)—O—, —C(═O)—, —O—C(═O)—O—, —C(═O)—NH—, —NH— (wherein H may be substituted with a substituent such as an alkyl group or an acyl group), —S—, —S(═O)₂— and —S(═O)₂—O—. When the aliphatic hydrocarbon group is cyclic, any of these substituents may be included within the ring structure of the aliphatic hydrocarbon group.

Examples of the substituent for substituting some or all of the hydrogen atoms include an alkoxy group, halogen atom, halogenated alkyl group, hydroxyl group, oxygen atom (═O) and cyano group.

The alkoxy group is preferably an alkoxy group of 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom include a fluorine atom, chlorine atom, bromine atom and iodine atom, and a fluorine atom is preferable.

Examples of the halogenated alkyl group include groups in which some or all of the hydrogen atoms within an alkyl group of 1 to 5 carbon atoms (such as a methyl group, ethyl group, propyl group, n-butyl group or tert-butyl group) have each been substituted with an aforementioned halogen atom.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably contains 1 to 20 carbon atoms, more preferably 1 to 15 carbon atoms, and most preferably 1 to 10 carbon atoms. Specific examples include a methyl group, ethyl group, propyl group, butyl group, pentyl group, hexyl group, heptyl group, octyl group, nonyl group, decyl group, undecyl group, dodecyl group, tridecyl group, isotridecyl group, tetradecyl group, pentadecyl group, hexadecyl group, isohexadecyl group, heptadecyl group, octadecyl group, nonadecyl group, eicosyl group, heneicosyl group and docosyl group.

The branched saturated hydrocarbon group (alkyl group) preferably contains 3 to 20 carbon atoms, more preferably 3 to 15 carbon atoms, and most preferably 3 to 10 carbon atoms. Specific examples include a 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group and 4-methylpentyl group.

The unsaturated hydrocarbon group preferably contains 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (allyl group) and a butynyl group. Examples of branched monovalent unsaturated hydrocarbon groups include a 1-methylpropenyl group and a 2-methylpropenyl group.

Among the above examples, a propenyl group is particularly desirable as the unsaturated hydrocarbon group.

The aliphatic cyclic group may be either a monocyclic group or a polycyclic group. The aliphatic cyclic group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms.

Examples of the aliphatic cyclic group include groups in which one or more hydrogen atoms have been removed from a monocycloalkane, and groups in which one or more hydrogen atoms have been removed from a polycycloalkane such as a bicycloalkane, tricycloalkane or tetracycloalkane. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent in the ring structure, the aliphatic cyclic group is preferably a polycyclic group, more preferably a group in which one or more hydrogen atoms have been removed from a polycycloalkane, and most preferably a group in which one or more hydrogen atoms have been removed from adamantane.

When the aliphatic cyclic group contains a hetero atom-containing substituent in the ring structure, the hetero atom-containing substituent is preferably —O—, —C(═O)—O—, —S—, —S(═O)₂— or —S(═O)₂—O—. Specific examples of such aliphatic cyclic groups include the groups represented by formulas (L1) to (L6) and (S1) to (S4) shown below.

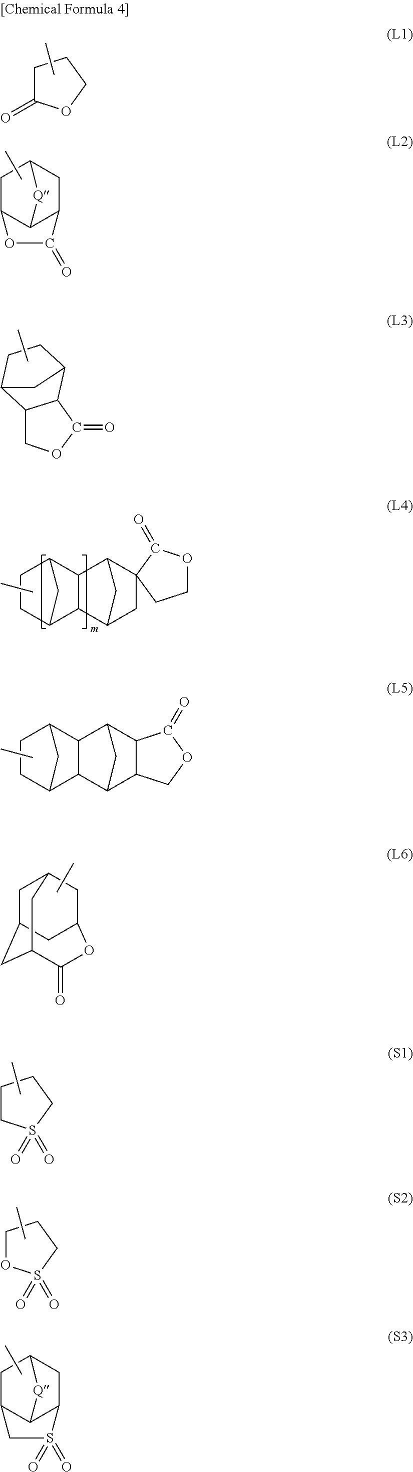

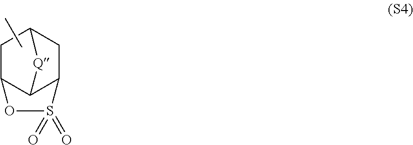

In the formulas, Q″ represents an alkylene group of 1 to 5 carbon atoms, —O—, —S—, —O—R⁹⁴— or —S—R⁹⁵— (wherein each of R⁹⁴ and R⁹⁵ independently represents an alkylene group of 1 to 5 carbon atoms), and m represents 0 or 1.

Examples of the alkylene groups for Q″, R⁹⁴ and R⁹⁵ include the same alkylene groups as those described above for R⁹¹ to R⁹³.

In these aliphatic cyclic groups, some of the hydrogen atoms bonded to the carbon atoms that constitute the ring structure may each be substituted with a substituent. Examples of this substituent include an alkyl group, alkoxy group, halogen atom, halogenated alkyl group, hydroxyl group or oxygen atom (═O).

As the alkyl group, an alkyl group of 1 to 5 carbon atoms is preferable, and a methyl group, ethyl group, propyl group, n-butyl group or tert-butyl group is particularly desirable.

Examples of the alkoxy group and the halogen atom include the same groups and atoms as those listed above for the substituent used for substituting some or all of the hydrogen atoms.

Among the various possibilities described above, X is preferably a cyclic group which may have a substituent. This cyclic group may be either an aromatic hydrocarbon group which may have a substituent, or an aliphatic cyclic group which may have a substituent, although an aliphatic cyclic group which may have a substituent is preferable.

As the aromatic hydrocarbon group, a naphthyl group which may have a substituent or a phenyl group which may have a substituent is preferable.

As the aliphatic cyclic group which may have a substituent, a polycyclic aliphatic cyclic group which may have a substituent is preferable. As this polycyclic aliphatic cyclic group, groups in which one or more hydrogen atoms have been removed from an aforementioned polycycloalkane, and groups represented by the above formulas (L2) to (L5), and (S3) and (S4) are preferable.

Further, X is preferably a group containing a polar region, as such groups yield improved lithography properties and a superior resist pattern shape.

Examples of these groups containing a polar region include groups in which a portion of the carbon atoms that constitute the aliphatic cyclic group of an aforementioned group X have been substituted with a substituent containing a hetero atom, namely with a substituent such as —O—, —C(═O)—O—, —C(═O)—, —O—C(═O)—O—, —C(═O)—NH—, —NH— (wherein H may be substituted with a substituent such as an alkyl group or acyl group), —S—, —S(═O)₂— or —S(═O)₂—O.

R⁴″ is preferably a group having X-Q¹- as a substituent. In such cases, R⁴″ is preferably a group represented by the formula X— Q¹-Y¹- (wherein Q¹ and X are the same as defined above, and Y¹ represents an alkylene group of 1 to 4 carbon atoms which may have a substituent, or a fluorinated alkylene group of 1 to 4 carbon atoms which may have a substituent).

In the group represented by the formula X-Q¹-Y¹-, examples of the alkylene group represented by Y¹ include those alkylene groups described above for Q¹ in which the number of carbon atoms is within a range from 1 to 4.

Examples of the fluorinated alkylene group for Y¹ include groups in which some or all of the hydrogen atoms of an aforementioned alkylene group have each been substituted with a fluorine atom.

Specific examples of Y¹ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—, —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)— and —C(CH₃)(CH₂CH₃)—.

Y¹ is preferably a fluorinated alkylene group, and particularly preferably a fluorinated alkylene group in which the carbon atom bonded to the adjacent sulfur atom is fluorinated. In such cases, a strong acid having a high acid strength is generated from the acid generator component. As a result, a resist pattern of finer dimensions is formed. Furthermore, the resolution, resist pattern shape and lithography properties also improve.

Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The expression that the alkylene group or fluorinated alkylene group “may have a substituent” means that some or all of the hydrogen atoms or fluorine atoms in the alkylene group or fluorinated alkylene group may each be substituted, either with an atom other than a hydrogen atom or fluorine atom, or with a group.

Examples of substituents with which the alkylene group or fluorinated alkylene group may be substituted include alkyl groups of 1 to 4 carbon atoms, alkoxy groups of 1 to 4 carbon atoms, and a hydroxyl group.

In the above formula (b-2), each of R⁵″ and R⁶″ independently represents an aryl group or an alkyl group. At least one of R⁵″ and R⁶″ represents an aryl group, and it is preferable that both of R⁵″ and R⁶″ are aryl groups.

Examples of the aryl group for R⁵″ and R⁶″ include the same aryl groups as those described for R¹− to R³″.

Examples of the alkyl group for R⁵″ and R⁶″ include the same alkyl groups as those described for R¹″ to R³″.

Among the various possibilities, the case in which R⁵″ and R⁶″ are both phenyl groups is the most desirable.

Examples of R⁴″ within formula (b-2) include the same groups as those described above for R⁴″ within formula (b-1).

Specific examples of the onium salt acid generators represented by formula (b-1) or (b-2) include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, diphenylmonomethylsulfonium trifluoromethanesulfonate, heptafluoropropanesulfonate or nonafluorobutanesulfonate, (4-methylphenyl)diphenylsulfonium trifluoromethanesulfonate, heptafluoropropanesulfonate or nonafluorobutanesulfonate, (4-methoxyphenyl)diphenylsulfonium trifluoromethanesulfonate, heptafluoropropanesulfonate or nonafluorobutanesulfonate, tri(4-tert-butyl)phenylsulfonium trifluoromethanesulfonate, heptafluoropropanesulfonate or nonafluorobutanesulfonate, diphenyl(1-(4-methoxy)naphthyl)sulfonium trifluoromethanesulfonate, heptafluoropropanesulfonate or nonafluorobutanesulfonate, di(1-naphthyl)phenylsulfonium trifluoromethanesulfonate, heptafluoropropanesulfonate or nonafluorobutanesulfonate, 1-phenyltetrahydrothiophenium trifluoromethanesulfonate, heptafluoropropanesulfonate or nonafluorobutanesulfonate, 1-(4-methylphenyl)tetrahydrothiophenium trifluoromethanesulfonate, heptafluoropropanesulfonate or nonafluorobutanesulfonate, 1-(3,5-dimethyl-4-hydroxyphenyl)tetrahydrothiophenium trifluoromethanesulfonate, heptafluoropropanesulfonate or nonafluorobutanesulfonate, 1-(4-methoxynaphthalene-1-yl)tetrahydrothiophenium trifluoromethanesulfonate, heptafluoropropanesulfonate or nonafluorobutanesulfonate, 1-(4-ethoxynaphthalene-1-yl)tetrahydrothiophenium trifluoromethanesulfonate, heptafluoropropanesulfonate or nonafluorobutanesulfonate, 1-(4-n-butoxynaphthalene-1-yl)tetrahydrothiophenium trifluoromethanesulfonate, heptafluoropropanesulfonate or nonafluorobutanesulfonate, 1-phenyltetrahydrothiopyranium trifluoromethanesulfonate, heptafluoropropanesulfonate or nonafluorobutanesulfonate, 1-(4-hydroxyphenyl)tetrahydrothiopyranium trifluoromethanesulfonate, heptafluoropropanesulfonate or nonafluorobutanesulfonate, 1-(3,5-dimethyl-4-hydroxyphenyptetrahydrothiopyranium trifluoromethanesulfonate, heptafluoropropanesulfonate or nonatluorobutanesulfonate, and 1-(4-methylphenyl)tetrahydrothiopyranium trifluoromethanesulfonate, heptafluoropropanesulfonate or nonafluorobutanesulfonate.

It is also possible to use onium salts in which the anion moiety of any of these onium salts has either been replaced by an alkylsulfonate such as methanesulfonate, n-propanesulfonate, n-butanesulfonate, n-octanesulfonate, 1-adamantanesulfonate or 2-norbornanesulfonate, or been replaced by a sulfonate such as d-camphor-10-sulfonate, benzenesulfonate, perfluorobenzenesulfonate or p-toluenesulfonate.

Further, onium salts in which the anion moiety of any of these onium salts has been replaced by an anion moiety represented by any one of formulas (b1) to (b8) shown below can also be used.

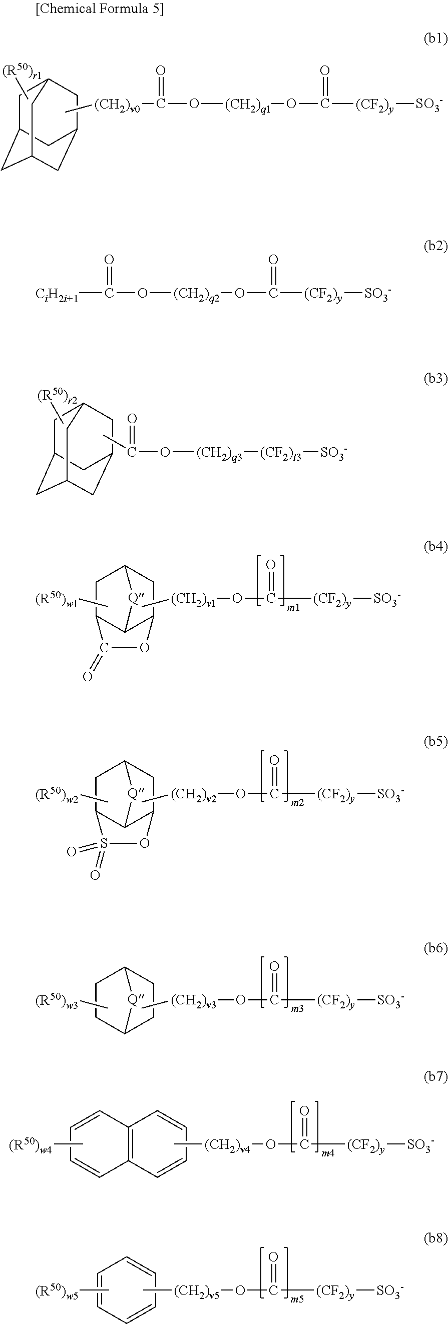

In the formulas, y represents an integer of 1 to 3, each of q1 and q2 independently represents an integer of 1 to 5, q3 represents an integer of 1 to 12, t3 represents an integer of 1 to 3, each of r1 and r2 independently represents an integer of 0 to 3, i represents an integer of 1 to 20, R⁵⁰ represents a substituent, each of m1 to m5 independently represents 0 or 1, each of v0 to v5 independently represents an integer of 0 to 3, each of w1 to w5 independently represents an integer of 0 to 3, and Q″ is the same as defined above.

Examples of the substituent R⁵⁰ include the same groups as those which the aforementioned aliphatic hydrocarbon group or aromatic hydrocarbon group for X may have as a substituent.

If there are two or more R⁵⁰ groups, as indicated by the values r1, r2, and w1 to w5, then the plurality of R⁵⁰ groups within the compound may be the same or different.

Further, onium salt acid generators in which the anion moiety (R⁴″SO₃⁻) in the above general formula (b-1) or (b-2) has been replaced with an anion moiety represented by general formula (b-3) or (b-4) shown below (but in which the cation moiety is the same as the cation shown in formula (b-1) or (b-2)) can also be used favorably as the onium salt acid generator.

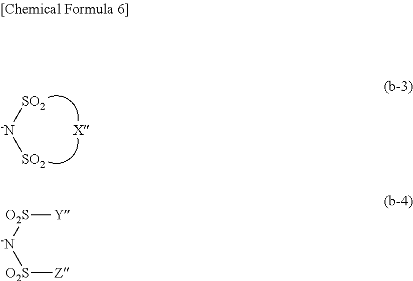

In the formulas, X″ represents an alkylene group of 2 to 6 carbon atoms in which at least one hydrogen atom has been substituted with a fluorine atom, and each of Y″ and Z″ independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, wherein the alkylene group contains 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, wherein the alkyl group contains 1 to 10 carbon atoms, preferably 1 to 7 carbon atoms, and more preferably 1 to 3 carbon atoms.

The smaller the number of carbon atoms in the alkylene group for X″ or the alkyl group for Y″ and Z″ within the aforementioned ranges of the number of carbon atoms, the more the solubility in a resist solvent is improved, and therefore a smaller number of carbon atoms is preferred.

Further, in the alkylene group for X″ or the alkyl group for Y″ and Z″, it is preferable that the number of hydrogen atoms substituted with fluorine atoms is as large as possible, because the acid strength increases and the transparency to high-energy radiation of 200 nm or less and electron beams is improved.

The proportion of fluorine atoms within the alkylene group or alkyl group, namely the fluorination ratio, is preferably within a range from 70 to 100%, and more preferably from 90 to 100%. A perfluoroalkylene or perfluoroalkyl group in which all the hydrogen atoms are substituted with fluorine atoms is the most desirable.

As the onium salt acid generator, onium salts of the above general formula (b-1) or (b-2) in which the anion moiety (R⁴″SO₃⁻) has been substituted with R^{a}—COO⁻ (wherein R^{a} represents an alkyl group or a fluorinated alkyl group) (and in which the cation moiety is the same as that of general formula (b-1) or (b-2)) may also be used.

Examples of R^{a} in the above formula include the same groups as those listed above for R⁴″.

Specific examples of R^{a}—COO⁻ include a trifluoroacetate ion, an acetate ion, and a 1-adamantanecarboxylate ion.

Furthermore, a sulfonium salt having a cation moiety represented by general formula (b-5) or (b-6) shown below may also be used as an onium salt acid generator.

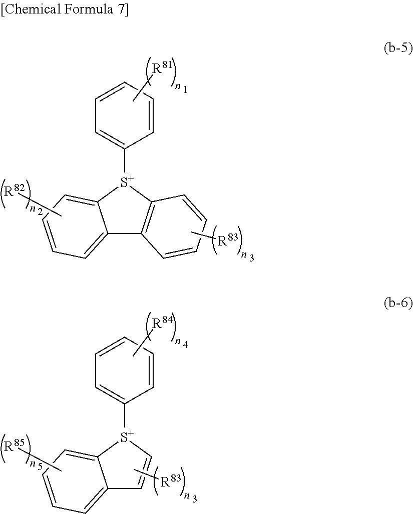

In the above formulas, each of R⁸¹ to R⁸⁶ independently represents an alkyl group, acetyl group, alkoxy group, carboxyl group, hydroxyl group or hydroxyalkyl group, each of n₁ to n₅ independently represents an integer of 0 to 3, and n₆ represents an integer of 0 to 2.

The alkyl group for R⁸¹ to R⁸⁶ is preferably an alkyl group of 1 to 5 carbon atoms, more preferably a linear or branched alkyl group, and most preferably a methyl group, ethyl group, propyl group, isopropyl group, n-butyl group or tert-butyl group.

The alkoxy group is preferably an alkoxy group of 1 to 5 carbon atoms, more preferably a linear or branched alkoxy group, and most preferably a methoxy group or ethoxy group.

The hydroxyalkyl group is preferably an aforementioned alkyl group in which one or more hydrogen atoms have each been substituted with a hydroxyl group, and specific examples include a hydroxymethyl group, hydroxyethyl group and hydroxypropyl group.

When the subscripts n₁ to n₆ appended to R⁸¹ to R⁸⁶ represent an integer of 2 or more, the plurality of R⁸¹ to R⁸⁶ groups may be the same or different.

n₁ is preferably 0 to 2, more preferably 0 or 1, and still more preferably 0.

It is preferable that each of n₂ and n₃ independently represents 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

There are no particular limitations on the anion moiety of the sulfonium salt having a cation moiety represented by formula (b-5) or (b-6), and the same anion moieties as those used within conventionally proposed onium salt acid generators may be used. Examples of such anion moieties include fluorinated alkylsulfonate ions such as the anion moieties (R⁴″SO₃⁻) of the onium salt acid generators represented by general formula (b-1) or (b-2) shown above, and anion moieties represented by general formula (b-3) or (b-4) shown above.

In the present description, an oxime sulfonate acid generator is a compound having at least one group represented by general formula (B-1) shown below, and has a feature of generating acid upon irradiation (exposure). Such oxime sulfonate acid generators are widely used for chemically amplified resist compositions, and any of these known compounds may be selected as appropriate.

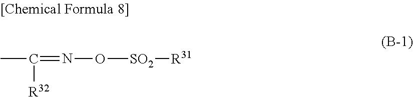

In formula (B-1), each of R³¹ and R³² independently represents an organic group.

The organic group for R³¹ and R³² refers to a group which contains a carbon atom, and may also include atoms other than the carbon atom (such as a hydrogen atom, oxygen atom, nitrogen atom, sulfur atom or halogen atom (such as a fluorine atom or chlorine atom) or the like).

As the organic group for R³¹, a linear, branched or cyclic alkyl group or aryl group is preferable. The alkyl group or aryl group may have a substituent. There are no particular limitations on the substituent, and examples include a fluorine atom or a linear, branched or cyclic alkyl group having 1 to 6 carbon atoms. The expression that the alkyl group or aryl group “may have a substituent” means that some or all of the hydrogen atoms of the alkyl group or aryl group may each be substituted with a substituent.

The alkyl group for R³¹ preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. A “partially halogenated alkyl group” refers to an alkyl group in which some of the hydrogen atoms are each substituted with a halogen atom, whereas a “completely halogenated alkyl group” refers to an alkyl group in which all of the hydrogen atoms are substituted with halogen atoms. Examples of the halogen atom include a fluorine atom, chlorine atom, bromine atom or iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, a partially or completely halogenated aryl group is particularly desirable. A “partially halogenated aryl group” refers to an aryl group in which some of the hydrogen atoms are each substituted with a halogen atom, whereas a “completely halogenated aryl group” refers to an aryl group in which all of hydrogen atoms are substituted with halogen atoms.

As the organic group for R³¹, an alkyl group of 1 to 4 carbon atoms which has no substituent, or a fluorinated alkyl group of 1 to 4 carbon atoms is particularly desirable.

As the organic group for R³², a linear, branched or cyclic alkyl group, an aryl group, or a cyano group is preferable. Examples of the alkyl group and the aryl group for R³² include the same alkyl groups and aryl groups as those described above for R³¹.

As R³², a cyano group, an alkyl group of 1 to 8 carbon atoms having no substituent, or a fluorinated alkyl group of 1 to 8 carbon atoms is particularly desirable.

Preferred examples of the oxime sulfonate acid generator include compounds represented by general formula (B-2) or (B-3) shown below.

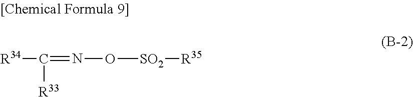

In formula (B-2), R³³ represents a cyano group, an alkyl group having no substituent or a halogenated alkyl group, R³⁴ represents an aryl group, and R³⁵ represents an alkyl group having no substituent or a halogenated alkyl group.

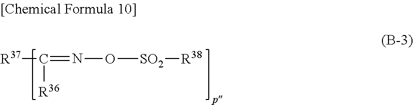

In formula (B-3), R³⁶ represents a cyano group, an alkyl group having no substituent or a halogenated alkyl group, R³⁷ represents a divalent or trivalent aromatic hydrocarbon group, R³⁸ represents an alkyl group having no substituent or a halogenated alkyl group, and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more fluorinated, and most preferably 90% or more fluorinated.

Examples of the aryl group for R³⁴ include groups in which one hydrogen atom has been removed from an aromatic hydrocarbon ring, such as a phenyl group, biphenylyl group, fluorenyl group, naphthyl group, anthryl group or phenanthryl group, and heteroaryl groups in which some of the carbon atoms constituting the ring(s) of these groups are substituted with a hetero atom such as an oxygen atom, a sulfur atom or a nitrogen atom. Of these, a fluorenyl group is preferable.

The aryl group for R³⁴ may have a substituent such as an alkyl group, a halogenated alkyl group or an alkoxy group of 1 to 10 carbon atoms. The alkyl group or halogenated alkyl group as the substituent preferably contains 1 to 8 carbon atoms, and more preferably 1 to 4 carbon atoms. The halogenated alkyl group is preferably a fluorinated alkyl group.

The alkyl group having no substituent or the halogenated alkyl group for R³⁵ preferably contains 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms within the alkyl group fluorinated, more preferably 70% or more fluorinated, and still more preferably 90% or more fluorinated. A completely fluorinated alkyl group in which 100% of the hydrogen atoms have been substituted with fluorine atoms is particularly desirable.

In general formula (B-3), examples of the alkyl group having no substituent and the halogenated alkyl group for R³⁶ include the same groups as those described above for the alkyl group having no substituent and the halogenated alkyl group for R³³.

Examples of the divalent or trivalent aromatic hydrocarbon group for R³⁷ include groups in which an additional one or two hydrogen atoms respectively have been removed from the aryl group for R³⁴.

Examples of the alkyl group having no substituent or the halogenated alkyl group for R³⁸ include the same groups as those described above for the alkyl group having no substituent or the halogenated alkyl group for R³⁵.

p″ is preferably 2.

Specific examples of oxime sulfonate acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyl oxyimino)-1-cyclohexenyl acetonitrile, α-(n-butylsulfonyloxyimino)-1-cyclohexenyl acetonitrile, α-(methylsulfonyloxyimino)-phenyl acetonitrile, (methyl sulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate acid generators disclosed in Japanese Unexamined Patent Application, First Publication No. Hei 09-208554 (Chemical Formulas 18 and 19 shown in paragraphs [0012] to [0014]) and oxime sulfonate acid generators disclosed in International Patent Publication No. 04/074242 pamphlet (Examples 1 to 40 described on pages 65 to 85) may also be used favorably.

Furthermore, the following compounds may also be used as preferred examples.

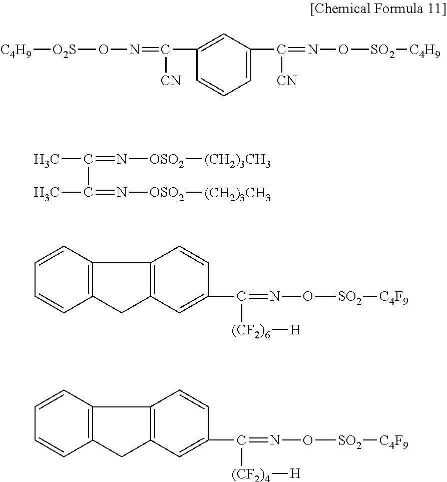

Of the aforementioned diazomethane acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may also be used favorably.

Furthermore, examples of poly(bis-sulfonyl)diazomethanes include those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane.

Moreover, compounds such as N,N-dimethyl-N-hydroxyethylamine p-decyl-phenylsulfonate, 2,4,4,6-tetrabromocyclohexadienone, benzoin tosylate and 2-nitrobenzyl tosylate can also be used favorably as the acid generator component.

Among the above compounds, particularly preferred thermal acid generators that generate acid upon heating at 130° C. or higher include:

bis(1,1-dimethylethylsulfonyl)diazomethane (a compound represented by chemical formula (TAG-1) shown below),

N,N-dimethyl-N-hydroxyethylamine p-decyl-phenylsulfonate (a compound represented by chemical formula (TAG-2) shown below),

2,4,4,6-tetrabromocyclohexadienone, benzoin tosylate, and 2-nitrobenzyl tosylate.

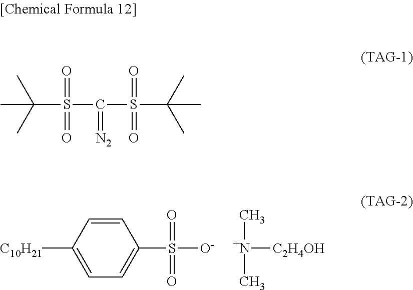

In the pattern miniaturization agent, a single acid generator component may be used alone, or a combination of two or more acid generators may be used.

In the pattern miniaturization agent of the present invention, the amount of the acid generator component is preferably within a range from 0.01 to 5% by weight, more preferably from 0.025 to 1% by weight, and still more preferably from 0.05 to 0.50% by weight.

Provided that the amount of the acid generator component is at least as large as the lower limit of the above range, an appropriate solubility of the resist pattern in the alkali developing solution can be achieved by application of a predetermined amount of the pattern miniaturization agent. On the other hand, provided that the amount of the acid generator component is not more than the upper limit of the above range, the resist pattern does not dissolve excessively in the alkali developing solution upon application of a predetermined amount of the pattern miniaturization agent, and excessive variation in the dimensions of the resist pattern can be avoided.

(Organic Solvent that does not Dissolve the Resist Pattern Formed in Step (1))

In the present invention, the expression “does not dissolve the resist pattern” means that when the chemically amplified positive-type resist composition is applied to the support and dried under conditions at 23° C. to form a resist film having a thickness of 0.2 μm, and this resist film is then immersed in the organic solvent, even after 60 minutes immersion, the resist film does not disappear, nor undergo any marked variation in the film thickness (the resist film thickness preferably does not reduce below 0.16 μm).

Including this organic solvent that does not dissolve the resist pattern means that when the pattern miniaturization agent is applied to the resist pattern formed in the step (1), dissolution of the resist pattern by the organic solvent of the pattern miniaturization agent can be inhibited, thereby preventing deterioration or destruction of the shape of the resist pattern, and preventing mixing at the interface between the resist pattern and the pattern miniaturization agent.

Examples of this organic solvent that does not dissolve the resist pattern include any organic solvent that does not dissolve the resist pattern formed in the aforementioned step (1) [namely, the step (I-1) or (II-1)], but is able to dissolve the aforementioned acid generator component. Among such solvents, this organic solvent that does not dissolve the resist pattern preferably includes at least one solvent selected from the group consisting of alcohol-based organic solvents, fluorine-based organic solvents, and ether-based organic solvents not having a hydroxyl group. Of these organic solvents, from the viewpoints of the coating properties on the support, and the solubility of the acid generator component contained within the pattern miniaturization agent, an alcohol-based organic solvent is particularly desirable.

Here, an “alcohol-based organic solvent” describes a compound in which at least one hydrogen atom of an aliphatic hydrocarbon has been substituted with a hydroxyl group, and which is a liquid under normal temperature and pressure conditions. The structure of the main chain that constitutes the aliphatic hydrocarbon may be a chain-like structure, a cyclic structure, a chain-like structure that incorporates a cyclic structure, or a chain-like structure that incorporates an ether linkage.

A “fluorine-based organic solvent” describes a compound containing a fluorine atom which is a liquid under normal temperature and pressure conditions.

An “ether-based organic solvent not having a hydroxyl group” describes a compound having an ether linkage (C—O—C) within the structure, which does not have a hydroxyl group, and which is a liquid under normal temperature and pressure conditions. The ether-based organic solvent not having a hydroxyl group preferably also does not contain a carbonyl group.

The alcohol-based organic solvent is preferably a monohydric alcohol, a dihydric alcohol, or a derivative of a dihydric alcohol or the like.

As the monohydric alcohol, a primary or secondary monohydric alcohol is preferred depending on the number of carbon atoms within the compound, and a primary monohydric alcohol is the most desirable.

Here, a “monohydric alcohol” describes a compound in which one hydrogen atom within a hydrocarbon compound composed solely of carbon and hydrogen has been substituted with a hydroxyl group. This definition excludes derivatives of dihydric or higher polyhydric alcohols. The aforementioned hydrocarbon compound may have either a chain-like structure or a cyclic structure.

A “dihydric alcohol” describes a compound in which two hydrogen atoms within an aforementioned hydrocarbon compound have been substituted with hydroxyl groups, and excludes derivatives of trihydric or higher polyhydric alcohols.

Derivatives of dihydric alcohols include compounds in which one of the hydroxyl groups within a dihydric alcohol has been substituted with a substituent (such as an alkoxy group or alkoxyalkyloxy group).

The boiling point (under normal pressure) of the alcohol-based organic solvent is preferably within a range from 50 to 160° C., and more preferably from 65 to 150° C. From the viewpoints of coatability, stability of the composition upon storage, and the heating temperature during the bake treatment, the boiling point is most preferably within a range from 75 to 135° C.

Specific examples of the alcohol-based organic solvent include compounds having a chain-like structure, such as propylene glycol (PG), 1-butoxy-2-propanol (PGB), n-hexanol, 2-heptanol, 3-heptanol, 1-heptanol, 5-methyl-1-hexanol, 6-methyl-2-heptanol, 1-octanol, 2-octanol, 3-octanol, 4-octanol, 2-ethyl-1-hexanol, 2-(2-butoxyethoxy)ethanol, n-pentyl alcohol, s-pentyl alcohol, t-pentyl alcohol, isopentyl alcohol, isobutanol (also called isobutyl alcohol or 2-methyl-1-propanol), isopropyl alcohol, 2-ethylbutanol, neopentyl alcohol, n-butanol, s-butanol, t-butanol, 1-propanol, 2-methyl-1-butanol, 2-methyl-2-butanol, 4-methyl-2-pentanol, ethanol and methanol.

Further, examples of compounds having a cyclic structure include cyclopentanemethanol, 1-cyclopentylethanol, cyclohexanol, cyclohexanemethanol (CM), cyclohexaneethanol, 1,2,3,6-tetrahydrobenzyl alcohol, exo-norborneol, 2-methylcyclohexanol, cycloheptanol, 3,5-dimethylcyclohexanol and benzyl alcohol.

Among the various alcohol-based organic solvents, monohydric alcohols having a chain-like structure or derivatives of dihydric alcohols are preferred, 1-butoxy-2-propanol (PGB), isobutanol (2-methyl-1-propanol), 4-methyl-2-pentanol, n-butanol and ethanol are more preferred, and ethanol is the most desirable.

An example of a fluorine-based solvent is perfluoro-2-butyltetrahydrofuran.

Examples of preferred ether-based organic solvents not having a hydroxyl group include compounds represented by general formula (s-1) shown below.

R⁴⁰—O—R⁴¹ (s-1)

In this formula, each of R⁴⁰ and R⁴¹ independently represents a monovalent hydrocarbon group. Alternatively, R⁴⁰ and R⁴¹ may be bonded together to form a ring. —O— represents an ether linkage.

In the above formula, examples of the hydrocarbon group for R⁴⁰ and R⁴¹ include alkyl groups and aryl groups, and alkyl groups are preferred. Of the various possibilities, compounds in which R⁴⁰ and R⁴¹ are both alkyl groups are preferred, and compounds in which R⁴⁰ and R⁴¹ represent the same alkyl group are particularly desirable.

There are no particular limitations on the alkyl group for each of R⁴⁰ and R⁴¹, and examples include linear, branched or cyclic alkyl groups of 1 to 20 carbon atoms. In the alkyl group, some or all of the hydrogen atoms may or may not each be substituted with a halogen atom.

In terms of achieving favorable coating properties for the pattern miniaturization agent, the alkyl group preferably contains 1 to 15 carbon atoms, and more preferably 1 to 10 carbon atoms. Specific examples of the alkyl group include an ethyl group, propyl group, isopropyl group, n-butyl group, isobutyl group, n-pentyl group, isopentyl group, cyclopentyl group and hexyl group, and of these, an n-butyl group or isopentyl group is particularly desirable.

The halogen atom with which a hydrogen atom of the alkyl group may be substituted is preferably a fluorine atom.

There are no particular limitations on the aryl group for each of R⁴⁰ and R⁴¹, and examples include aryl groups of 6 to 12 carbon atoms, wherein some or all of the hydrogen atoms within the aryl group may or may not each be substituted with an alkyl group, alkoxy group or halogen atom or the like.

In terms of enabling low-cost synthesis, an aryl group of 6 to 10 carbon atoms is preferred. Specific examples of such aryl groups include a phenyl group, benzyl group and naphthyl group.

The alkyl group with which a hydrogen atom of the aryl group may be substituted is preferably an alkyl group of 1 to 5 carbon atoms, and more preferably a methyl group, ethyl group, propyl group, n-butyl group or tert-butyl group.

The alkoxy group with which a hydrogen atom of the aryl group may be substituted is preferably an alkoxy group of 1 to 5 carbon atoms, and more preferably a methoxy group or an ethoxy group.

The halogen atom with which a hydrogen atom of the aryl group may be substituted is preferably a fluorine atom.

Further, in the above formula, R⁴⁰ and R⁴¹ may be bonded together to form a ring. In such a case, each of R⁴⁰ and R⁴¹ independently represents a linear or branched alkylene group (and preferably an alkylene group of 1 to 10 carbon atoms), and R⁴⁰ and R⁴¹ are bonded together to form a ring. Further, a carbon atom within the alkylene group may be substituted with an oxygen atom.

Specific examples of this type of ether-based organic solvent include 1,8-cineole, tetrahydrofuran and dioxane.

Furthermore, the boiling point (under normal pressure) of the ether-based organic solvent not having a hydroxyl group is preferably within a range from 30 to 300° C., more preferably from 100 to 200° C., and still more preferably from 140 to 180° C. Ensuring that the boiling point is at least as high as the lower limit of the above temperature range means coating irregularities upon application of the pattern miniaturization agent can be suppressed, resulting in improved coating properties. On the other hand, ensuring that the boiling point is not more than the upper limit of the above range is preferred in terms of the heating temperature required during the bake treatment, as it enables the ether-based organic solvent to be satisfactorily removed from the resist film during the bake treatment.

Specific examples of the ether-based organic solvent not having a hydroxyl group include 1,8-cineole (boiling point: 176° C.), dibutyl ether (boiling point: 142° C.), diisopentyl ether (boiling point: 171° C.), dioxane (boiling point: 101° C.), anisole (boiling point: 155° C.), ethyl benzyl ether (boiling point: 189° C.), diphenyl ether (boiling point: 259° C.), dibenzyl ether (boiling point: 297° C.), phenetole (boiling point: 170° C.), butyl phenyl ether, tetrahydrofuran (boiling point: 66° C.), ethyl propyl ether (boiling point: 63° C.), diisopropyl ether (boiling point: 69° C.), dihexyl ether (boiling point: 226° C.), and dipropyl ether (boiling point: 91° C.).

As the ether-based organic solvent not having a hydroxyl group, a cyclic or chain-like ether-based organic solvent is preferred in terms of achieving a favorable effect in terms of inhibiting dissolution of the resist pattern, and of such solvents, at least one organic solvent selected from the group consisting of 1,8-cineole, dibutyl ether and diisopentyl ether is particularly preferred.

In the pattern miniaturization agent, a single organic solvent that does not dissolve the resist pattern may be used alone, or a combination of two or organic solvents may be used.

In the pattern miniaturization agent of the present invention, there are no particular limitations on the amount of the organic solvent that does not dissolve the resist pattern, and typically, an amount of solvent is used that is sufficient to prepare the pattern miniaturization agent as a liquid having a concentration that enables favorable application to the resist pattern. For example, the organic solvent may be used in an amount that yields a solid fraction concentration for the pattern miniaturization agent within a range from 1 to 30% by weight.

The pattern miniaturization agent may also include other components besides the acid generator component and the organic solvent that does not dissolve the resist pattern. Examples of these other components include surfactants and antioxidants.

### <Chemically Amplified Positive-Type Resist Composition>

The chemically amplified positive-type resist composition (hereafter also referred to as simply “the positive-type resist composition”) that can be used in the resist pattern formation method of the present invention contains an acid generator component (B) that generates acid upon exposure (hereafter referred to as “component (B)”) and a base component (A) having an acid-dissociable, dissolution-inhibiting group (hereafter referred to as “component (A)”), and may be selected appropriately from the multitude of chemically amplified positive-type resist compositions that have already been proposed.

In the positive-type resist composition, when acid is generated from the component (B) upon exposure, the action of the acid causes dissociation of the acid-dissociable, dissolution-inhibiting group of the component (A), thereby increasing the solubility of the component (A) in an alkali developing solution. Accordingly, by subjecting a resist film formed using the positive-type resist composition to selective exposure, the exposed portions become soluble in the alkali developing solution, whereas the unexposed portions remain insoluble in the alkali developing solution, meaning alkali developing can be used to remove only the exposed portions, thus forming a resist pattern.

### [Component (A)]

The component (A) is a base component having an acid-dissociable, dissolution-inhibiting group.

The term “base component” refers to an organic compound capable of forming a film. The base component is preferably an organic compound having a molecular weight of 500 or more. When the organic compound has a molecular weight of 500 or more, the film-forming ability is improved, and a resist pattern at the nano level can be more easily formed.

The “organic compounds having a molecular weight of 500 or more” that can be used as the base component are broadly classified into non-polymers and polymers.

In general, compounds which have a molecular weight of at least 500 but less than 4,000 may be used as non-polymers. Hereafter, the term “low-molecular weight compound” is used to describe a non-polymer having a molecular weight of at least 500 but less than 4,000.

In terms of the polymers, typically, compounds which have a molecular weight of 1,000 or more may be used. In the following description, a polymer having a molecular weight of 1,000 or more may be referred to as a “resin”.

For these polymers, the “molecular weight” refers to the polystyrene-equivalent weight-average molecular weight determined by gel permeation chromatography (GPC).

The component (A) may be a resin component (A1) that exhibits increased solubility in an alkali developing solution under the action of acid (hereafter frequently referred to as “component (A1)”), a low-molecular weight compound component (A2) that exhibits increased solubility in an alkali developing solution under the action of acid (hereafter frequently referred to as “component (A2)”), or a mixture thereof.

In the present invention, the component (A) preferably includes the component (A1).

Preferred forms of the component (A1) and the component (A2) are described below in further detail.

### [Component (A1)]

The component (A1) may be selected appropriately from among the various base resins proposed for conventional chemically amplified KrF positive-type resist compositions, ArF positive-type resist compositions, EB positive-type resist compositions and EUV positive-type resist compositions and the like, in accordance with the exposure source used during resist pattern formation.

Specific examples of these base resins include resins having hydrophilic groups (such as hydroxyl groups or carboxyl groups) in which these hydrophilic groups are protected with acid-dissociable, dissolution-inhibiting groups.

Examples of resins having hydrophilic groups include novolac resins, resins having a structural unit derived from a hydroxystyrene (PHS-based resins), in which an atom other than a hydrogen atom or a substituent may be bonded to the carbon atom on the α-position, such as polyhydroxystyrene (PHS) and hydroxystyrene-styrene copolymers, and acrylic resins having a structural unit derived from an acrylate ester in which an atom other than a hydrogen atom or a substituent may be bonded to the carbon atom on the α-position.

Any one of these resins may be used alone, or a combination of two or more resins may be used.

In the present invention, a “structural unit derived from a hydroxystyrene” is a structural unit that is formed by cleavage of the ethylenic double bond of a hydroxystyrene.

A “hydroxystyrene” describes a hydroxystyrene in which a hydrogen atom is bonded to the α-position carbon atom (the carbon atom to which the phenyl group is bonded).

The expression “hydroxystyrene in which an atom other than a hydrogen atom or a substituent may be bonded to the carbon atom on the α-position” includes not only the hydroxystyrene, but also compounds in which an atom or group other than a hydrogen atom is bonded to the α-position carbon atom, and derivatives of these compounds. Specifically, the above expression includes compounds in which at least the benzene ring and the hydroxyl group bonded to the benzene ring are retained, and in which, for example, the hydrogen atom bonded to the α-position of the hydroxystyrene is substituted with a substituent such as an alkyl group of 1 to 5 carbon atoms, a halogenated alkyl group of 1 to 5 carbon atoms or a hydroxyalkyl group or the like, and in which the benzene ring of the hydroxystyrene to which the hydroxyl group is bonded may also have an alkyl group of 1 to 5 carbon atoms bonded thereto, and/or the benzene ring to which the hydroxyl group is bonded may also include an additional one or two hydroxyl groups (so that the total number of hydroxyl groups is 2 or 3).

A “structural unit derived from an acrylate ester” is a structural unit that is formed by cleavage of the ethylenic double bond of an acrylate ester.

The term “acrylate ester” describes an acrylate ester in which a hydrogen atom is bonded to the carbon atom on the α-position (the carbon atom to which the carbonyl group of the acrylic acid is bonded).

The expression “acrylate ester in which an atom other than a hydrogen atom or a substituent may be bonded to the carbon atom on the α-position” includes not only the acrylate ester, but also compounds in which an atom or group other than a hydrogen atom is bonded to the α-position carbon atom.

In the expression “an atom other than a hydrogen atom or a substituent may be bonded to the carbon atom on the α-position”, examples of the atom other than a hydrogen atom include a halogen atom, whereas examples of the substituent include an alkyl group of 1 to 5 carbon atoms, a halogenated alkyl group of 1 to 5 carbon atoms, and a hydroxyalkyl group of 1 to 5 carbon atoms. Specific examples of the halogen atom include a fluorine atom, chlorine atom, bromine atom and iodine atom. Further, in a structural unit derived from an acrylate ester, the α-position (α-position carbon atom) refers to the carbon atom to which the carbonyl group is bonded, unless stated otherwise.

In the hydroxystyrene or acrylate ester, the alkyl group as the α-position substituent is preferably a linear or branched alkyl group, and specific examples include a methyl group, ethyl group, propyl group, isopropyl group, n-butyl group, isobutyl group, tert-butyl group, pentyl group, isopentyl group and neopentyl group.

Further, specific examples of the halogenated alkyl group as the α-position substituent include groups in which some or all of the hydrogen atoms of an aforementioned “alkyl group as the α-position substituent” have each been substituted with a halogen atom. Examples of the halogen atom include a fluorine atom, chlorine atom, bromine atom and iodine atom, and a fluorine atom is particularly desirable.

Furthermore, specific examples of the hydroxyalkyl group as the α-position substituent include groups in which some or all of the hydrogen atoms of an aforementioned “alkyl group as the α-position substituent” have each been substituted with a hydroxyl group. The number of hydroxyl groups in the hydroxyalkyl group is preferably within a range from 1 to 5, and is most preferably 1.

In the present invention, the moiety bonded to the α-position of the hydroxystyrene or acrylate ester is preferably a hydrogen atom, an alkyl group of 1 to 5 carbon atoms, or a halogenated alkyl group of 1 to 5 carbon atoms, is more preferably a hydrogen atom, an alkyl group of 1 to 5 carbon atoms, or a fluorinated alkyl group of 1 to 5 carbon atoms, and from the viewpoint of industrial availability, is most preferably a hydrogen atom or a methyl group.

In the present invention, the component (A1) in the positive-type resist composition preferably includes a structural unit derived from an acrylate ester in which an atom other than a hydrogen atom or a substituent may be bonded to the carbon atom on the α-position.

Among such compounds, the component (A1) preferably includes a structural unit (a1), which is derived from an acrylate ester in which an atom other than a hydrogen atom or a substituent may be bonded to the carbon atom on the α-position, and contains an acid-dissociable, dissolution-inhibiting group.

Further, in addition to the structural unit (a1), the component (A1) preferably also includes a structural unit (a2), which is derived from an acrylate ester in which an atom other than a hydrogen atom or a substituent may be bonded to the carbon atom on the α-position, and contains a lactone-containing cyclic group.

Furthermore, in addition to the structural unit (a1), the component (A1) preferably also includes a structural unit (a3), which is derived from an acrylate ester in which an atom other than a hydrogen atom or a substituent may be bonded to the carbon atom on the α-position, and contains a polar group-containing aliphatic hydrocarbon group.

Moreover, the component (A1) preferably also includes a structural unit (a0), which is derived from an acrylate ester in which an atom other than a hydrogen atom or a substituent may be bonded to the carbon atom on the α-position, and contains an —S(═O)₂-containing cyclic group.

In the present invention, the component (A1) may also include one or more other structural units besides the aforementioned structural units (a1) to (a3) and (a0).

—Structural Unit (a1):

The structural unit (a1) is a structural unit which is derived from an acrylate ester in which an atom other than a hydrogen atom or a substituent may be bonded to the carbon atom on the α-position, and contains an acid-dissociable, dissolution-inhibiting group.

The acid-dissociable, dissolution-inhibiting group in the structural unit (a1) has an alkali dissolution-inhibiting effect that renders the entire component (A1) insoluble in an alkali developing solution prior to dissociation, but then dissociates under the action of the acid generated from the component (B) upon exposure, causing an increase in the solubility of the entire component (A1) in an alkali developing solution.

As the acid-dissociable, dissolution-inhibiting group in the structural unit (a1), any of the groups that have already been proposed as acid-dissociable, dissolution-inhibiting groups for the base resins of chemically amplified resists can be used. Generally, groups that form either a cyclic or chain-like tertiary alkyl ester with the carboxyl group of the (meth)acrylic acid or the like, and acetal-type acid-dissociable, dissolution-inhibiting groups such as alkoxyalkyl groups are the most widely known.

The term “tertiary alkyl ester” describes a structure in which an ester is formed by substituting the hydrogen atom of a carboxyl group with a chain-like or cyclic alkyl group, and a tertiary carbon atom within the chain-like or cyclic alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid-dissociable, dissolution-inhibiting groups”.

Examples of tertiary alkyl ester-type acid-dissociable, dissolution-inhibiting groups include aliphatic branched acid-dissociable, dissolution-inhibiting groups and acid-dissociable, dissolution-inhibiting groups containing an aliphatic cyclic group.

Here, the term “aliphatic branched” refers to a branched structure having no aromaticity. The structure of the “aliphatic branched acid-dissociable, dissolution-inhibiting group” is not limited to groups constituted of only carbon and hydrogen (not limited to hydrocarbon groups), but is preferably a hydrocarbon group. Further, the “hydrocarbon group” may be either saturated or unsaturated, but in most cases, is preferably saturated.

Examples of the aliphatic branched, acid-dissociable, dissolution-inhibiting group include groups represented by the formula —C(R⁷¹)(R⁷²)(R⁷³). In this formula, each of R⁷¹ to R⁷³ independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, 2-methyl-2-butyl group, 2-methyl-2-pentyl group and 3-methyl-3-pentyl group. A tert-butyl group is particularly desirable.

The term “aliphatic cyclic group” refers to a monocyclic group or polycyclic group that has no aromaticity.

The aliphatic cyclic group within the “acid-dissociable, dissolution-inhibiting groups containing an aliphatic cyclic group” may or may not have a substituent. Examples of the substituent include alkyl groups of 1 to 5 carbon atoms, alkoxy groups of 1 to 5 carbon atoms, a fluorine atom, fluorinated alkyl groups of 1 to 5 carbon atoms, and an oxygen atom (═O).

The basic ring structure of the “aliphatic cyclic group” excluding substituents is not limited to structures constituted of only carbon and hydrogen (not limited to hydrocarbon groups), but is preferably a hydrocarbon group. Further, the hydrocarbon group may be either saturated or unsaturated, but in most cases, is preferably saturated. The basic ring structure preferably contains 5 to 30 carbon atoms.

The aliphatic cyclic group is preferably a polycyclic group.

Examples of the aliphatic cyclic group include groups in which one or more hydrogen atoms have been removed from a monocycloalkane which may or may not be substituted with an alkyl group of 1 to 5 carbon atoms, a fluorine atom or a fluorinated alkyl group, and groups in which one or more hydrogen atoms have been removed from a polycycloalkane such as a bicycloalkane, tricycloalkane or tetracycloalkane. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane. Further, a portion of the carbon atoms that constitute the ring structure of one of these groups in which one or more hydrogen atoms have been removed from a monocycloalkane or in which one or more hydrogen atoms have been removed from a polycycloalkane may be substituted with an ethereal oxygen atom (—O—).

Examples of acid-dissociable, dissolution-inhibiting groups containing an aliphatic cyclic group include:

(i) a group which forms a tertiary carbon atom on the ring structure of a monovalent aliphatic cyclic group in which a substituent (a group or an atom other than hydrogen) is bonded to the carbon atom to which an atom adjacent to the acid-dissociable, dissolution-inhibiting group (for example, the —O— within —C(═O)—O—) is bonded, and

(ii) a group which has a monovalent aliphatic cyclic group, and a branched alkylene group containing a tertiary carbon atom that is bonded to the monovalent aliphatic cyclic group.

In the group (i), an example of the substituent bonded to the carbon atom within the ring structure of the monovalent aliphatic cyclic group that is bonded to the atom adjacent to the acid-dissociable, dissolution-inhibiting group is an alkyl group. Specific examples of this alkyl group include the same groups as those described below for R¹⁴ in formulas (1-1) to (1-9) shown below.

Specific examples of groups of type (i) include groups represented by general formulas (1-1) to (1-9) shown below.

Specific examples of groups of type (ii) include groups represented by general formulas (2-1) to (2-6) shown below.

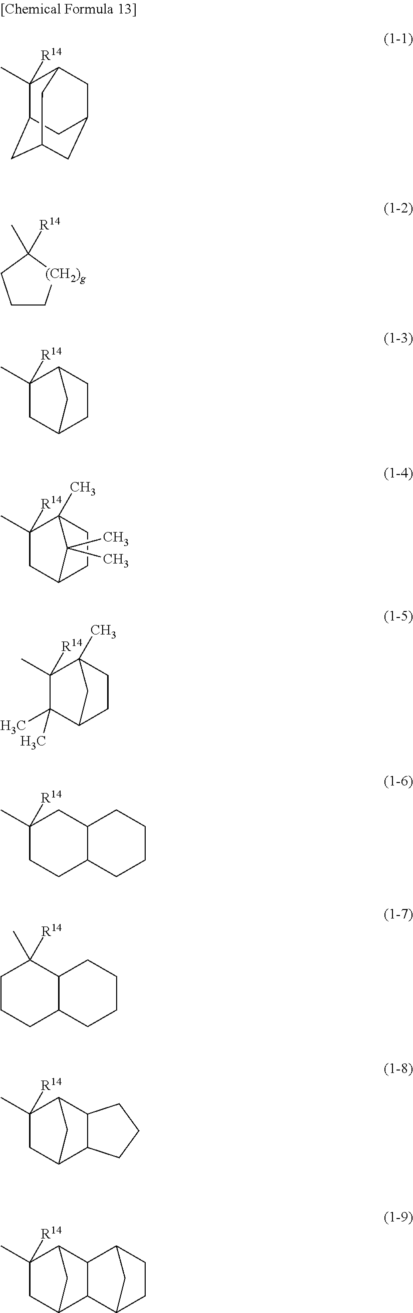

In the formulas above, R¹⁴ represents an alkyl group, and g represents an integer of 0 to 8.

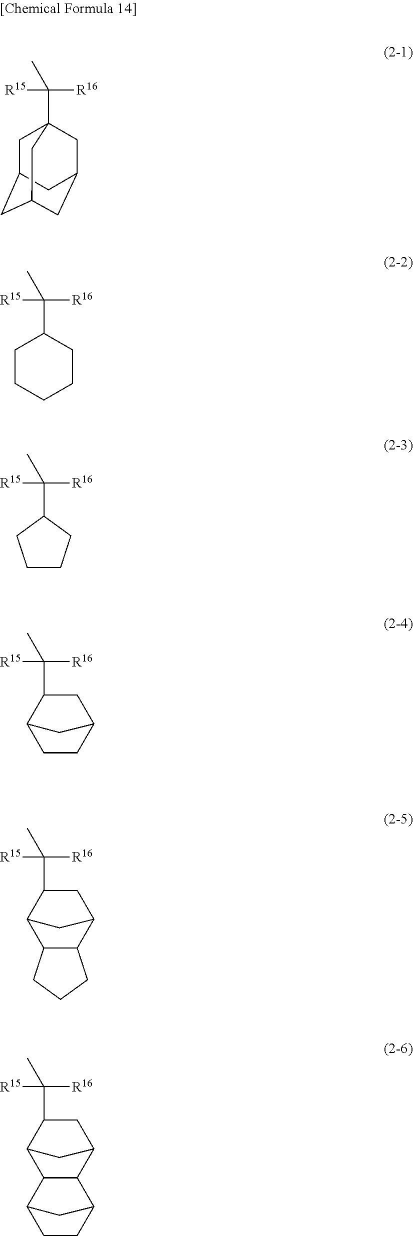

In the formulas above, each of R¹⁵ and R¹⁶ independently represents an alkyl group.

The alkyl group represented by R¹⁴ is preferably a linear or branched alkyl group.

The linear alkyl group preferably has 1 to 5 carbon atoms, more preferably 1 to 4 carbon atoms, and still more preferably 1 or 2 carbon atoms. Specific examples include a methyl group, ethyl group, n-propyl group, n-butyl group and n-pentyl group. Among these, a methyl group, ethyl group or n-butyl group is preferable, and a methyl group or ethyl group is more preferable.

The branched alkyl group preferably has 3 to 10 carbon atoms, and more preferably 3 to 5 carbon atoms. Specific examples of such branched alkyl groups include an isopropyl group, isobutyl group, tert-butyl group, isopentyl group and neopentyl group, and an isopropyl group is particularly desirable.

g is preferably an integer of 0 to 3, more preferably an integer of 1 to 3, and still more preferably 1 or 2.

Examples of the alkyl groups for R¹⁵ and R¹⁶ include the same alkyl groups as those described above for R¹⁴.

In formulas (1-1) to (1-9) and (2-1) to (2-6), some of the carbon atoms that constitute the ring may be replaced with an ethereal oxygen atom (—O—).

Further, in formulas (1-1) to (1-9) and (2-1) to (2-6), one or more of the hydrogen atoms bonded to the carbon atoms that constitute the ring may each be substituted with a substituent. Examples of the substituent include an alkyl group of 1 to 5 carbon atoms, a fluorine atom, or a fluorinated alkyl group of 1 to 5 carbon atoms.

An “acetal-type acid-dissociable, dissolution-inhibiting group” generally substitutes a hydrogen atom at the terminal of an alkali-soluble group such as a carboxyl group or hydroxyl group, so as to be bonded with an oxygen atom. When acid is generated upon exposure, the generated acid acts to break the bond between the acetal-type acid-dissociable, dissolution-inhibiting group and the oxygen atom to which the acetal-type acid-dissociable, dissolution-inhibiting group is bonded.

Examples of acetal-type acid-dissociable, dissolution-inhibiting groups include groups represented by general formula (p1) shown below.

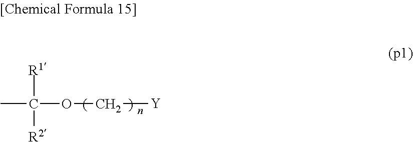

In the formula, each of R^{1′} and R^{2′} independently represents a hydrogen atom or an alkyl group of 1 to 5 carbon atoms, n represents an integer of 0 to 3, and Y represents an alkyl group of 1 to 5 carbon atoms or an aliphatic cyclic group

In formula (p1), n is preferably an integer of 0 to 2, more preferably 0 or 1, and most preferably 0.

Examples of the alkyl group for R^{1′} and R^{2′} include the same alkyl groups as those described above for the α-position substituent within the description relating to the acrylate ester. Among these, a methyl group or ethyl group is preferable, and a methyl group is the most desirable.

In the present invention, it is preferable that at least one of R^{1′} and R^{2′} is a hydrogen atom. That is, it is preferable that the acid-dissociable, dissolution-inhibiting group (p1) is a group represented by general formula (p1-1) shown below.

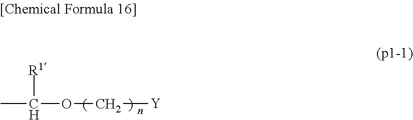

In the formula, R^{1′}, n and Y are the same as defined above.

Examples of the alkyl group for Y include the same alkyl groups as those described above for the α-position substituent within the description relating to the acrylate ester.

As the aliphatic cyclic group for Y, any of the multitude of monocyclic or polycyclic aliphatic cyclic groups that have been proposed for conventional ArF resists and the like can be appropriately selected for use. For example, the same aliphatic cyclic groups as those described above in connection with the “acid-dissociable, dissolution-inhibiting group containing an aliphatic cyclic group” can be used.

Further, as the acetal-type acid-dissociable, dissolution-inhibiting group, groups represented by general formula (p2) shown below can also be used.

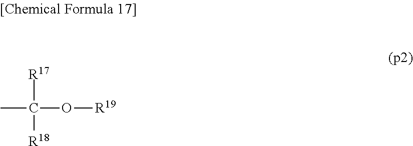

In the formula, each of R¹⁷ and R¹⁸ independently represents a linear or branched alkyl group or a hydrogen atom, and R¹⁹ represents a linear, branched or cyclic alkyl group, or alternatively, each of R¹⁷ and R¹⁹ may independently represent a linear or branched alkylene group, wherein R¹⁷ and R¹⁹ are bonded to each other to form a ring.

The alkyl group for R¹⁷ and R¹⁸ preferably has 1 to 15 carbon atoms, and may be either linear or branched. As the alkyl group, an ethyl group or methyl group is preferable, and a methyl group is most preferable.

It is particularly desirable that either one of R¹⁷ and R¹⁸ is a hydrogen atom, and the other is a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. Examples of the cycloalkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane and cyclohexane, and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

Further, in the above formula (p2), each of R¹⁷ and R¹⁹ may independently represent a linear or branched alkylene group (preferably an alkylene group of 1 to 5 carbon atoms), wherein the terminal of R¹⁹ and the terminal of R¹⁷ are bonded to each other.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include tetrahydropyranyl group and tetrahydrofuranyl group.

More specific examples of the structural unit (a1) include structural units represented by general formula (a1-0-1) shown below and structural units represented by general formula (a1-0-2) shown below.

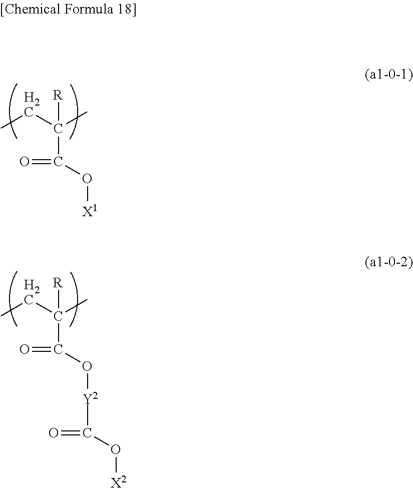

In the formulas, R represents a hydrogen atom, an alkyl group of 1 to 5 carbon atoms or a halogenated alkyl group of 1 to 5 carbon atoms, X¹ represents an acid-dissociable, dissolution-inhibiting group, Y² represents a divalent linking group, and X² represents an acid-dissociable, dissolution-inhibiting group.

In general formula (a1-0-1), examples of the alkyl group and the halogenated alkyl group for R include the same alkyl groups and halogenated alkyl groups as those described above for the α-position substituent within the description relating to the acrylate ester. R is preferably a hydrogen atom, an alkyl group of 1 to 5 carbon atoms or a fluorinated alkyl group of 1 to 5 carbon atoms, and is most preferably a hydrogen atom or a methyl group.

There are no particular limitations on X¹ as long as it is an acid-dissociable, dissolution-inhibiting group. Examples include the aforementioned tertiary alkyl ester-type acid-dissociable, dissolution-inhibiting groups and acetal-type acid-dissociable, dissolution-inhibiting groups, and of these, tertiary alkyl ester-type acid-dissociable, dissolution-inhibiting groups are preferable.

In general formula (a1-0-2), R is the same as defined above.

X² is the same as defined for X¹ in general formula (a1-0-1).

There are no particular limitations on the divalent linking group for Y², and examples include alkylene groups, divalent aliphatic cyclic groups, divalent aromatic cyclic groups, and divalent linking groups containing a hetero atom.

When Y² is an alkylene group, the alkylene group preferably contains 1 to 10 carbon atoms, more preferably 1 to 6 carbon atoms, still more preferably 1 to 4 carbon atoms, and most preferably 1 to 3 carbon atoms.

When Y² is a divalent aliphatic cyclic group, examples of the aliphatic cyclic group include the same aliphatic cyclic groups as those mentioned above in relation to the “acid-dissociable, dissolution-inhibiting group containing an aliphatic cyclic group” with the exception that two or more hydrogen atoms have been removed from the ring structure. The aliphatic cyclic group for Y² is preferably a group in which two or more hydrogen atoms have been removed from cyclopentane, cyclohexane, norbornane, isobornane, adamantane, tricyclodecane or tetracyclododecane.

When Y² is a divalent aromatic cyclic group, examples of the aromatic cyclic group include groups in which two hydrogen atoms have been removed from an aromatic hydrocarbon ring which may have a substituent. The aromatic hydrocarbon ring preferably contains 6 to 15 carbon atoms, and specific examples include a benzene ring, naphthalene ring, phenanthrene ring and anthracene ring. Among these, a benzene ring or naphthalene ring is particularly desirable.

Examples of the substituent which the aromatic hydrocarbon ring may have include a halogen atom, alkyl group, alkoxy group, halogenated lower alkyl group or oxygen atom (═O). Specific examples of the halogen atom include a fluorine atom, chlorine atom, iodine atom and bromine atom.

When Y² is a divalent linking group containing a hetero atom, examples of the divalent linking group containing a hetero atom include —O—, —C(═O)—O—, —C(═O)—, —O—C(═O)—O—, —C(═O)—NH—, —NH— (wherein H may be replaced with a substituent such as an alkyl group or acyl group or the like), —S—, —S(═O)₂—, —S(═O)₂—O—, groups represented by the formula -A-O—B—, and groups represented by the formula -[A-C(═O)—O]_{m′}—B—. In these formulas -A-O—B— and -[A-C(═O)—O]_{m′}—B—, each of A and B represents a divalent hydrocarbon group which may have a substituent, —O— represents an oxygen atom, and m′ represents an integer of 0 to 3.

When Y² represents —NH—, the H may be replaced with a substituent such as an alkyl group or acyl group or the like. This substituent (the alkyl group or acyl group or the like) preferably has 1 to 10 carbon atoms, more preferably 1 to 8 carbon atoms, and most preferably 1 to 5 carbon atoms.

When Y² represents a group represented by the formula -A-O—B— or the formula -[A-C(═O)—O]_{m′}—B—, each of A and B represents a divalent hydrocarbon group which may have a substituent. The expression that the hydrocarbon group “may have a substituent” means that some or all of the hydrogen atoms within the hydrocarbon group may each be substituted with a group or atom other than a hydrogen atom.

The hydrocarbon group for A may be an aliphatic hydrocarbon group or an aromatic hydrocarbon group. An “aliphatic hydrocarbon group” refers to a hydrocarbon group that has no aromaticity. The aliphatic hydrocarbon group for A may be either saturated or unsaturated, but in most cases, is preferably saturated.

More specific examples of the aliphatic hydrocarbon group for A include linear or branched aliphatic hydrocarbon groups, and aliphatic hydrocarbon groups that include a ring within the structure.

The linear or branched aliphatic hydrocarbon group preferably has 1 to 10 carbon atoms, more preferably 1 to 8 carbon atoms, still more preferably 2 to 5 carbon atoms, and most preferably 2 carbon atoms.

The linear aliphatic hydrocarbon group is preferably a linear alkylene group, and specific examples include a methylene group, ethylene group [—(CH₂)₂—], trimethylene group [—(CH₂)₃—], tetramethylene group [—(CH₂)₄—] and pentamethylene group [—(CH₂)₅—].

The branched aliphatic hydrocarbon group is preferably a branched alkylene group, and specific examples include alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, alkylethylene groups such as —CH(CH₃)CH₂—, —CH(CH₃)CH(CH₃)—, —C(CH₃)₂CH₂— and —CH(CH₂CH₃)CH₂—, alkyltrimethylene groups such as —CH(CH₃)CH₂CH₂— and —CH₂CH(CH₃)CH₂—, and alkyltetramethylene groups such as —CH(CH₃)CH₂CH₂CH₂— and —CH₂CH(CH₃)CH₂CH₂—. The alkyl group within the alkylalkylene group is preferably a linear alkyl group of 1 to 5 carbon atoms.

The linear or branched aliphatic hydrocarbon group may or may not have a substituent. Examples of the substituent include a fluorine atom, a fluorinated alkyl group of 1 to 5 carbon atoms and an oxygen atom (═O).

Examples of the aliphatic hydrocarbon group that includes a ring within the structure include cyclic aliphatic hydrocarbon groups (groups in which two hydrogen atoms have been removed from an aliphatic hydrocarbon ring), and groups in which a cyclic aliphatic hydrocarbon group is bonded to the terminal of an aforementioned linear or branched aliphatic hydrocarbon group, or interposed within the chain of an aforementioned linear or branched aliphatic hydrocarbon group.

The cyclic aliphatic hydrocarbon group preferably contains 3 to 20 carbon atoms, and more preferably 3 to 12 carbon atoms.

The cyclic aliphatic hydrocarbon group may be either a polycyclic group or a monocyclic group. As the monocyclic group, a group in which two hydrogen atoms have been removed from a monocycloalkane of 3 to 6 carbon atoms is preferable. Examples of the monocycloalkane include cyclopentane and cyclohexane.

As the polycyclic group, a group in which two hydrogen atoms have been removed from a polycycloalkane of 7 to 12 carbon atoms is preferable. Specific examples of the polycycloalkane include adamantane, norbornane, isobornane, tricyclodecane and tetracyclododecane.

The cyclic aliphatic hydrocarbon group may or may not have a substituent. Examples of the substituent include a lower alkyl group of 1 to 5 carbon atoms, a fluorine atom, a fluorinated lower alkyl group of 1 to 5 carbon atoms, and an oxygen atom (═O).

The group A is preferably a linear aliphatic hydrocarbon group, more preferably a linear alkylene group, still more preferably a linear alkylene group of 1 to 5 carbon atoms, and most preferably a methylene group or an ethylene group.

The group B is preferably a linear or branched aliphatic hydrocarbon group, and a methylene group, an ethylene group or an alkylmethylene group is particularly desirable. The alkyl group within the alkylmethylene group is preferably a linear alkyl group of 1 to 5 carbon atoms, more preferably a linear alkyl group of 1 to 3 carbon atoms, and most preferably a methyl group.

Furthermore, in the group represented by the formula -[A-C(═O)—O]_{m′}—B—, m′ represents an integer of 0 to 3, and is preferably an integer of 0 to 2, more preferably 0 or 1, and most preferably 1.

More specific examples of the structural unit (a1) include structural units represented by general formulas (a1-1) to (a1-4) shown below.

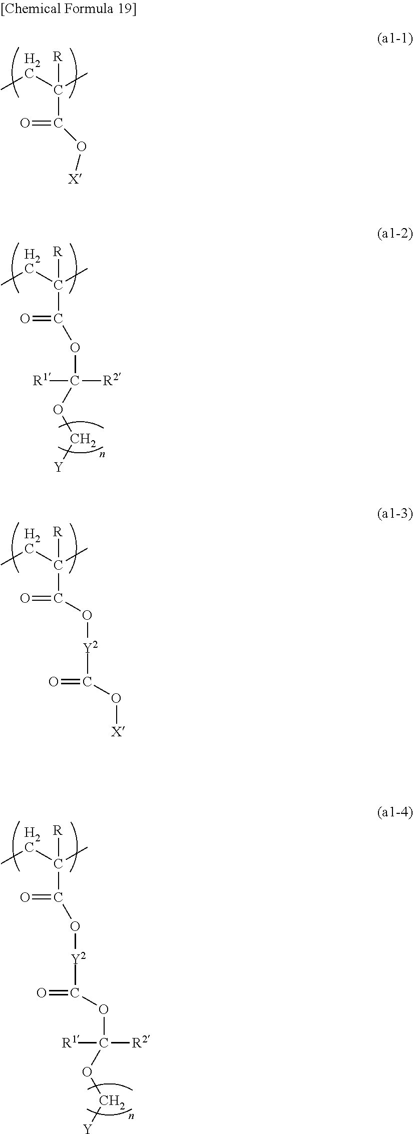

In the formulas, R, R^{1′}, R^{2′}, n, Y and Y² are each the same as defined above, and X′ represents an acid-dissociable, dissolution-inhibiting group.

In the formulas, examples of the tertiary alkyl ester-type acid-dissociable, dissolution-inhibiting group for X′ include the same tertiary alkyl ester-type acid-dissociable, dissolution-inhibiting groups as those described above.

R^{1′}, R^{2′}, n and Y are the same as defined for R^{1′}, R^{2′}, n and Y in general formula (p1), described above in connection with the “acetal-type acid-dissociable, dissolution-inhibiting group”.

Examples of Y² include the same groups as those mentioned above for Y² in general formula (a1-0-2).

Specific examples of structural units represented by the above general formula (a1-1) to (a1-4) are shown below.

In the formulas shown below, R^{α} represents a hydrogen atom, a methyl group or a trifluoromethyl group.

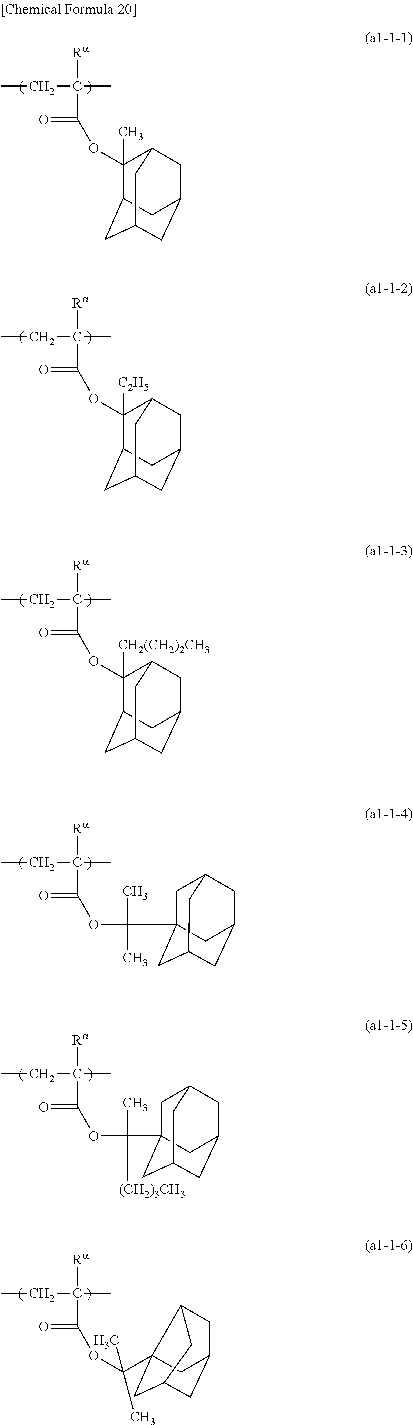

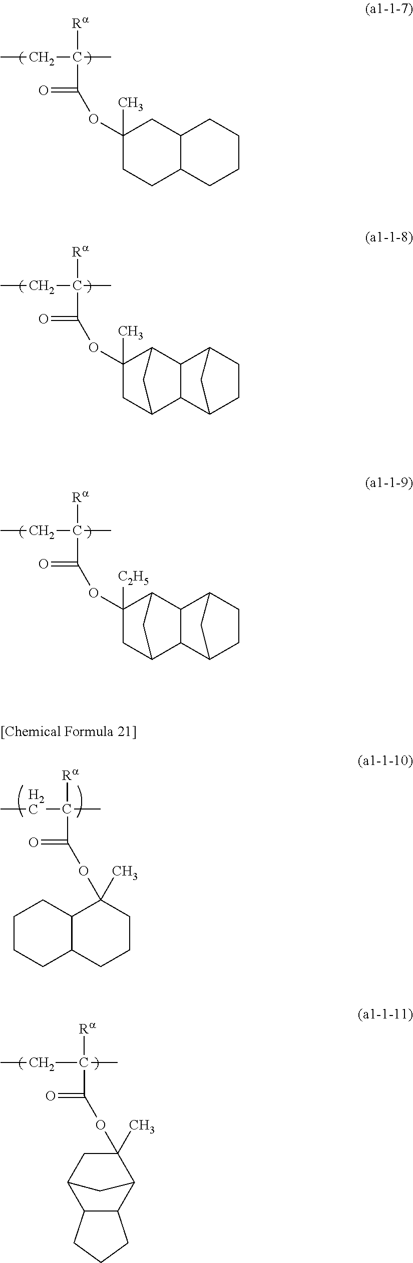

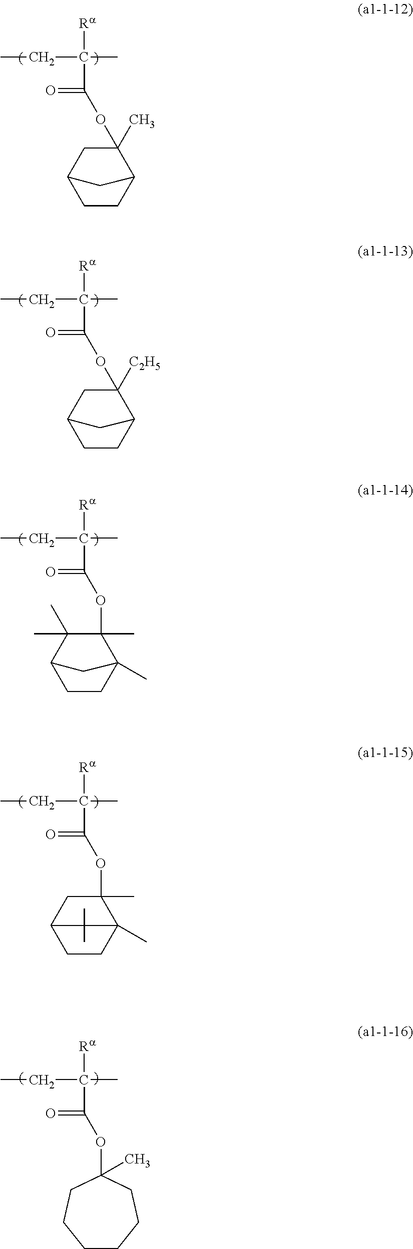

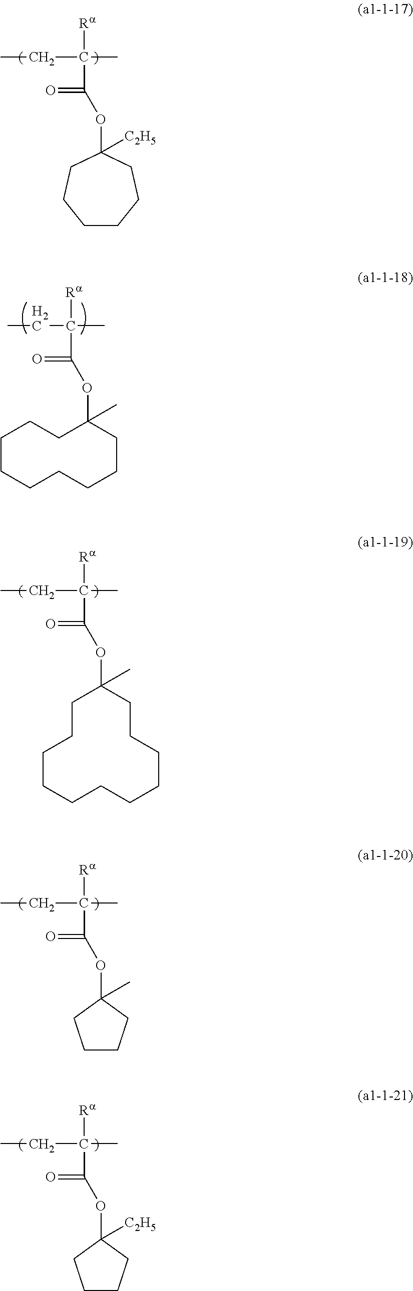

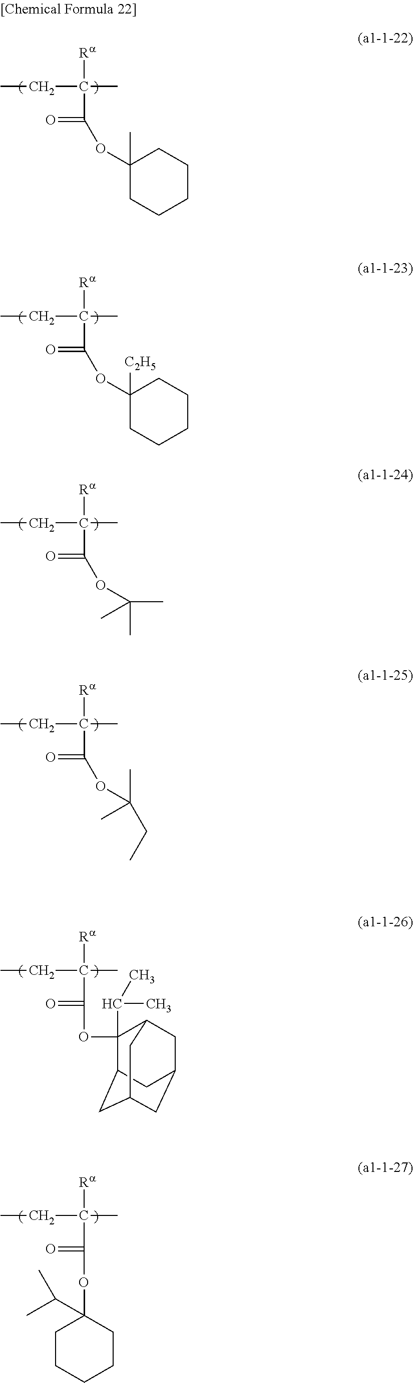

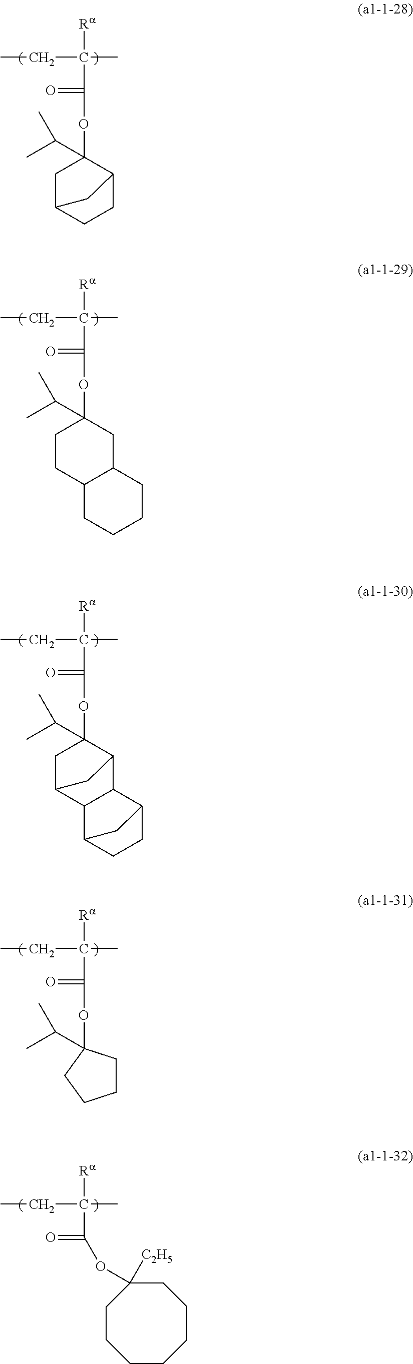

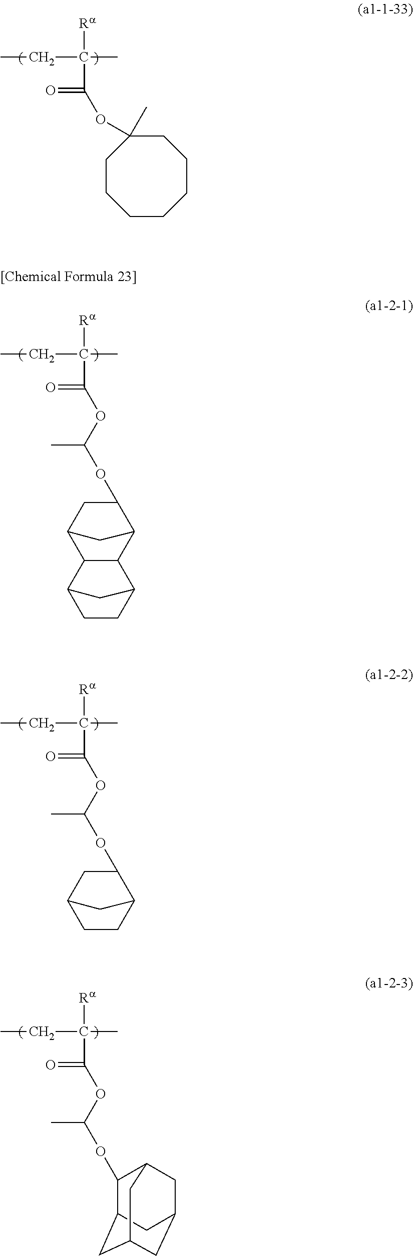

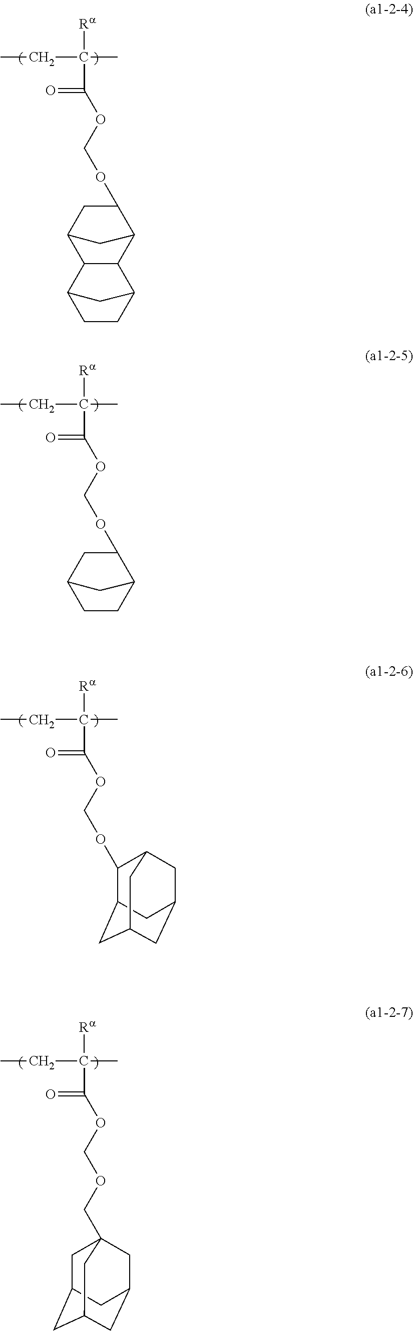

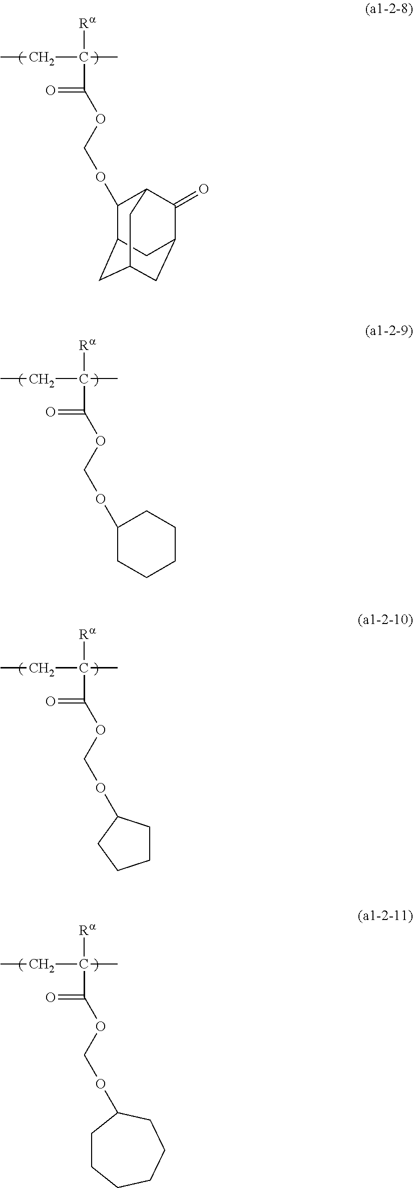

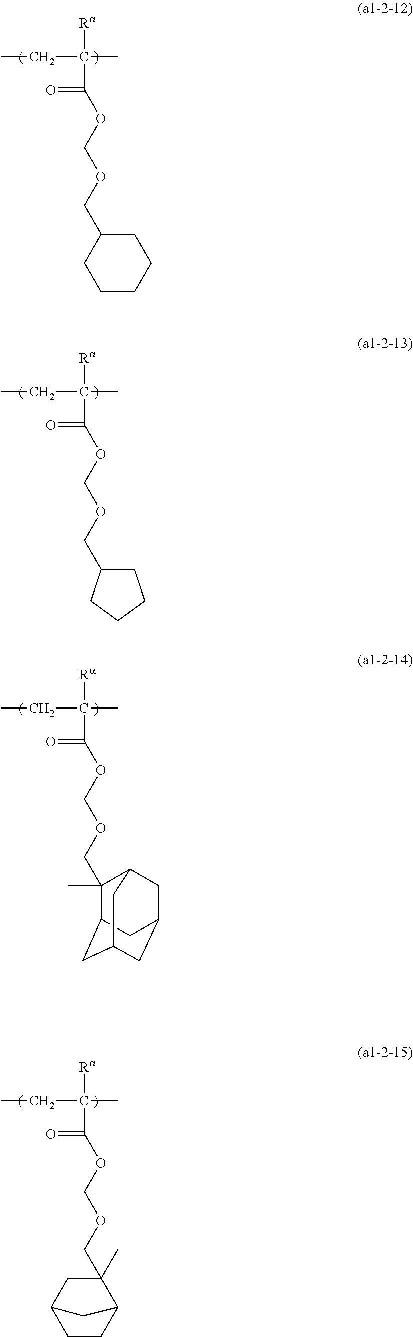

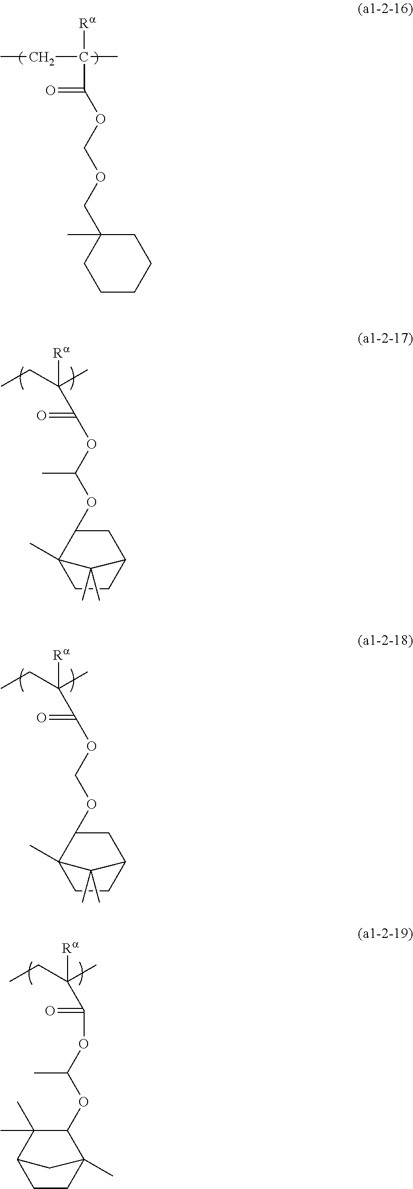

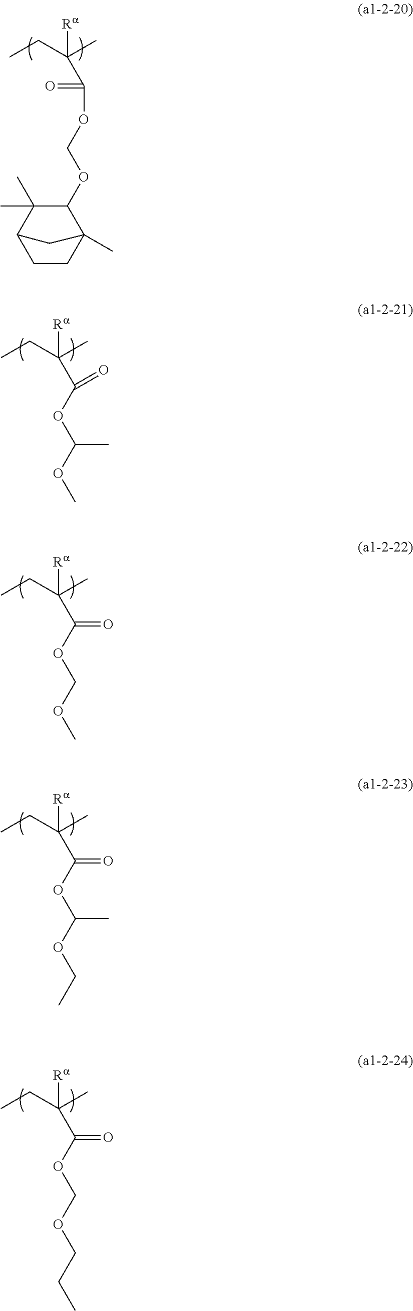

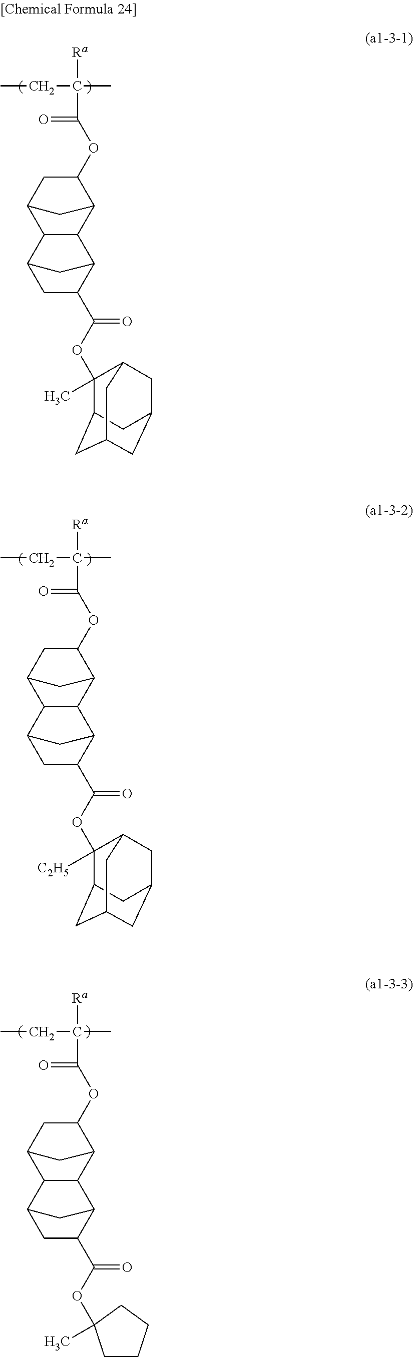

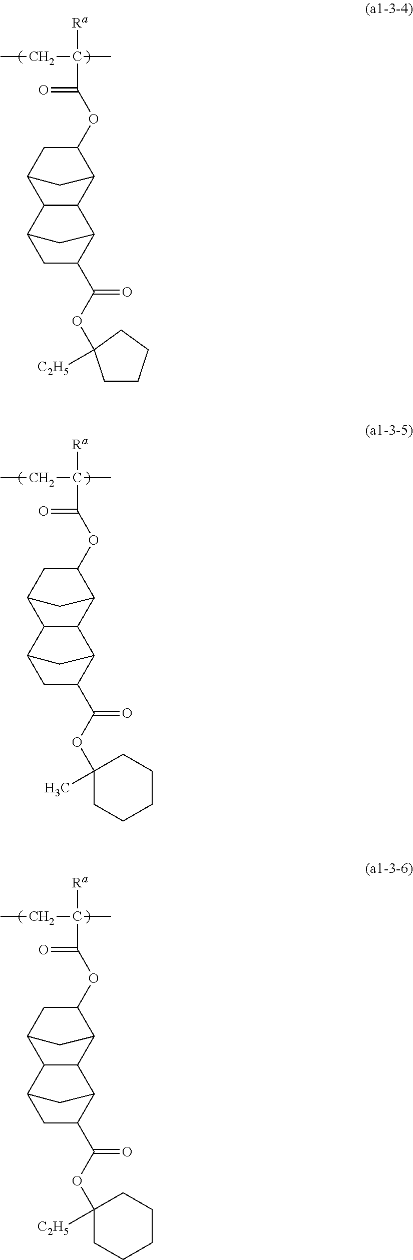

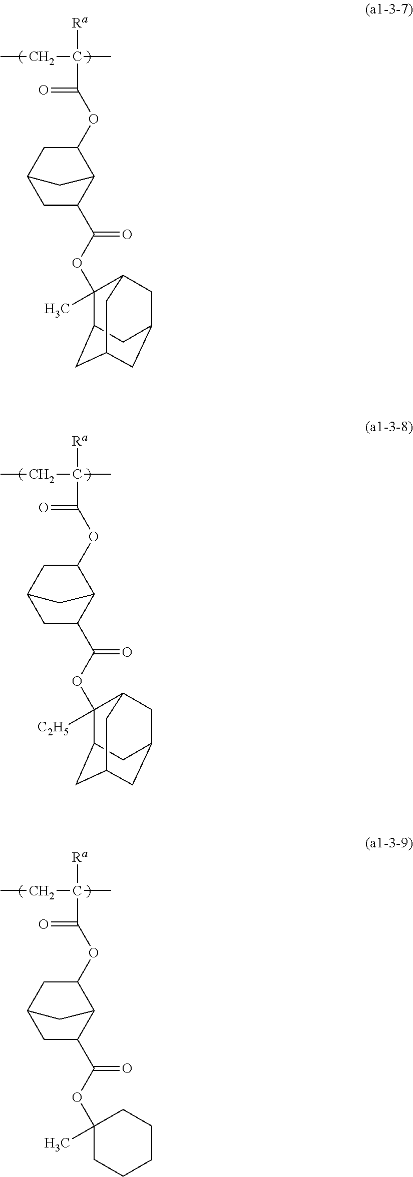

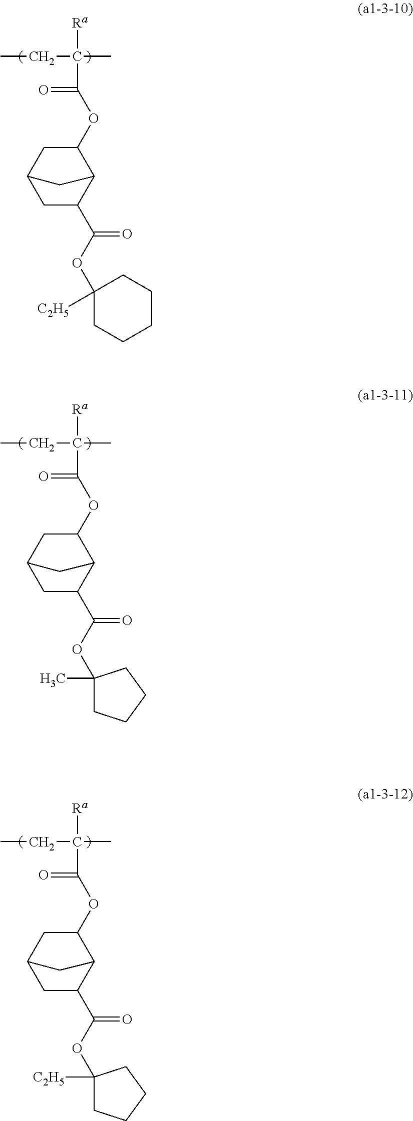

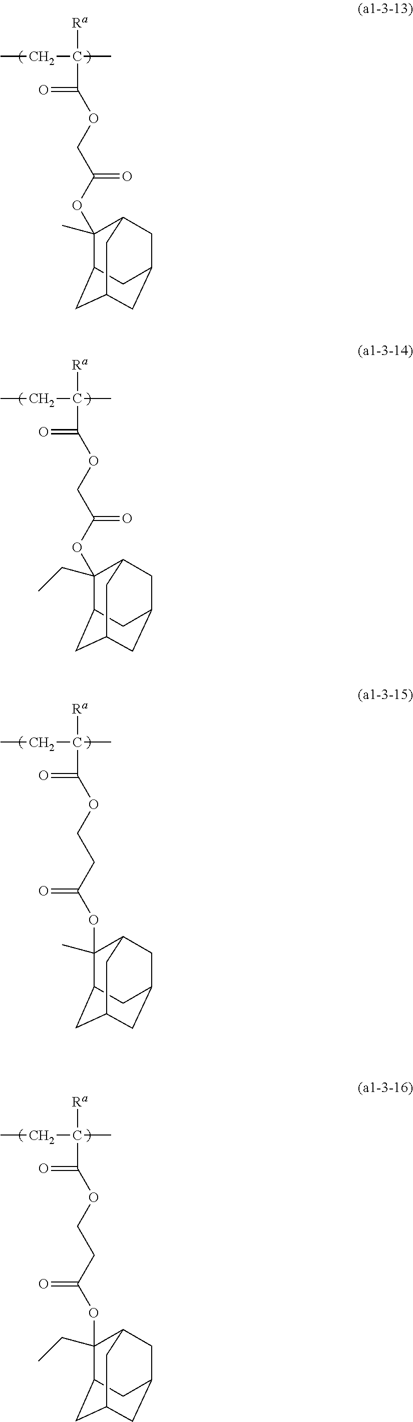

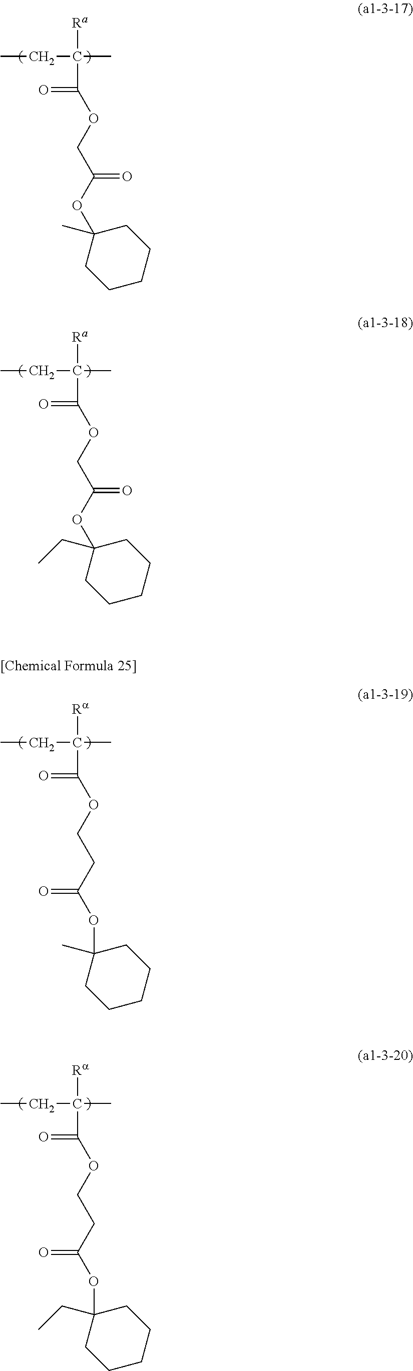

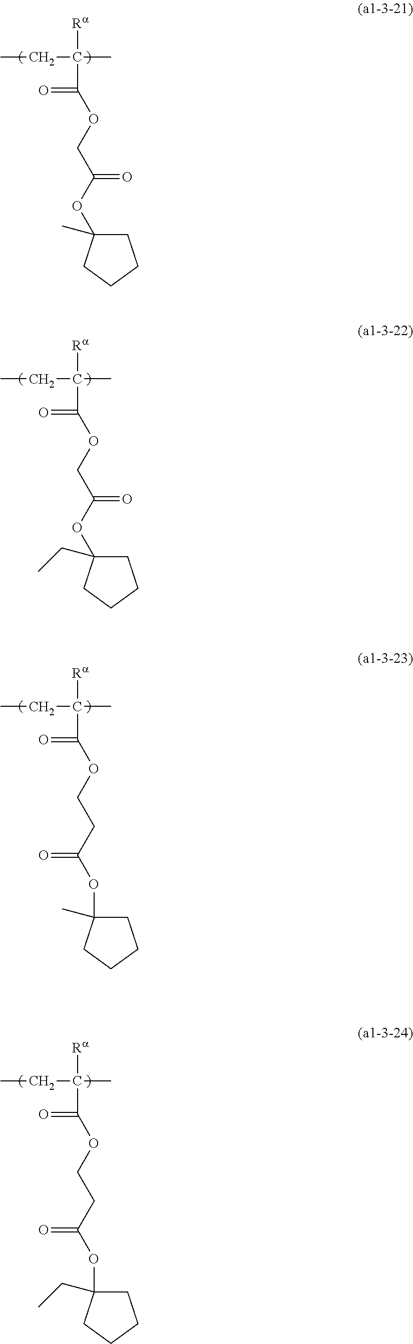

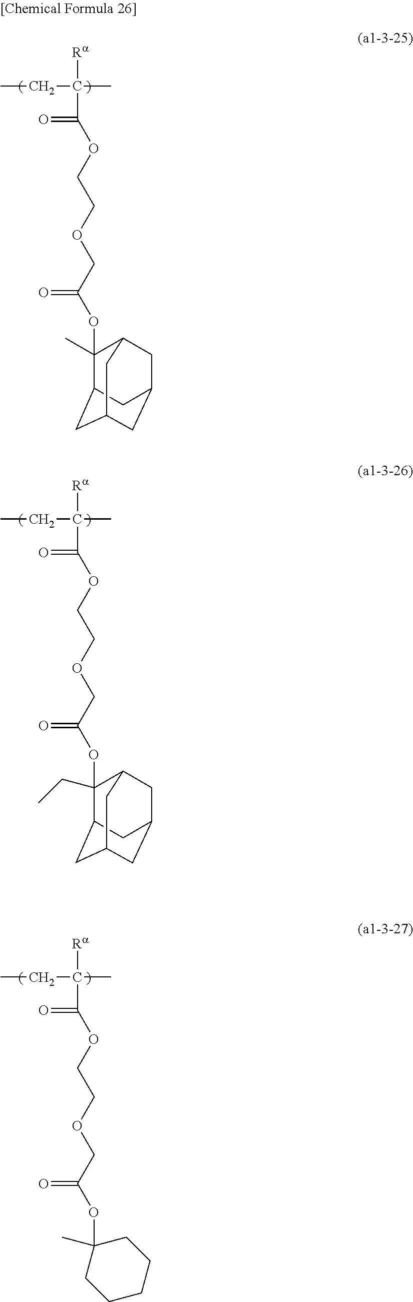

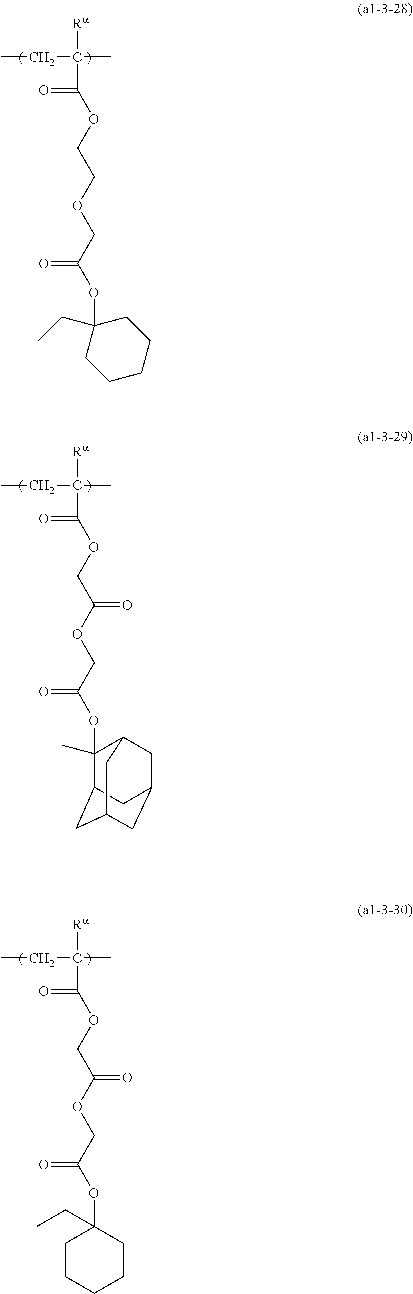

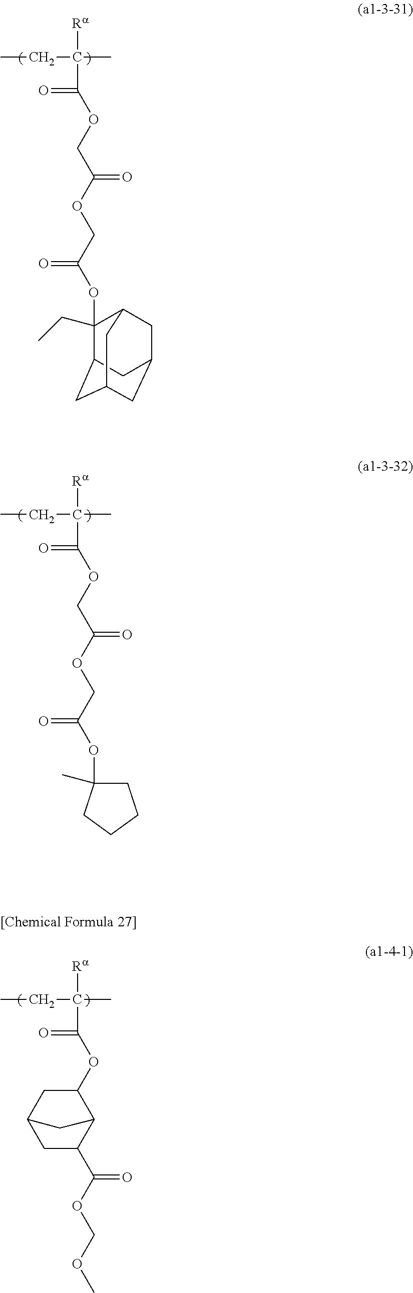

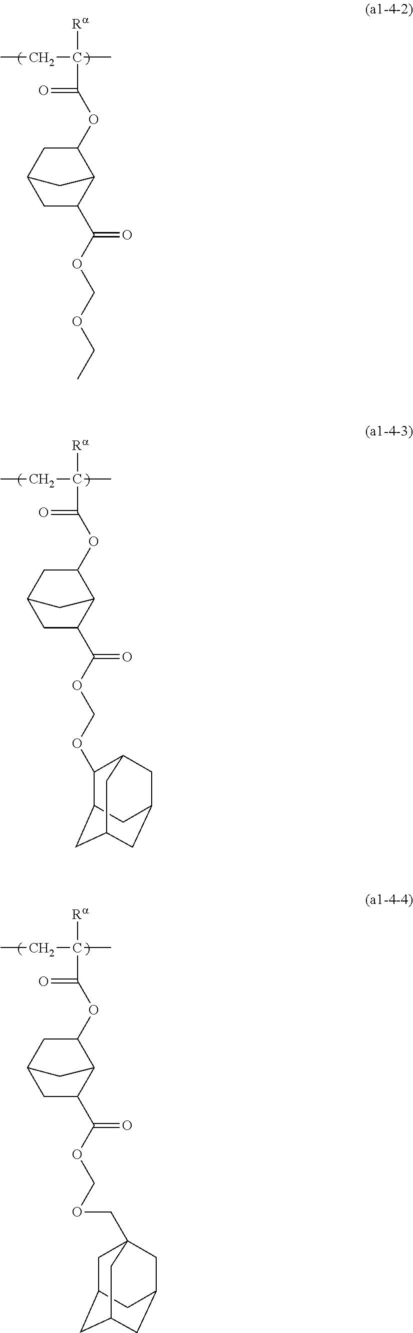

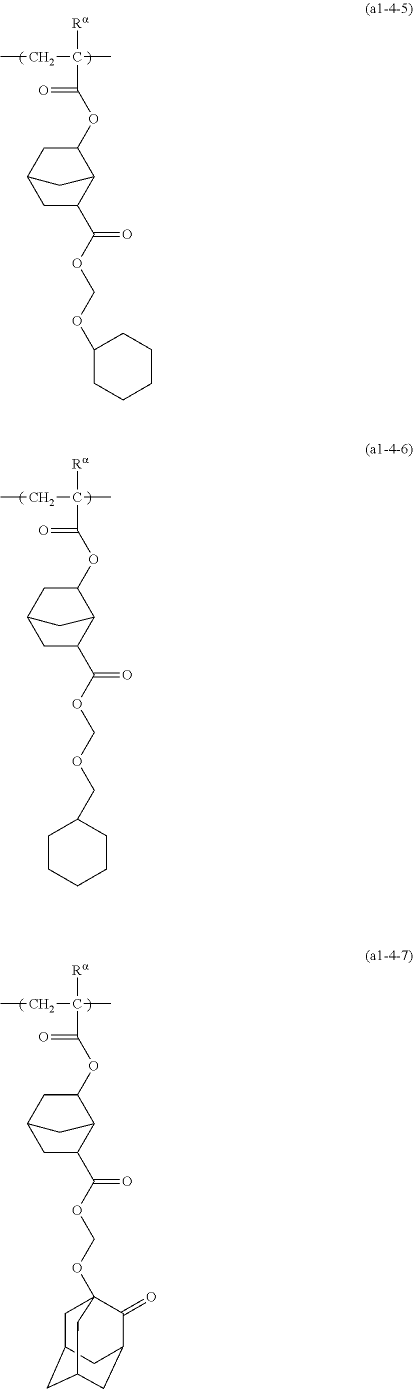

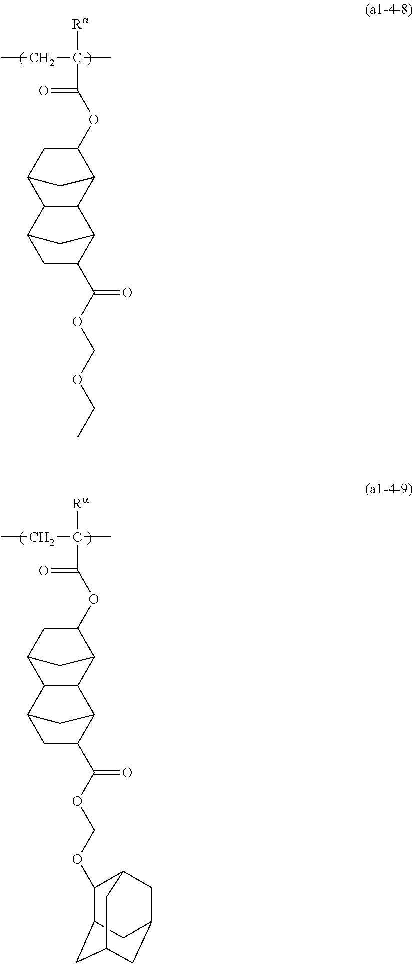

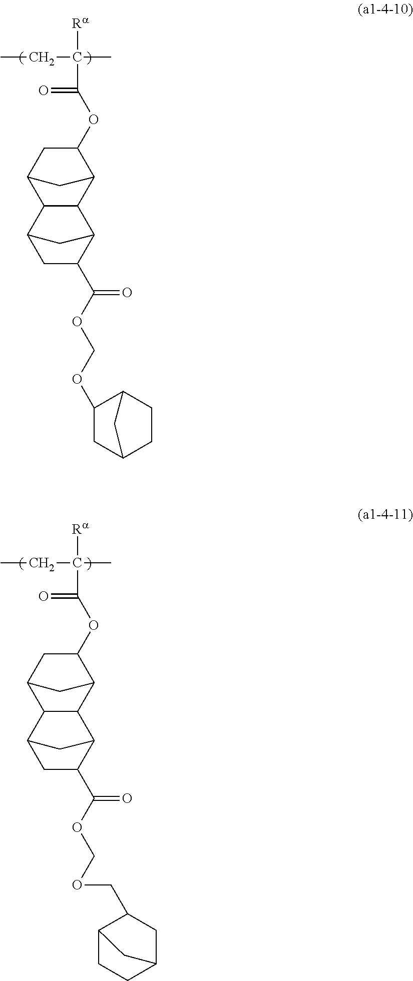

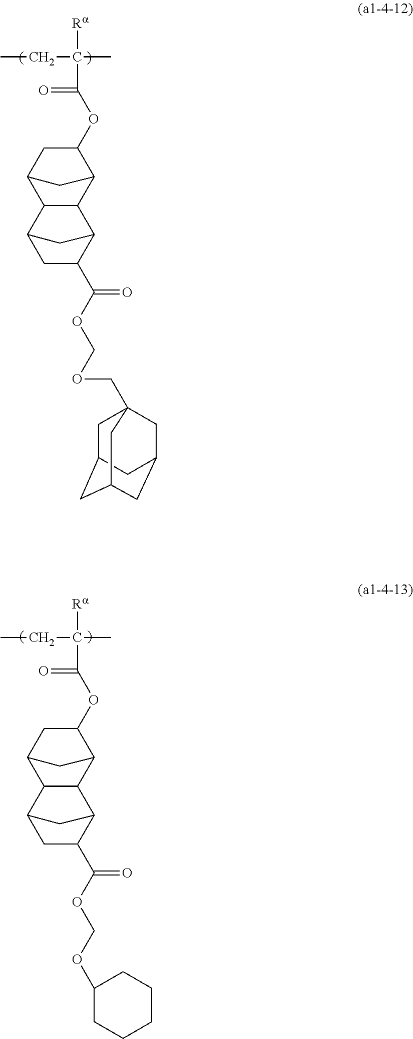

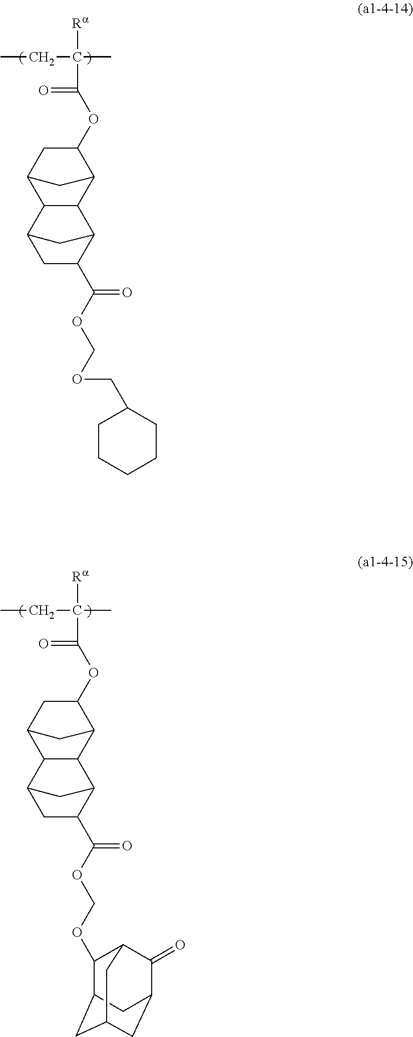

As the structural unit (a1), one type of structural unit may be used alone, or a combination of two or more types of structural units may be used.

Among the above structural units, structural units represented by general formulas (a1-1) and (a1-3) are preferable. Specifically, the use of at least one structural unit selected from the group consisting of structural units represented by formulas (a1-1-1) to (a-1-1-4), (a1-1-20) to (a1-1-23), (a1-1-26), (a1-1-32) to (a1-1-33), and (a1-3-25) to (a1-3-32) is more preferable.

Further, as the structural unit (a1), structural units represented by general formula (a1-1-01) shown below which includes the structural units represented by formulas (a1-1-1) to (a1-1-3) and (a1-1-26), structural units represented by general formula (a1-1-02) shown below which includes the structural units represented by formulas (a1-1-16), (a1-1-17), (a1-1-20) to (a1-1-23), and (a1-1-32) to (a1-1-33), structural units represented by general formula (a1-3-01) shown below which includes the structural units represented by formulas (a1-3-25) and (a1-3-26), structural units represented by general formula (a1-3-02) shown below which includes the structural units represented by formulas (a1-3-27) and (a1-3-28), and structural units represented by general formula (a1-3-03) shown below which includes the structural units represented by formulas (a1-3-29) to (a1-3-32) are also preferable.

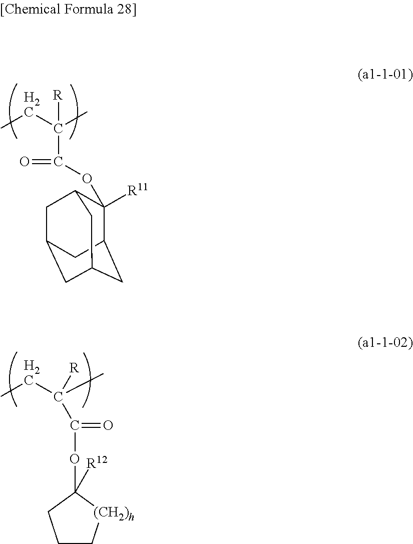

In the formulas, R represents a hydrogen atom, an alkyl group of 1 to 5 carbon atoms or a halogenated alkyl group of 1 to 5 carbon atoms, R¹¹ represents an alkyl group of 1 to 5 carbon atoms, R¹² represents an alkyl group of 1 to 5 carbon atoms, and h represents an integer of 1 to 6.

In general formula (a1-1-01), R is the same as defined above.

The alkyl group for R¹¹ is the same as defined above for the alkyl group for R, and a methyl group, ethyl group or isopropyl group is preferable.

In general formula (a1-1-02), R is the same as defined above.

The alkyl group for R¹² is the same as defined above for the alkyl group for R, and a methyl group, ethyl group or isopropyl group is preferable.

h is preferably 1 or 2, and most preferably 2.

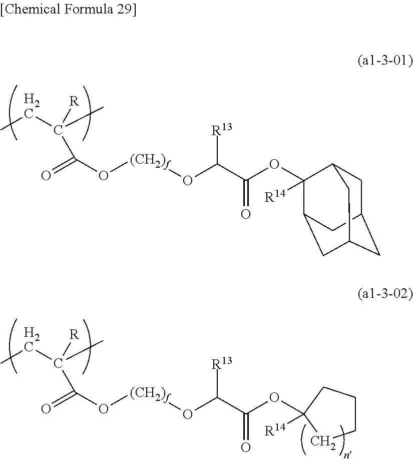

In the formula, R represents a hydrogen atom, an alkyl group of 1 to 5 carbon atoms or a halogenated alkyl group of 1 to 5 carbon atoms, R¹⁴ represents an alkyl group, R¹³ represents a hydrogen atom or a methyl group, f represents an integer of 1 to 10, and n′ represents an integer of 1 to 6.

In general formulas (a1-3-01) and (a1-3-02), R is the same as defined above.

R¹³ is preferably a hydrogen atom.

The alkyl group for R¹⁴ is the same as defined above for the group R¹⁴ in the above formulas (1-1) to (1-9), and is preferably a methyl group, ethyl group or isopropyl group.

f is preferably an integer of 1 to 8, more preferably an integer of 2 to 5, and most preferably 2.

n′ is most preferably 1 or 2.

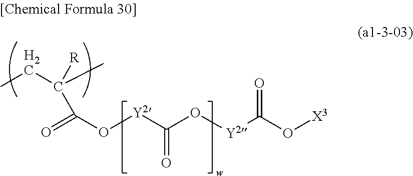

In the formula, R is the same as defined above, each of Y²′ and Y²″ independently represents a divalent linking group, X³ represents an acid-dissociable, dissolution-inhibiting group, and w represents an integer of 0 to 3.

In formula (a1-3-03), examples of the divalent linking groups for Y²′ and Y²″ include the same groups as those described above for Y² in general formula (a1-3).

Y²′ is preferably a divalent hydrocarbon group which may have a substituent, more preferably a linear aliphatic hydrocarbon group, and still more preferably a linear alkylene group. Among such linear alkylene groups, a linear alkylene group of 1 to 5 carbon atoms is preferable, and a methylene group or an ethylene group is the most desirable.

Y²″ is preferably a divalent hydrocarbon group which may have a substituent, more preferably a linear aliphatic hydrocarbon group, and still more preferably a linear alkylene group. Among such linear alkylene groups, a linear alkylene group of 1 to 5 carbon atoms is preferable, and a methylene group or an ethylene group is the most desirable.

Examples of the acid-dissociable, dissolution-inhibiting group for X³ include the same groups as those described above. X³ is preferably a tertiary alkyl ester-type acid-dissociable, dissolution-inhibiting group, and more preferably an aforementioned group of the type (i) which forms a tertiary carbon atom on the ring structure of a monovalent aliphatic cyclic group. Among such groups, a group represented by the above general formula (1-1) is preferable.

w represents an integer of 0 to 3, preferably an integer of 0 to 2, more preferably 0 or 1, and most preferably 1.

In the component (A1), the amount of the structural unit (a1), based on the combined total of all the structural units that constitute the component (A1) is preferably within a range from 10 to 80 mol %, more preferably from 20 to 70 mol %, and still more preferably from 25 to 50 mol %. Provided that the amount of the structural unit (a1) is at least as large as the lower limit of the above range, a pattern can be formed easily using a resist composition prepared from the component (A1). On the other hand, provided that the amount of the structural unit (a1) is not more than the upper limit of the above range, a good balance can be achieved with the other structural units.

—Structural Unit (a2):

The structural unit (a2) is a structural unit which is derived from an acrylate ester in which an atom other than a hydrogen atom or a substituent may be bonded to the carbon atom on the α-position, and contains a lactone-containing cyclic group.

In this description, the term “lactone-containing cyclic group” refers to a cyclic group including a single ring (lactone ring) containing an —O—C(═O)— structure. The lactone ring is counted as the first ring, and a lactone-containing cyclic group in which the only ring structure is the lactone ring is referred to as a monocyclic group, and groups containing other ring structures are described as polycyclic groups regardless of the structure of the other rings.

When the component (A1) is used for forming a resist film, the lactone-containing cyclic group of the structural unit (a2) is effective in improving the adhesion of the resist film to the substrate, and improving the affinity between the resist film and a developing solution containing water.

There are no particular limitations on the structural unit (a2), and an arbitrary structural unit may be used. Specific examples of lactone-containing monocyclic groups include groups in which one hydrogen atom has been removed from a 4- to 6-membered lactone ring, including a group in which one hydrogen atom has been removed from β-propiolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specific examples of the structural unit (a2) include structural units represented by general formulas (a2-1) to (a2-5) shown below.

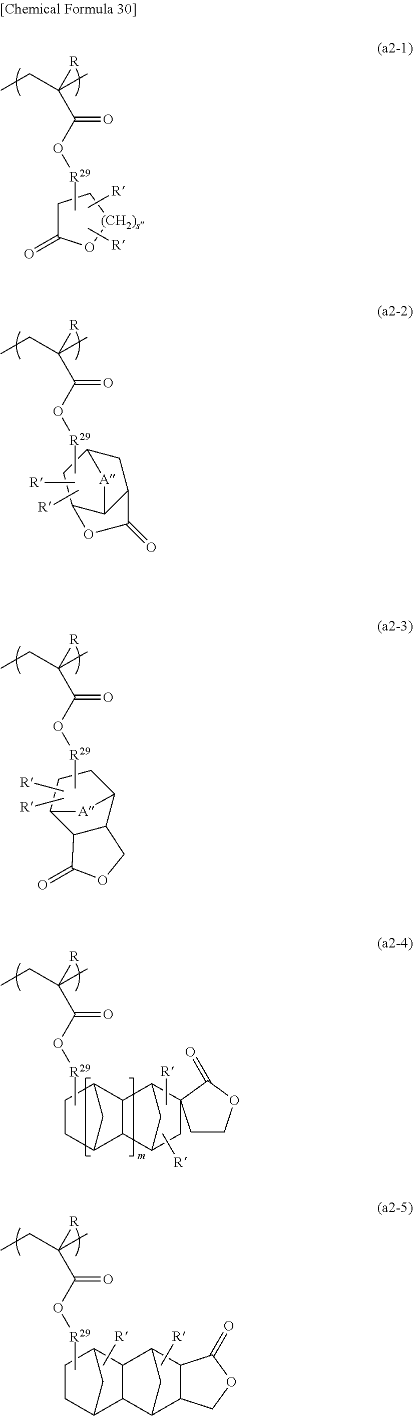

In the formulas, R represents a hydrogen atom, an alkyl group of 1 to 5 carbon atoms or a halogenated alkyl group of 1 to 5 carbon atoms, each R′ independently represents a hydrogen atom, an alkyl group of 1 to 5 carbon atoms, an alkoxy group of 1 to 5 carbon atoms or —COOR″, wherein R″ represents a hydrogen atom or an alkyl group, R²⁹ represents either a single bond or a divalent linking group, s″ represents an integer of 0 to 2, A″ represents an oxygen atom, a sulfur atom or an alkylene group of 1 to 5 carbon atoms which may contain an oxygen atom or a sulfur atom, and m represents 0 or 1.

In general formulas (a2-1) to (a2-5), R is the same as defined above for R in the structural unit (a1).

Examples of the alkyl group of 1 to 5 carbon atoms for R′ include a methyl group, ethyl group, propyl group, n-butyl group and tert-butyl group.

Examples of the alkoxy group of 1 to 5 carbon atoms for R′ include a methoxy group, ethoxy group, n-propoxy group, iso-propoxy group, n-butoxy group and tert-butoxy group.

If due consideration is given to factors such as industrial availability, then R′ is preferably a hydrogen atom.

The alkyl group for R″ may be a linear, branched or cyclic alkyl group.

When R″ is a linear or branched alkyl group, the alkyl group preferably contains 1 to 10 carbon atoms, and more preferably 1 to 5 carbon atoms

When R″ is a cyclic alkyl group, the alkyl group preferably contains 3 to 15 carbon atoms, more preferably 4 to 12 carbon atoms, and most preferably 5 to 10 carbon atoms. Examples include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

A″ is preferably an alkylene group of 1 to 5 carbon atoms, an oxygen atom (—O—) or a sulfur atom (—S—) and is more preferably an alkylene group of 1 to 5 carbon atoms or —O—. The alkylene group of 1 to 5 carbon atoms is preferably a methylene group or a dimethylethylene group, and is most preferably a methylene group.

R²⁹ represents a single bond or a divalent linking group. Examples of the divalent linking group include the same divalent linking groups as those described above for Y² in general formula (a1-0-2). Among these, an alkylene group, an ester linkage (—C(═O)—O—) or a combination thereof is preferable. The alkylene group as the divalent linking group for R²⁹ is preferably a linear or branched alkylene group. Specific examples include the same linear alkylene groups and branched alkylene groups as those described above, within the description relating to Y², for the aliphatic hydrocarbon group for A.

R²⁹ is preferably a single bond or a group represented by —R²⁹′—C(═O)—O— (wherein R²⁹′ represents a linear or branched alkylene group). The linear or branched alkylene group for R²⁹′ preferably contains 1 to 10 carbon atoms, more preferably 1 to 8 carbon atoms, and still more preferably 1 to 5 carbon atoms.

In formula (a2-1), s″ is preferably 1 or 2.

Specific examples of structural units represented by general formulas (a2-1) to (a2-5) are shown below. In the formulas shown below, R^{α} represents a hydrogen atom, a methyl group or a trifluoromethyl group.

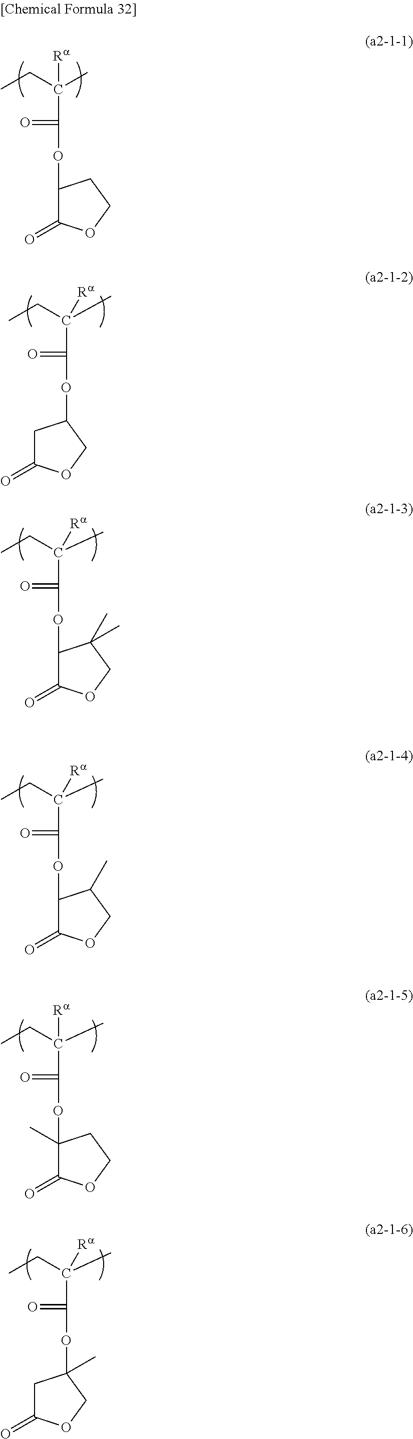

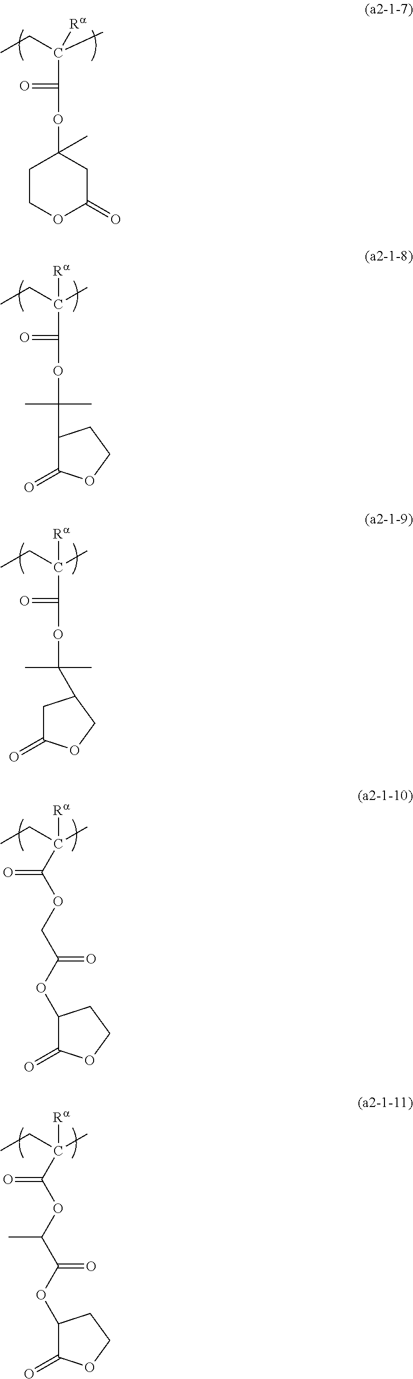

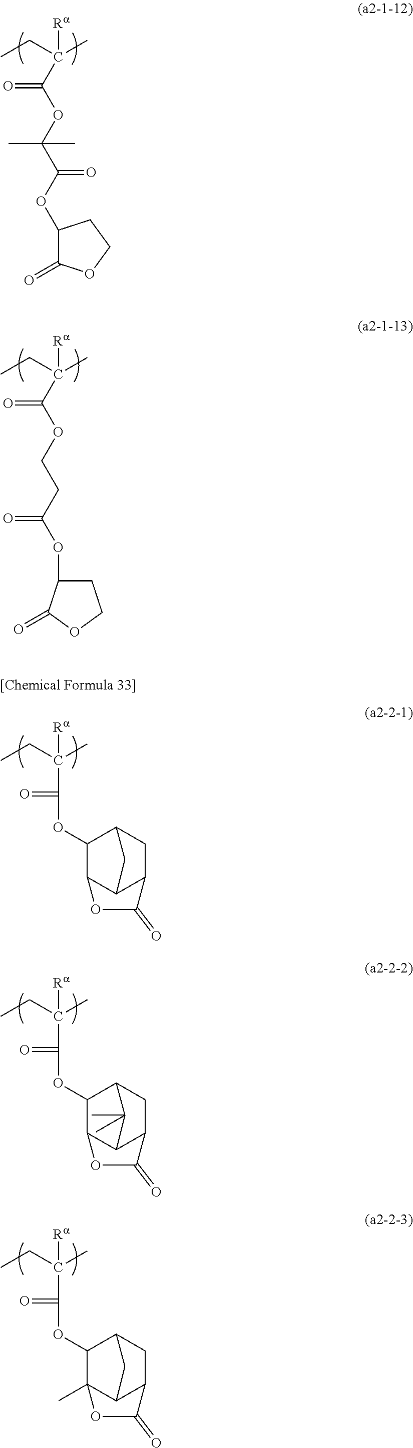

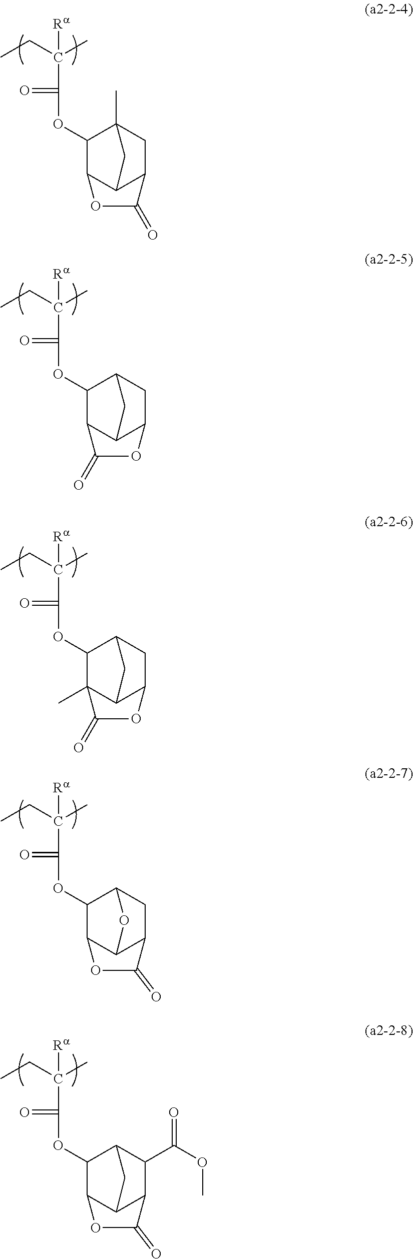

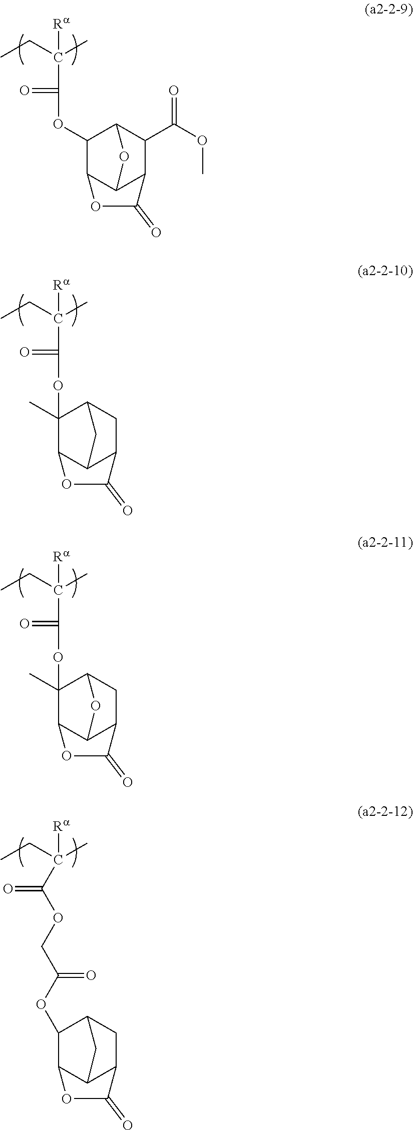

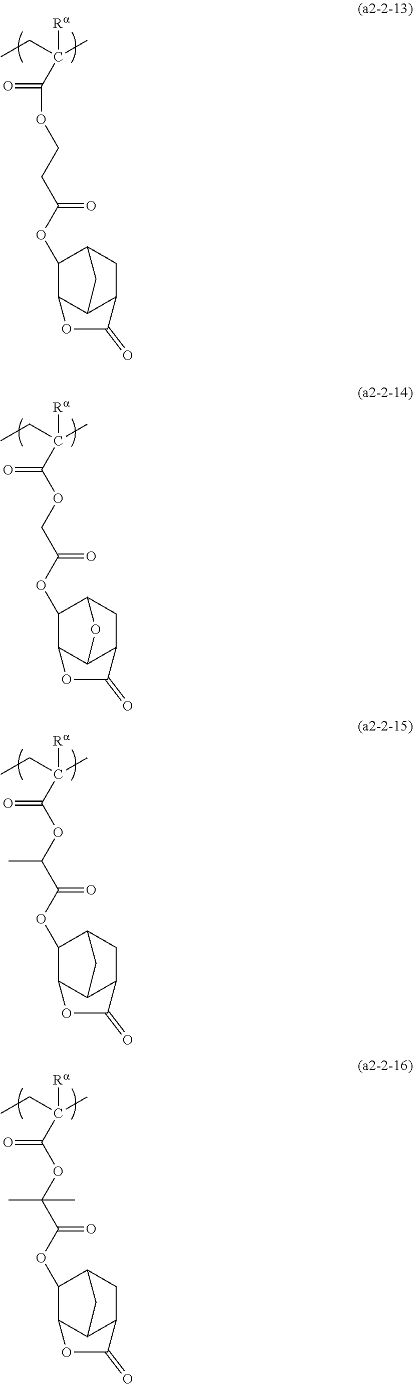

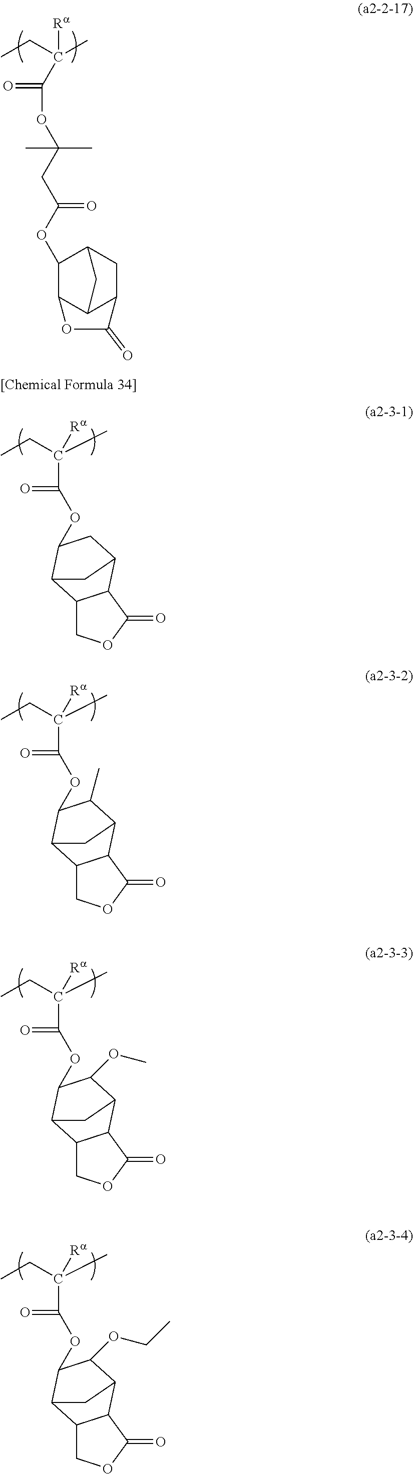

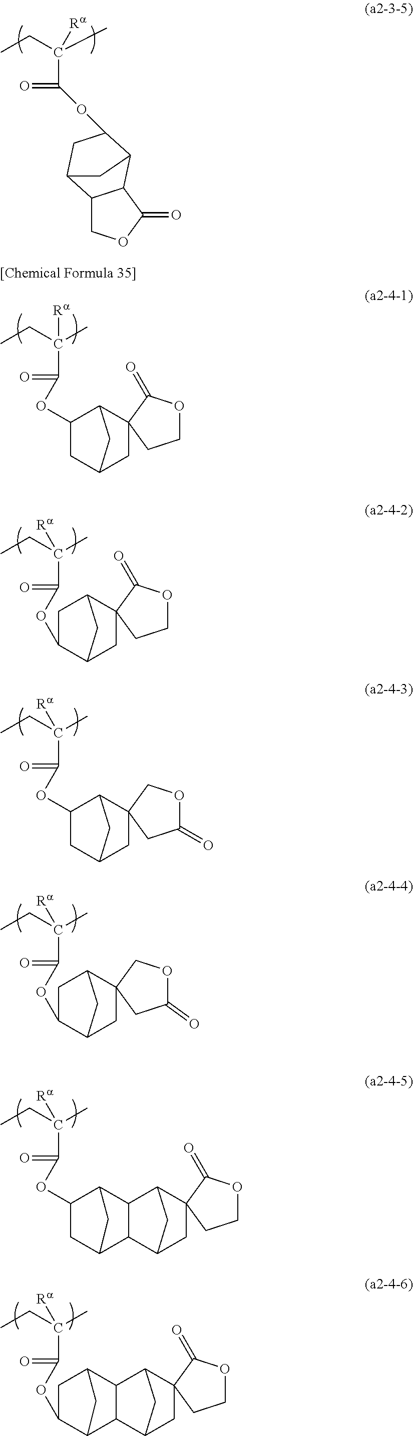

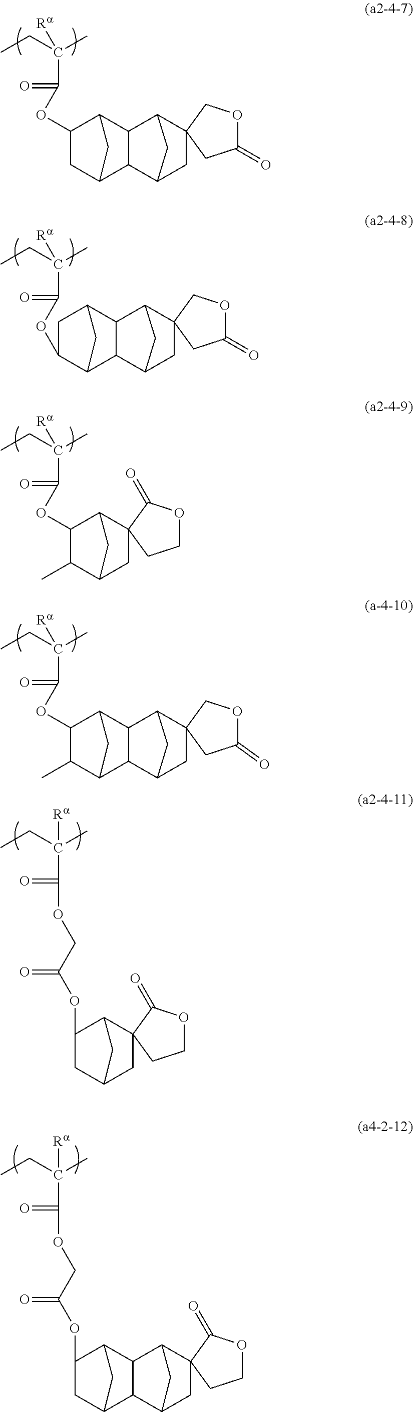

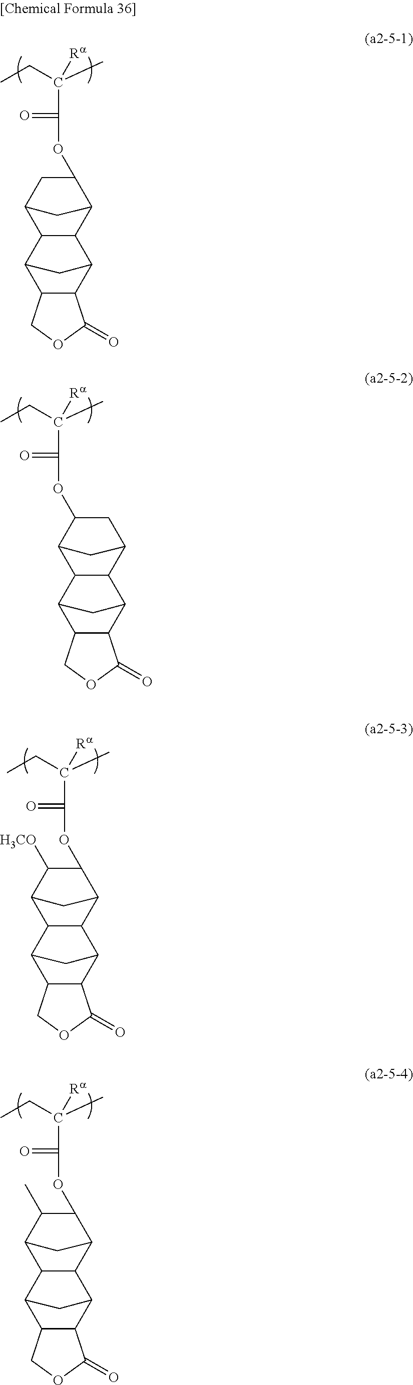

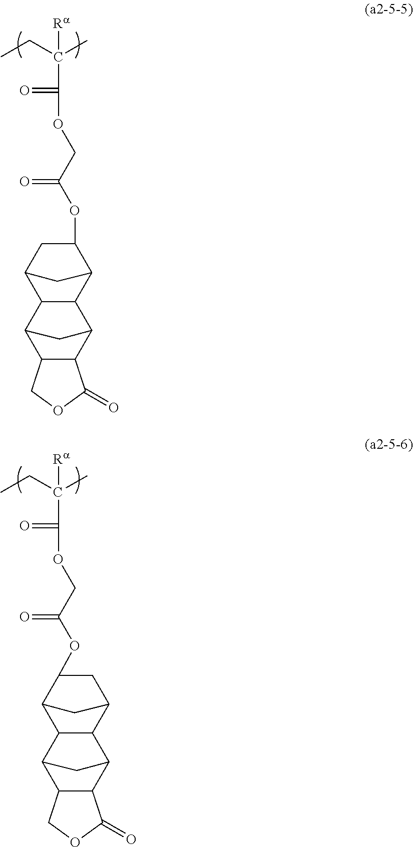

As the structural unit (a2) within the component (A1), one type of structural unit may be used alone, or a combination of two or more types of structural units may be used.

The structural unit (a2) is preferably at least one structural unit selected from the group consisting of structural units represented by general formulas (a2-1) to (a2-5), and is more preferably at least one structural unit selected from the group consisting of structural units represented by general formulas (a2-1) to (a2-3). Of these, it is particularly preferable to use at least one structural unit selected from the group consisting of the structural units represented by chemical formulas (a2-1-1), (a2-1-2), (a2-2-1), (a2-2-7), (a2-3-1) and (a2-3-5).

The amount of the structural unit (a2) within the component (A1), based on the combined total of all the structural units that constitute the component (A1), is preferably within a range from 5 to 60 mol %, more preferably from 10 to 50 mol %, and most preferably from 20 to 50 mol %. By ensuring that the amount of the structural unit (a2) is at least as large as the lower limit of the above range, the effects generated by including the structural unit (a2) are obtained satisfactorily, whereas by ensuring that the amount is not more than the upper limit of the above range, a good balance can be achieved with the other structural units.

—Structural Unit (a3):

The structural unit (a3) is a structural unit which is derived from an acrylate ester in which an atom other than a hydrogen atom or a substituent may be bonded to the carbon atom on the α-position, and contains a polar group-containing aliphatic hydrocarbon group.

By including the structural unit (a3) within the component (A1), the hydrophilicity of the component (A) is improved, and the compatibility with the developing solution is improved. As a result, the alkali solubility of the exposed portions improves, which contributes to a favorable improvement in the resolution.

Examples of the polar group include a hydroxyl group, cyano group, carboxyl group, or fluorinated alcohol group (a hydroxyalkyl group in which some of the hydrogen atoms of the alkyl group have been substituted with fluorine atoms), although a hydroxyl group is particularly desirable.

In the structural unit (a3), although there are no particular limitations on the number of polar groups bonded to the aliphatic hydrocarbon group, 1 to 3 polar groups is preferable, and one polar group is the most desirable.

Examples of the aliphatic hydrocarbon group to which the polar group is bonded include linear or branched hydrocarbon groups (and preferably alkylene groups) of 1 to 10 carbon atoms, and cyclic aliphatic hydrocarbon groups (cyclic groups). These cyclic groups may be either monocyclic or polycyclic, and can be selected appropriately from the multitude of groups that have been proposed for the resins of resist compositions designed for use with ArF excimer lasers. The cyclic group is preferably a polycyclic group, which most preferably contains 7 to 30 carbon atoms.

The structural unit (a3) is preferably a structural unit derived from an acrylate ester that includes an aliphatic polycyclic group containing a hydroxyl group, cyano group, carboxyl group or fluorinated alcohol group. Examples of the polycyclic group include groups in which two or more hydrogen atoms have been removed from a bicycloalkane, tricycloalkane or tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid.

On the other hand, when the hydrocarbon group within the polar group-containing aliphatic hydrocarbon group is a polycyclic group, the structural unit (a3) is preferably a structural unit represented by general formula (a3-1), (a3-2) or (a3-3) shown below. Among these structural units, a structural unit represented by general formula (a3-1) is particularly desirable.

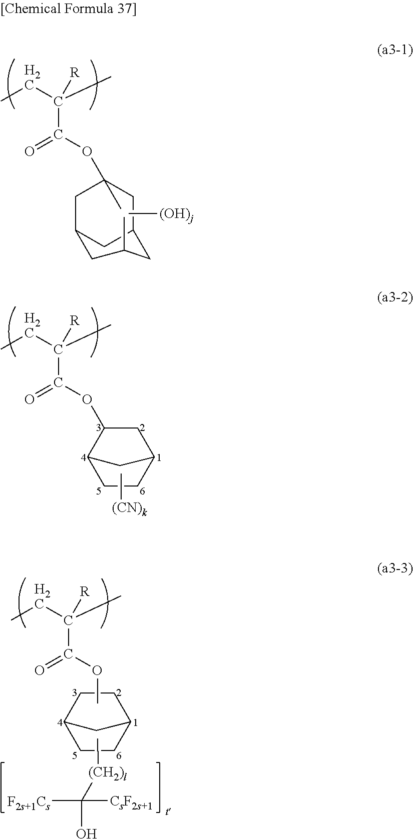

In the formulas, R is the same as defined above, j represents an integer of 1 to 3, k represents an integer of 1 to 3, t′ represents an integer of 1 to 3, 1 represents an integer of 1 to 5, and s represents an integer of 1 to 3.

In formula (a3-1), j is preferably 1 or 2, and more preferably 1. When j is 2, it is preferable that the hydroxyl groups are bonded to the 3rd and 5th positions of the adamantyl group. When j is 1, it is preferable that the hydroxyl group is bonded to the 3rd position of the adamantyl group.

j is preferably 1, and it is particularly desirable that the hydroxyl group is bonded to the 3rd position of the adamantyl group.

In formula (a3-2), k is preferably 1. The cyano group is preferably bonded to the 5th or 6th position of the norbornyl group.

In formula (a3-3), t′ is preferably 1. 1 is preferably 1. s is preferably 1. Further, in formula (a3-3), it is preferable that a 2-norbornyl group or 3-norbornyl group is bonded to the terminal of the carboxyl group of the acrylic acid. The fluorinated alkyl alcohol is preferably bonded to the 5th or 6th position of the norbornyl group.

As the structural unit (a3), one type of structural unit may be used alone, or a combination of two or more types of structural units may be used.

The amount of the structural unit (a3) within the component (A1), based on the combined total of all the structural units that constitute the component (A1), is preferably within a range from 5 to 50 mol %, more preferably from 5 to 40 mol %, and still more preferably from 5 to 25 mol %. By ensuring that the amount of the structural unit (a3) is at least as large as the lower limit of the above range, the effects generated by including the structural unit (a3) are obtained satisfactorily, whereas by ensuring that the amount is not more than the upper limit of the above range, a good balance can be achieved with the other structural units.

—Structural Unit (a0):

The structural unit (a0) is a structural unit which is derived from an acrylate ester in which an atom other than a hydrogen atom or a substituent may be bonded to the carbon atom on the α-position, and contains an —S(═O)₂-containing cyclic group.

Examples of preferred forms of the structural unit (a0) include structural units represented by general formula (a0-1) shown below.

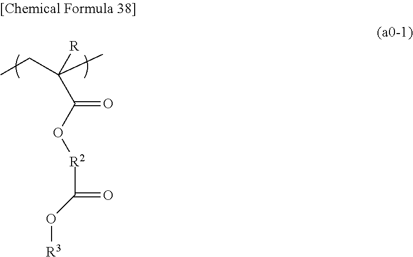

In formula (a0-1), R represents a hydrogen atom, an alkyl group of 1 to 5 carbon atoms, or a halogenated alkyl group of 1 to 5 carbon atoms, R² represents a divalent linking group, and R³ represents a cyclic group that includes —S(═O)₂— within the ring structure.

In formula (a0-1), R is the same as defined above for R in the structural unit (a1).

In formula (a0-1), R² represents a divalent linking group.

R² is preferably a divalent hydrocarbon group which may have a substituent, or a divalent linking group containing a hetero atom.

The hydrocarbon group for R² may be an aliphatic hydrocarbon group or an aromatic hydrocarbon group, and is the same as defined above for “the hydrocarbon group for A” mentioned within the description for Y² in general formula (a1-0-2).

The divalent linking group containing a hetero atom for R² is the same as defined above for the “divalent linking group containing a hetero atom” for Y² in general formula (a1-0-2).

In the present invention, the divalent linking group for R² is preferably an alkylene group, a divalent aliphatic cyclic group, or a divalent linking group containing a hetero atom. Among these groups, an alkylene group is particularly desirable.

When R² is an alkylene group, the alkylene group preferably contains 1 to 10 carbon atoms, more preferably 1 to 6 carbon atoms, still more preferably 1 to 4 carbon atoms, and most preferably 1 to 3 carbon atoms. Specific examples include the same groups as those mentioned above for the linear alkylene groups and branched alkylene groups.

When R² is a divalent aliphatic cyclic group, examples of the aliphatic cyclic group include the same groups as the cyclic aliphatic hydrocarbon groups described above for the “aliphatic hydrocarbon group that includes a ring within the structure”.

As the aliphatic cyclic group, groups in which two or more hydrogen atoms have been removed from cyclopentane, cyclohexane, norbornane, isobornane, adamantane, tricyclodecane or tetracyclododecane are particularly desirable.

When R² is a divalent linking group containing a hetero atom, examples of preferred divalent linking groups include —O—, —C(═O)—O—, —C(═O)—, —O—C(═O)—O—, —C(═O)—NH—, —NR⁰⁴— (wherein R⁰⁴ represents a substituent such as an alkyl group or acyl group), —S—, —S(═O)₂—, —S(═O)₂—O—, groups represented by the formula -A-O—B—, and groups represented by the formula -[A-C(═O)—O]_{d}—B—. Here, each of A and B independently represents a divalent hydrocarbon group which may have a substituent, and is the same as defined above for A and B. d represents an integer of 0 to 3.

Examples of the divalent hydrocarbon group which may have a substituent for A and B include the same groups as those mentioned above for the “divalent hydrocarbon group which may have a substituent” for R².

A is preferably a linear aliphatic hydrocarbon group, more preferably a linear alkylene group, still more preferably a linear alkylene group of 1 to 5 carbon atoms, and most preferably a methylene group or an ethylene group.

B is preferably a linear or branched aliphatic hydrocarbon group, and a methylene group, an ethylene group or an alkylmethylene group is particularly desirable. The alkyl group within the alkylmethylene group is preferably a linear alkyl group of 1 to 5 carbon atoms, more preferably a linear alkyl group of 1 to 3 carbon atoms, and most preferably a methyl group.

Furthermore, in the group represented by the formula -[A-C(═O)—O]_{d}—B—, d represents an integer of 0 to 3, and is preferably an integer of 0 to 2, more preferably 0 or 1, and most preferably 1.

R² may or may not have an acid-dissociable moiety in the structure.

An “acid-dissociable moiety” refers to a moiety within the structure of R² which is dissociated under the action of the acid generated upon exposure. When R² has an acid-dissociable moiety, it is preferable that the acid-dissociable moiety has a tertiary carbon atom.

In formula (a0-1), R³ represents a cyclic group that includes —S(═O)₂— within the ring structure. Specifically, R³ represents a cyclic group in which the sulfur atom (S) of the —S(═O)₂— forms a part of the ring structure of the cyclic group.

The cyclic group for R³ describes the cyclic group that includes —S(═O)₂— within the ring structure. This ring that includes —S(═O)₂— is counted as the first ring, and groups containing only this ring are referred to as monocyclic groups, whereas groups containing other ring structures are described as polycyclic groups regardless of the structure of the other rings. The cyclic group for R³ may be either a monocyclic group or a polycyclic group.

Of the various possibilities, R³ is preferably a cyclic group containing —O—S(═O)₂— within the ring structure, namely a cyclic group containing a sultone ring in which the —O—S— within the —O—S(═O)₂— forms a part of the ring structure.

The cyclic group for R³ preferably contains 3 to 30 carbon atoms, more preferably 4 to 20 carbon atoms, still more preferably 4 to 15 carbon atoms, and most preferably 4 to 12 carbon atoms.

Here, the number of carbon atoms refers to the number of carbon atoms that constitute the ring structure, and does not include carbon atoms contained within substituents.

The cyclic group for R³ may be an aliphatic cyclic group or an aromatic cyclic group, but is preferably an aliphatic cyclic group.

Examples of the aliphatic cyclic group for R³ include groups in which some of the carbon atoms that constitute the ring structure of an aforementioned hydrocarbon group for R², namely a cyclic aliphatic hydrocarbon group mentioned within the above description of the “hydrocarbon group for A”, have been substituted with either —S(═O)₂— or —O—S(═O)₂—.

More specific examples of monocyclic groups include groups in which one hydrogen atom has been removed from a monocycloalkane in which a —CH₂— moiety that constitutes part of the ring structure has been substituted with —S(═O)₂—, and groups in which one hydrogen atom has been removed from a monocycloalkane in which a —CH₂—CH₂— moiety that constitutes part of the ring structure has been substituted with —O—S(═O)₂—. Further, specific examples of polycyclic groups include groups in which one hydrogen atom has been removed from a polycycloalkane (such as a bicycloalkane, tricycloalkane or tetracycloalkane) in which a —CH₂— moiety that constitutes part of the ring structure has been substituted with —S(═O)₂—, and groups in which one hydrogen atom has been removed from a polycycloalkane in which a —CH₂—CH₂— moiety that constitutes part of the ring structure has been substituted with —O—S(═O)₂—.

The cyclic group for R³ may have a substituent. Examples of the substituent include an alkyl group, alkoxy group, halogen atom, halogenated alkyl group, hydroxyl group, oxygen atom (═O), —COOR″, —OC(═O)R″, hydroxyalkyl group and cyano group. Here, R″ represents a hydrogen atom or an alkyl group, and is the same as R″ defined above.

The alkyl group for the substituent is preferably an alkyl group of 1 to 6 carbon atoms. The alkyl group is preferably a linear or branched group. Specific examples include a methyl group, ethyl group, propyl group, isopropyl group, n-butyl group, isobutyl group, tert-butyl group, pentyl group, isopentyl group, neopentyl group or hexyl group. Among these, a methyl group or ethyl group is preferred, and a methyl group is particularly desirable.

The alkoxy group for the substituent is preferably an alkoxy group of 1 to 6 carbon atoms. The alkoxy group is preferably a linear or branched group. Specific examples include groups in which an oxygen atom (—O—) is bonded to any of the alkyl groups described above as a substituent.

Examples of the halogen atom for the substituent include a fluorine atom, chlorine atom, bromine atom or iodine atom, and a fluorine atom is preferable.

Examples of the halogenated alkyl group for the substituent include groups in which some or all of the hydrogen atoms of an aforementioned alkyl group substituent have each been substituted with an aforementioned halogen atom. A fluorinated alkyl group is preferred as the halogenated alkyl group, and a perfluoroalkyl group is particularly desirable.

In the aforementioned —COOR″ group and —OC(═O)R″ group, R″ is preferably a hydrogen atom, or a linear, branched or cyclic alkyl group of 1 to 15 carbon atoms.

In those cases where R″ represents a linear or branched alkyl group, the alkyl group preferably contains 1 to 10 carbon atoms, and more preferably 1 to 5 carbon atoms, and is most preferably a methyl group or ethyl group.

In those cases where R″ is a cyclic alkyl group, the alkyl group preferably contains 3 to 15 carbon atoms, more preferably 4 to 12 carbon atoms, and most preferably 5 to 10 carbon atoms. Examples of the cyclic alkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

The hydroxyalkyl group for the substituent preferably contains 1 to 6 carbon atoms, and specific examples thereof include groups in which at least one hydrogen atom within an aforementioned alkyl group substituent has been substituted with a hydroxyl group.

More specific examples of R³ include groups represented by general formulas (3-1) to (3-4) shown below.

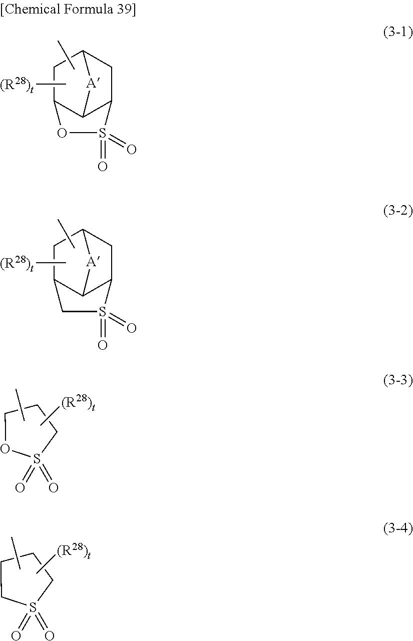

In the formulas, A′ represents an oxygen atom, a sulfur atom, or an alkylene group of 1 to 5 carbon atoms which may contain an oxygen atom or a sulfur atom, t represents an integer of 0 to 2, and R²⁸ represents an alkyl group, alkoxy group, halogenated alkyl group, hydroxyl group, —COOR″, —OC(═O)R″, hydroxyalkyl group or cyano group, wherein R″ represents a hydrogen atom or an alkyl group.

In general formulas (3-1) to (3-4) above, A′ represents an oxygen atom (—O—), a sulfur atom (—S—), or an alkylene group of 1 to 5 carbon atoms which may contain an oxygen atom or a sulfur atom.

As the alkylene group of 1 to 5 carbon atoms for A′, a linear or branched alkylene group is preferable, and specific examples include a methylene group, ethylene group, n-propylene group and isopropylene group.

Examples of the alkylene groups which contain an oxygen atom or a sulfur atom include the aforementioned alkylene groups in which —O— or —S— is either bonded to the terminal of the alkylene group or interposed within the alkylene group. Specific examples of such alkylene groups include —O—CH₂—, —CH₂—O—CH₂—, —S—CH₂— and —CH₂—S—CH₂—.

A′ is preferably an alkylene group of 1 to 5 carbon atoms or —O—, more preferably an alkylene group of 1 to 5 carbon atoms, and most preferably a methylene group.

t represents an integer of 0 to 2, and is most preferably 0.

When t is 2, the plurality of R²⁸ groups may be the same or different.

Examples of the alkyl group, alkoxy group, halogenated alkyl group, —COOR″ group, —OC(═O)R″ group and hydroxyalkyl group for R²⁸ include the same alkyl groups, alkoxy groups, halogenated alkyl groups, —COOR″ groups, —OC(═O)R″ groups and hydroxyalkyl groups as those described above for the substituent which the cyclic group for R³ may have.

Specific examples of the cyclic groups represented by general formulas (3-1) to (3-4) are shown below. In the formulas shown below, “Ac” represents an acetyl group.

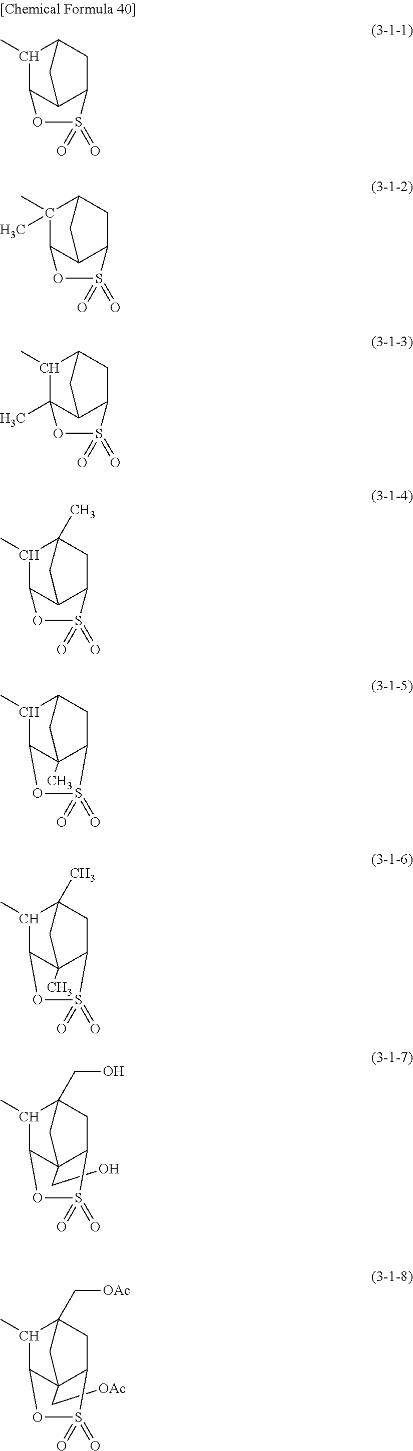

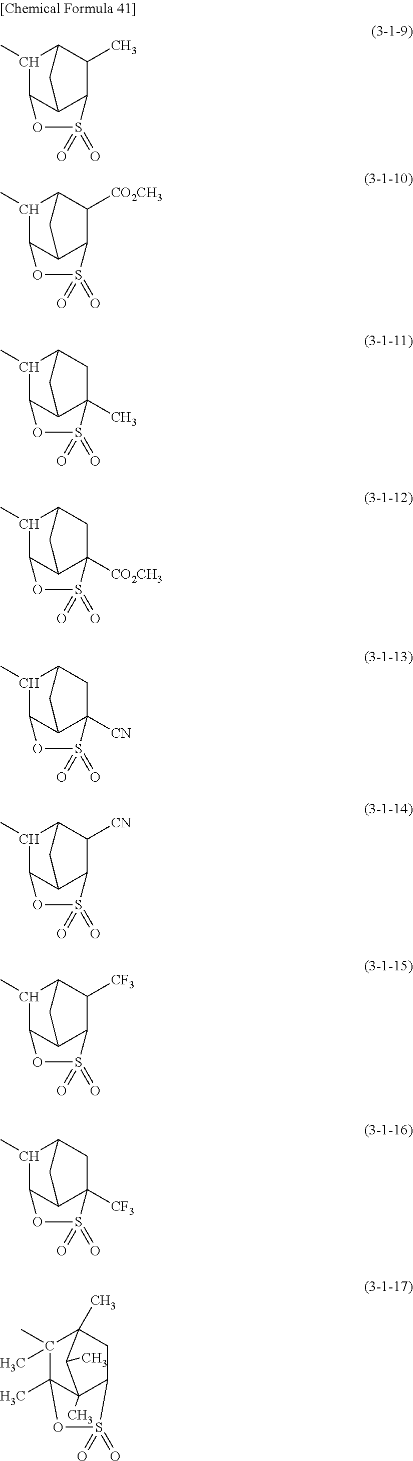

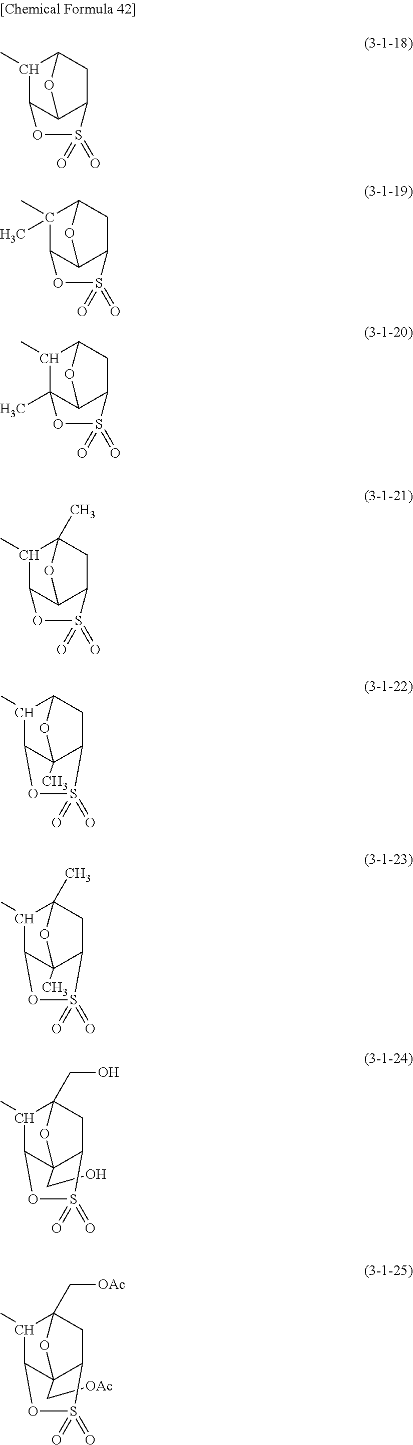

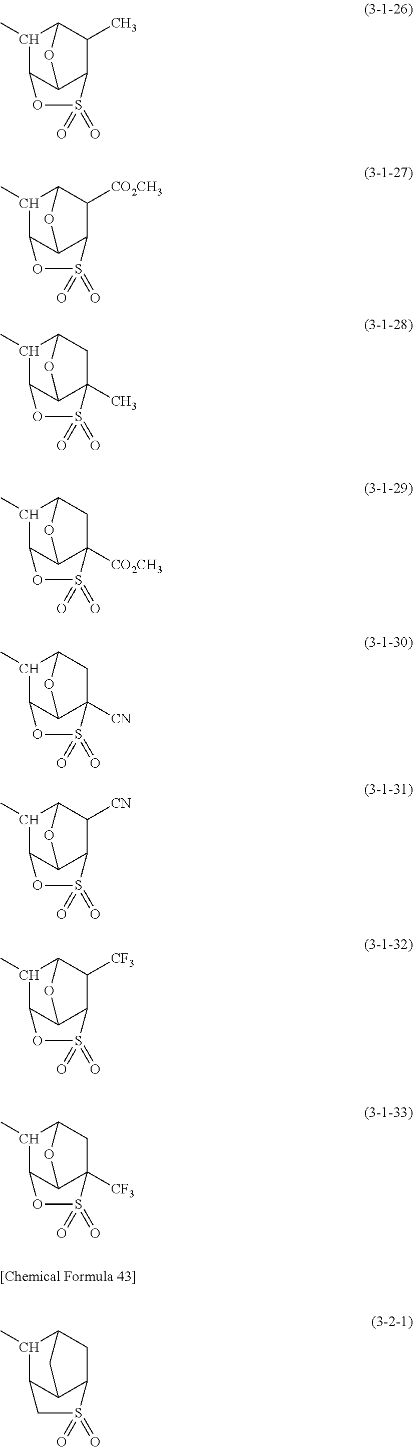

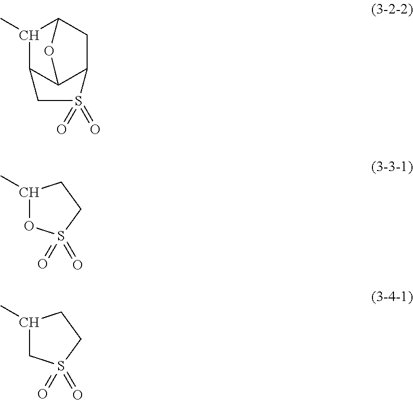

Among the above groups, R³ is preferably a cyclic group represented by general formula (3-1), (3-3) or (3-4), and cyclic groups represented by general formula (3-1) are particularly desirable.

Specifically, R³ is preferably at least one group selected from the group consisting of cyclic groups represented by the above chemical formulas (3-1-1), (3-1-18), (3-3-1) and (3-4-1), and is most preferably a cyclic group represented by chemical formula (3-1-1).

In the present invention, a structural unit represented by general formula (a0-1-11) shown below is particularly desirable as the structural unit (a0).

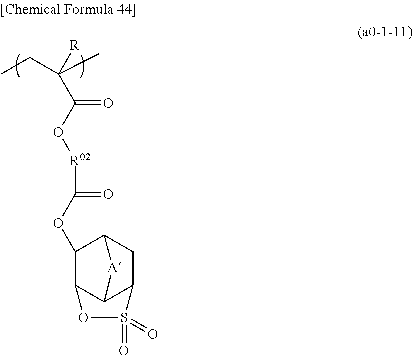

In the formula, R is the same as defined above, R⁰² represents a linear or branched alkylene group or a group represented by -A-C(═O)—O—B—(wherein A and B are the same as defined above), and A′ is the same as defined above.

The linear or branched alkylene group for R⁰² preferably contains 1 to 10 carbon atoms, more preferably 1 to 8 carbon atoms, still more preferably 1 to 5 carbon atoms, still more preferably 1 to 3 carbon atoms, and most preferably 1 or 2 carbon atoms.

In the group represented by -A-C(═O)—O—B—, each of A and B preferably represents a linear or branched alkylene group, more preferably an alkylene group of 1 to 5 carbon atoms, and most preferably a methylene group or an ethylene group. Specific examples include —(CH₂)₂—C(═O)—O—(CH₂)₂— and —(CH₂)₂—O—C(═O)—(CH₂)₂—.

A′ is preferably a methylene group, an oxygen atom (—O—) or a sulfur atom (—S—).

As the structural unit (a0), one type of structural unit may be used alone, or a combination of two or more types of structural units may be used.

In the component (A1), the amount of the structural unit (a0), based on the combined total of all the structural units that constitute the component (A1), is preferably within a range from 1 to 60 mol %, more preferably from 5 to 55 mol %, still more preferably from 10 to 50 mol %, and most preferably from 15 to 45 mol %. Provided that the amount of the structural unit (a0) is at least as large as the lower limit of the above range, the formed resist pattern exhibits superior lithography properties such as exposure latitude (EL margin) and line width roughness (LWR), whereas provided that the amount is not more than the upper limit of the above range, a good balance can be achieved with the other structural units.

### —Other Structural Units:

The component (A1) may also include a structural unit other than the structural units (a1) to (a3) and (a0) described above, provided this other structural unit does not impair the effects of the present invention.

There are no particular limitations on this other structural unit, and any other structural unit which cannot be classified as one of the above structural units (a1) to (a3) or (a0) can be used. For example, any of the multitude of conventional structural units used within resist resins for ArF excimer lasers or KrF excimer lasers (and particularly for ArF excimer lasers) can be used.

Examples of this other structural unit include a structural unit (a4) derived from an acrylate ester containing a non-acid-dissociable aliphatic polycyclic group.

—Structural Unit (a4):

Examples of the aliphatic polycyclic group in the structural unit (a4) include the same groups as those mentioned above for the structural unit (a1), and any of the multitude of conventional polycyclic groups used within the resin components of resist compositions for ArF excimer lasers or KrF excimer lasers (and particularly for ArF excimer lasers) can be used. In terms of industrial availability and the like, at least one polycyclic group selected from among a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include units with structures represented by general formulas (a4-1) to (a4-5) shown below.

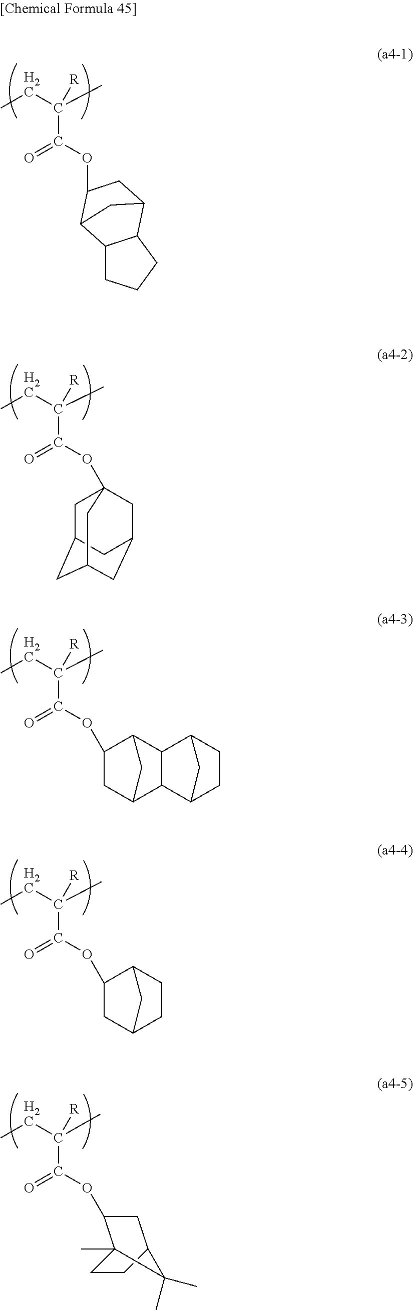

In the formulas, R is the same as defined above.

When the structural unit (a4) is included in the component (A1), the amount of the structural unit (a4) based on the combined total of all the structural units that constitute the component (A1) is preferably within a range from 1 to 30 mol %, and more preferably from 10 to 20 mol %.

The component (A1) is preferably a copolymer containing the structural unit (a1). Further, the component (A1) is preferably a copolymer containing the structural unit (a1) and at least one structural unit selected from the group consisting of the structural unit (a0) and the structural unit (a2), and copolymers that also contain the structural unit (a3) in addition to the above structural units are also desirable.

Specific examples of these copolymers include copolymers consisting of the structural units (a1), (a2) and (a3), copolymers consisting of the structural units (a1), (a2), (a3) and (a0), and copolymers consisting of the structural units (a1), (a2), (a3) and (a4).

In the component (A), the component (A1) may be a single polymer or a combination of two or more polymers.

The weight-average molecular weight (Mw) (the polystyrene equivalent value determined by gel permeation chromatography (GPC)) of the component (A1) is not particularly limited, but is preferably within a range from 1,000 to 50,000, more preferably from 1,500 to 30,000, and most preferably from 2,000 to 20,000. By ensuring that the weight-average molecular weight is not more than the upper limit of the aforementioned range, the component (A1) exhibits satisfactory solubility in a resist solvent when used as a resist, whereas by ensuring that the weight-average molecular weight is at least as large as the lower limit of the above range, dry etching resistance and the cross-sectional shape of the resist pattern are improved.

Further, the dispersity (Mw/Mn) of the component (A1) is not particularly limited, but is preferably from 1.0 to 5.0, more preferably from 1.0 to 3.0, and most preferably from 1.0 to 2.5. Here, Mn is the number-average molecular weight.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH during the above polymerization, a —C(CF₃)₂—OH group can be introduced at the terminals of the component (A1). Such a copolymer having an introduced hydroxyalkyl group in which some of the hydrogen atoms of the alkyl group have been substituted with fluorine atoms is effective in reducing developing defects and line edge roughness (LER: unevenness in the side walls of a line pattern).

In terms of the monomers used for forming each of the structural units, either commercially available monomers may be used, or the monomers may be synthesized using conventional methods.

For example, examples of monomers that yield the structural unit (a0) include compounds represented by general formula (a0-1-0) shown below (hereafter referred to as “compound (a0-1-0)”).

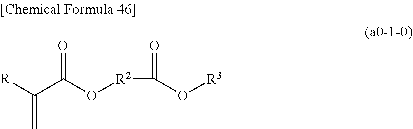

In formula (a0-1-0), R, R² and R³ are each the same as defined above.

There are no particular limitations on the method used for producing the compound (a0-1-0), and conventional methods can be used.

For example, in the presence of a base, a compound (X-2) represented by general formula (X-2) shown below may be added to a solution obtained by dissolving a compound (X-1) represented by general formula (X-1) shown below in a reaction solvent, and a reaction then performed to obtain the compound (a0-1-0).

Examples of the base include inorganic bases such as sodium hydride, K₂CO₃ and Cs₂CO₃, and organic bases such as triethylamine, 4-dimethylaminopyridine (DMAP) and pyridine. Examples of condensing agents include carbodiimide reagents such as ethyldiisopropylaminocarbodiimide hydrochloride (EDCI), dicyclohexylcarboxylmide (DCC), diisopropylcarbodiimide and carbodiimidazole, as well as tetraethyl pyrophosphate and benzotriazole-N-hydroxytrisdimethylaminophosphonium hexafluorophosphide (Bop reagent).

If desired, an acid may be used. As the acid, any acid generally used for dehydration/condensation may be used. Specific examples include inorganic acids such as hydrochloric acid, sulfuric acid and phosphoric acid, and organic acids such as methanesulfonic acid, trifluoromethanesulfonic acid, benzenesulfonic acid and p-toluenesulfonic acid. These acids may be used individually, or a combination of two or more acids may be used.

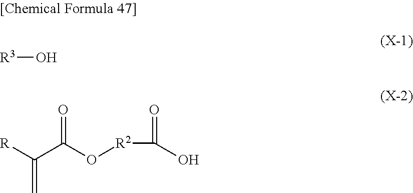

### [Component (A2)]

The component (A2) is preferably a low-molecular weight compound having a molecular weight of at least 500 but less than 4,000, containing a hydrophilic group and an acid-dissociable, dissolution-inhibiting group such as those mentioned above in the description of the component (A1). Specific examples of the component (A2) include compounds containing a plurality of phenol structures in which some of the hydrogen atoms of the hydroxyl groups have each been substituted with an aforementioned acid-dissociable, dissolution-inhibiting group.

Examples of the component (A2) include low-molecular weight phenolic compounds in which a portion of the hydroxyl group hydrogen atoms have each been substituted with an aforementioned acid-dissociable, dissolution-inhibiting group. These types of compounds are known, for example, as sensitizers or heat resistance improvers for use in non-chemically amplified g-line or i-line resists, and any of these compounds may be used.

Examples of these low-molecular weight phenol compounds include linear polyphenol compounds, including bisphenol type compounds such as bis(4-hydroxyphenyl)methane, bis(2,3,4-trihydroxyphenyl)methane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, bis(2,3-trihydroxyphenyl)methane, bis(2,4-dihydroxyphenyl)methane, 2,3,4-trihydroxyphenyl-4′-hydroxyphenylmethane, 2-(2,3,4-trihydroxyphenyl)-2-(2′,3′,4′-trihydroxyphenyl)propane, 2-(2,4-dihydroxyphenyl)-2-(2′,4′-dihydroxyphenyl)propane, 2-(4-hydroxyphenyl)-2-(4′-hydroxyphenyl)propane, 2-(3-fluoro-4-hydroxyphenyl)-2-(3′-fluoro-4′-hydroxyphenyl)propane, 2-(2,4-dihydroxyphenyl)-2-(4′-hydroxyphenyl)propane, 2-(2,3,4-trihydroxyphenyl)-2-(4′-hydroxyphenyl)propane, and 2-(2,3,4-trihydroxyphenyl)-2-(4′-hydroxy-3′,5′-dimethylphenyl)propane; trisphenol type compounds such as tris(4-hydroxyphenyl)methane, bis(4-hydroxy-3-methylphenyl)-2-hydroxyphenylmethane, bis(4-hydroxy-2,3,5-trimethylphenyl)-2-hydroxyphenylmethane, bis(4-hydroxy-3,5-dimethylphenyl)-4-hydroxyphenylmethane, bis(4-hydroxy-3,5-dimethylphenyl)-3-hydroxyphenylmethane, bis(4-hydroxy-3,5-dimethylphenyl)-2-hydroxyphenylmethane, bis(4-hydroxy-2,5-dimethylphenyl)-4-hydroxyphenylmethane, bis(4-hydroxy-2,5-dimethylphenyl)-3-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-2,5-dimethylphenyl)-2,4-dihydroxyphenylmethane, bis(4-hydroxyphenyl)-3-methoxy-4-hydroxyphenylmethane, bis(5-cyclohexyl-4-hydroxy-2-methylphenyl)-4-hydroxyphenylmethane, bis(5-cyclohexyl-4-hydroxy-2-methylphenyl)-3-hydroxyphenylmethane, bis(5-cyclohexyl-4-hydroxy-2-methylphenyl)-2-hydroxyphenylmethane, and bis(5-cyclohexyl-4-hydroxy-2-methylphenyl)-3,4-dihydroxyphenylmethane; linear trinuclear phenol compounds such as 2,4-bis(3,5-dimethyl-4-hydroxybenzyl)-5-hydroxyphenol and 2,6-bis(2,5-dimethyl-4-hydroxybenzyl)-4-methylphenol; linear tetranuclear phenol compounds such as 1,1-bis[3-(2-hydroxy-5-methylbenzyl)-4-hydroxy-5-cyclohexylphenyl]isopropane, bis[2,5-dimethyl-3-(4-hydroxy-5-methylbenzyl)-4-hydroxyphenyl]methane, bis[2,5-dimethyl-3-(4-hydroxybenzyl)-4-hydroxyphenyl]methane, bis[3-(3,5-dimethyl-4-hydroxybenzyl)-4-hydroxy-5-methylphenyl]methane, bis[3-(3,5-dimethyl-4-hydroxybenzyl)-4-hydroxy-5-ethylphenyl]methane, bis[3-(3,5-diethyl-4-hydroxybenzyl)-4-hydroxy-5-methylphenyl]methane, bis[3-(3,5-diethyl-4-hydroxybenzyl)-4-hydroxy-5-ethylphenyl]methane, bis[2-hydroxy-3-(3,5-dimethyl-4-hydroxybenzyl)-5-methylphenyl]methane, bis[2-hydroxy-3-(2-hydroxy-5-methylbenzyl)-5-methylphenyl]methane, bis[4-hydroxy-3-(2-hydroxy-5-methylbenzyl)-5-methylphenyl]methane, and bis[2,5-dimethyl-3-(2-hydroxy-5-methylbenzyl)-4-hydroxyphenyl]methane; and linear pentanuclear phenol compounds such as 2,4-bis[2-hydroxy-3-(4-hydroxybenzyl)-5-methylbenzyl]-6-cyclohexylphenol, 2,4-bis[4-hydroxy-3-(4-hydroxybenzyl)-5-methylbenzyl]-6-cyclohexylphenol, and 2,6-bis[2,5-dimethyl-3-(2-hydroxy-5-methylbenzyl)-4-hydroxybenzyl]-4-methylphenol; as well as polynuclear branched compounds such as 1-[1-(4-hydroxyphenyl)isopropyl]-4-[1,1-bis(4-hydroxyphenyl)ethyl]benzene and 1-[1-(3-methyl-4-hydroxyphenyl)isopropyl]-4-[1,1-bis(3-methyl-4-hydroxyphenyl)ethyl]benzene; and dimers through to dodecamers of formalin condensation products of phenols such as phenol, m-cresol, p-cresol and xylenol. Needless to say, the low-molecular weight phenol compound is not limited to these examples.

Furthermore, there are no particular limitations on the acid-dissociable, dissolution-inhibiting group, and suitable examples include the groups described above.

As the component (A), one type of compound may be used alone, or a combination of two or more types of compounds may be used.

In the positive-type resist composition, the amount of the component (A) may be adjusted appropriately in accordance with factors such as the thickness of the resist film that is to be formed.

### [Component (B)]

There are no particular limitations on the component (B), and any of the acid generators that have already been proposed for use in conventional chemically amplified resist compositions can be used.

Examples of these acid generators include the same acid generators as those mentioned above for the “acid generator that generates acid upon exposure” within the description relating to the acid generator component of the aforementioned pattern miniaturization agent.

As the component (B), a single acid generator may be used alone, or a combination of two or more acid generators may be used.

The amount of the component (B) within the positive-type resist composition is preferably within a range from 0.5 to 50 parts by weight, and more preferably from 1 to 40 parts by weight, relative to 100 parts by weight of the component (A). When the amount of the component (B) is within the above range, resist pattern formation can be performed satisfactorily. Further, a uniform solution can be obtained, and the storage stability improves.

### [Optional Components]

The positive-type resist composition used in the present invention may also include a nitrogen-containing organic compound component (hereafter referred to as “component (D)”) as an optional component.

There are no particular limitations on the component (D) provided it functions as an acid diffusion control agent, namely, a quencher which traps the acid generated from the component (B) upon exposure. A multitude of these components (D) have already been proposed, and any of these known compounds may be used.

A low-molecular weight compound (non-polymer) is usually used as the component (D).

Examples of the component (D) include amines such as aliphatic amines and aromatic amines, and of these, an aliphatic amine is preferred, and a secondary aliphatic amine or tertiary aliphatic amine is particularly desirable. Here, an “aliphatic amine” describes an amine having one or more aliphatic groups, wherein each of the aliphatic groups preferably contains 1 to 20 carbon atoms.

Examples of these aliphatic amines include amines in which at least one hydrogen atom of ammonia (NH₃) has been substituted with an alkyl group or hydroxyalkyl group of not more than 20 carbon atoms (namely, alkylamines or alkyl alcohol amines), and cyclic amines.

Specific examples of these alkylamines and alkyl alcohol amines include monoalkylamines such as n-hexylamine, n-heptylamine, n-octylamine, n-nonylamine and n-decylamine, dialkylamines such as diethylamine, di-n-propylamine, di-n-heptylamine, di-n-octylamine and dicyclohexylamine, trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine and tri-n-dodecylamine, and alkyl alcohol amines such as diethanolamine, triethanolamine, diisopropanolamine, triisopropanolamine, di-n-octanolamine, tri-n-octanolamine, stearyldiethanolamine and lauryldiethanolamine. Among these, trialkylamines and/or alkyl alcohol amines are particularly desirable.

Examples of the cyclic amine include heterocyclic compounds containing a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples include 1,5-diazabicyclo[4.3.0]-5-nonene, 1,8-diazabicyclo[5.4.0]-7-undecene, hexamethylenetetramine and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris {2-(1-methoxyethoxy)ethyl}amine, tris {2-(1-ethoxyethoxy)ethyl}amine, tris {2-(1-ethoxypropoxy)ethyl}amine and tris[2-{2-(2-hydroxyethoxy)ethoxy}ethyl]amine.

Examples of the aromatic amines include aniline, pyridine, 4-dimethylaminopyridine, pyrrole, indole, pyrazole, imidazole and derivatives thereof, as well as diphenylamine, triphenylamine, tribenzylamine, 2,6-diisopropylaniline, 2,2′-dipyridyl, and 4,4′-dipyridyl.

As the component (D), a single compound may be used alone, or a combination of two or more different compounds may be used.

The component (D) is typically used in an amount within a range from 0.01 to 5.0 parts by weight, relative to 100 parts by weight of the component (A). By ensuring that the amount of the component (D) is within the above range, the shape of the resist pattern and the post exposure stability of the latent image formed by the pattern-wise exposure of the resist layer are improved.

In the positive-type resist composition used in the present invention, for the purposes of preventing any deterioration in sensitivity, and improving the resist pattern shape and the post exposure stability of the latent image formed by the pattern-wise exposure of the resist layer, the resist composition may also include at least one compound (E) (hereafter referred to as “component (E)”) selected from the group consisting of organic carboxylic acids, and phosphorus oxo acids and derivatives thereof.

Examples of the organic carboxylic acids include acetic acid, malonic acid, citric acid, malic acid, succinic acid, benzoic acid and salicylic acid.

Examples of the phosphorus oxo acids include phosphoric acid, phosphonic acid and phosphinic acid. Among these, phosphonic acid is particularly desirable.

Examples of the phosphorus oxo acid derivatives include esters in which the hydrogen atom of an aforementioned oxo acid is substituted with a hydrocarbon group. Examples of the hydrocarbon group include alkyl groups of 1 to 5 carbon atoms and aryl groups of 6 to 15 carbon atoms.

Examples of phosphoric acid derivatives include phosphate esters such as di-n-butyl phosphate and diphenyl phosphate.

Examples of phosphonic acid derivatives include phosphonate esters such as dimethyl phosphonate, di-n-butyl phosphonate, diphenyl phosphonate and dibenzyl phosphonate, and phenylphosphonic acid.

Examples of phosphinic acid derivatives include phenylphosphinic acid and phosphinate esters.

As the component (E), one compound may be used alone, or a combination of two or more different compounds may be used.

The component (E) is typically used in an amount within a range from 0.01 to 5.0 parts by weight relative to 100 parts by weight of the component (A).

The positive-type resist composition used in the present invention may further include a polymeric compound (F1) (hereafter referred to as “component (F1)”) having a structural unit (f1) containing a base-dissociable group as an optional component.

Examples of the component (F1) include compounds disclosed in U.S. Patent Application No. 2009/0197204.

The component (F1) is preferably a polymeric compound (fluorine-containing polymeric compound (F1-1)) having the types of structural units shown below.

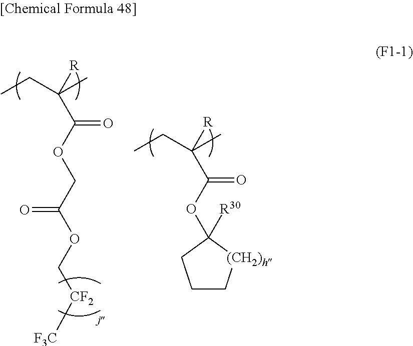

In formula (F1-1), R represents a hydrogen atom, an alkyl group of 1 to 5 carbon atoms or a halogenated alkyl group of 1 to 5 carbon atoms, wherein the plurality of R groups may be the same or different, j″ represents an integer of 0 to 3, R³⁰ represents an alkyl group of 1 to 5 carbon atoms, and h″ represents an integer of 1 to 6.

In formula (F1-1), R is the same as defined above for R in the structural unit (a1).

j″ is preferably an integer of 0 to 2, more preferably 0 or 1, and most preferably 0.

R³⁰ is the same as the alkyl group of 1 to 5 carbon atoms defined for R, and is preferably a methyl group or ethyl group, and most preferably an ethyl group.

h″ is preferably 3 or 4, and most preferably 4.

Although there are no particular limitations on the weight-average molecular weight (Mw) (the polystyrene-equivalent value determined by gel permeation chromatography) of the component (F1), the weight-average molecular weight is preferably within a range from 2,000 to 100,000, more preferably from 3,000 to 100,000, still more preferably from 4,000 to 50,000, and most preferably from 5,000 to 50,000. Provided that the weight-average molecular weight is not more than the upper limit of the above range, the component exhibits satisfactory solubility in the resist solvent when used within a resist, and provided the weight-average molecular weight is at least as large as the lower limit of the above range, the dry etching resistance and resist pattern cross-sectional shape are improved.

Further, the dispersity (Mw/Mn) is preferably within a range from 1.0 to 5.0, more preferably from 1.0 to 3.0, and most preferably from 1.2 to 2.8.

As the component (F1), one type of compound may be used alone, or a combination of two or more types of compounds may be used.

The amount of the component (F1) within the positive-type resist composition is preferably within a range from 0.1 to 50 parts by weight, more preferably from 0.1 to 40 parts by weight, still more preferably from 0.3 to 30 parts by weight, and most preferably from 0.5 to 15 parts by weight, relative to 100 parts by weight of the component (A). Provided that the amount of the component (F1) is at least as large as the lower limit of the above range, the hydrophobicity of a resist film formed using the positive-type resist composition improves, yielding a level of hydrophobicity that is ideal even for liquid immersion lithography. On the other hand, provided that the amount of the component (F1) is not more than the upper limit of the above range, the lithography properties can be improved.

The component (F1) can also be used favorably as an additive for a resist composition for use with liquid immersion lithography.

If desired, other miscible additives can also be added to the positive-type resist composition used in the present invention. Examples of such miscible additives include additive resins for improving the performance of the resist film, surfactants for improving the applicability, dissolution inhibitors, plasticizers, stabilizers, colorants, halation prevention agents, and dyes.

The positive-type resist composition used in the present invention can be produced by dissolving the materials for the resist composition in an organic solvent (hereafter referred to as “component (S)”).

The component (S) may be any organic solvent which can dissolve the respective components to give a uniform solution, and one or more types of organic solvent may be selected appropriately from those solvents which have conventionally been used as solvents for chemically amplified resists.

Examples of the component (S) include lactones such as γ-butyrolactone; ketones such as acetone, methyl ethyl ketone, cyclohexanone (CH), methyl-n-pentyl ketone, methyl isopentyl ketone and 2-heptanone; polyhydric alcohols such as ethylene glycol, diethylene glycol, propylene glycol and dipropylene glycol; polyhydric alcohol derivatives, including compounds having an ester bond such as ethylene glycol monoacetate, diethylene glycol monoacetate, propylene glycol monoacetate and dipropylene glycol monoacetate, and compounds having an ether bond such as a monoalkyl ether (such as a monomethyl ether, monoethyl ether, monopropyl ether or monobutyl ether) or a monophenyl ether of any of the above polyhydric alcohols or compounds having an ester bond [among these derivatives, propylene glycol monomethyl ether acetate (PGMEA) and propylene glycol monomethyl ether (PGME) are preferred]; cyclic ethers such as dioxane; esters such as methyl lactate, ethyl lactate (EL), methyl acetate, ethyl acetate, butyl acetate, methyl pyruvate, ethyl pyruvate, methyl methoxypropionate and ethyl ethoxypropionate; and aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene and mesitylene.

Among these organic solvents, one type of organic solvent may be used alone, or a mixed solvent containing two or more solvents may be used.

Among these, propylene glycol monomethyl ether acetate (PGMEA), propylene glycol monomethyl ether (PGME), γ-butyrolactone, EL and CH are preferred.

Further, among the mixed solvents, a mixed solvent obtained by mixing PGMEA with a polar solvent is preferable. The mixing ratio (weight ratio) of this mixed solvent can be determined appropriately with due consideration of the compatibility of the PGMEA with the polar solvent, but is preferably within a range from 1:9 to 9:1, and more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME ratio is preferably from 1:9 to 9:1, more preferably from 2:8 to 8:2, and still more preferably from 3:7 to 7:3. Further, as the component (S), a mixed solvent of at least one of PGMEA, PGME, CH and EL with γ-butyrolactone is also preferable. The mixing ratio (former:latter) of such a mixed solvent is preferably from 70:30 to 95:5.

The amount used of the component (S) is not particularly limited, and may be adjusted appropriately to a concentration which enables application of a coating solution onto a substrate or the like in accordance with the desired thickness of the coating film. In general, the organic solvent is used in an amount that yields a solid fraction concentration for the resist composition that is within a range from 1 to 20% by weight, and preferably from 2 to 15% by weight.

### <<Pattern Miniaturization Agent>>

The pattern miniaturization agent of the present invention is used in the resist pattern formation method of the present invention described above, and contains an acid generator component and an organic solvent that does not dissolve the resist pattern formed in the aforementioned step (1).

This pattern miniaturization agent is the same as the pattern miniaturization agent described above in relation to the resist pattern formation method of the present invention.

By using the resist pattern formation method and the pattern miniaturization agent of the present invention described above, miniaturization of an already formed resist pattern can be achieved. Further, the resist pattern suffers no detachment from the silicon substrate and no collapse of the resist pattern, and a resist pattern can be formed with very fine dimensions, reduced roughness, and a favorable shape with superior rectangularity.

Moreover, the resist pattern formation method of the present invention enables miniaturization of the resist pattern to be achieved with no limitations associated with the performance of the exposure apparatus or the wavelength of the exposure source.

### EXAMPLES

A more detailed description of the present invention is presented below based on a series of examples, although the present invention is in no way limited by these examples.

### <Preparation of Pattern Miniaturization Agent>

The six components listed below were each dissolved in ethanol in equimolar amounts to prepare a series of pattern miniaturization agents composed of ethanol solutions having a prescribed concentration.

Comparative example 1: methanesulfonic acid (0.0356% by weight)

Comparative example 2: methacrylic acid (3.7% by weight)

Example 1: a thermal acid generator represented by chemical formula (TAG-1) shown below (0.106% by weight)

Example 2: a thermal acid generator represented by chemical formula (TAG-2) shown below (0.143% by weight)

Example 3: a photo-acid generator represented by chemical formula (PAG-1) shown below (0.1236% by weight)

Example 4: a photo-acid generator represented by chemical formula (PAG-2) shown below (0.2275% by weight)

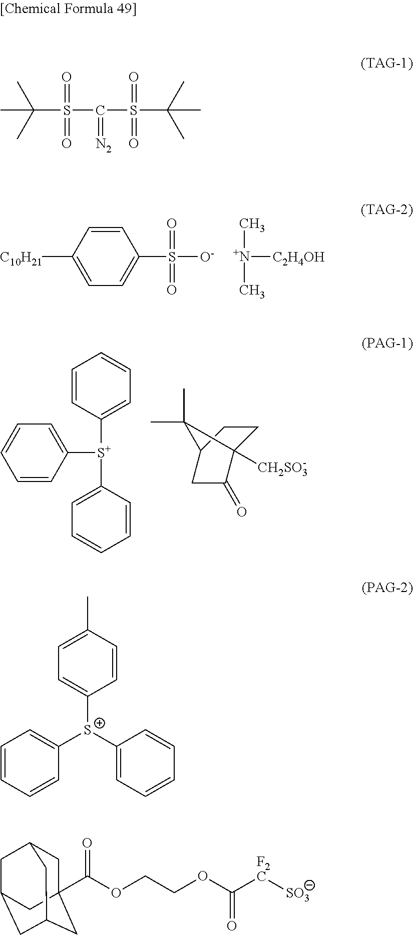

### <Preparation of Chemically Amplified Positive-Type Resist Composition>

The components shown in Table 1 were mixed together and dissolved to prepare a chemically amplified positive-type resist composition.

TABLE 1

| | Compo- | Compo- | Compo- | Compo- |
|---|---|---|---|---|
| | nent (A) | nent (B) | nent (D) | nent (S) |
| Chemically amplified positive- | (A)-1 | (B)-1 | (D)-1 | (S)-1 |
| type resist composition | [100] | [7.91] | [0.75] | [1800] |

In Table 1, the reference symbols refer to the following components, whereas the numerical values in brackets [ ] indicate the amount added (in parts by weight) of the component.

(A)-1: a copolymer represented by chemical formula (A1-1) shown below, having a weight-average molecular weight (Mw) of 10,000 and a dispersity of 1.50. In the formula, the symbol to the bottom right of each set of the parentheses indicates the proportion (mol %) of that particular structural unit within the copolymer, wherein a1:a2:a3=40:40:20.

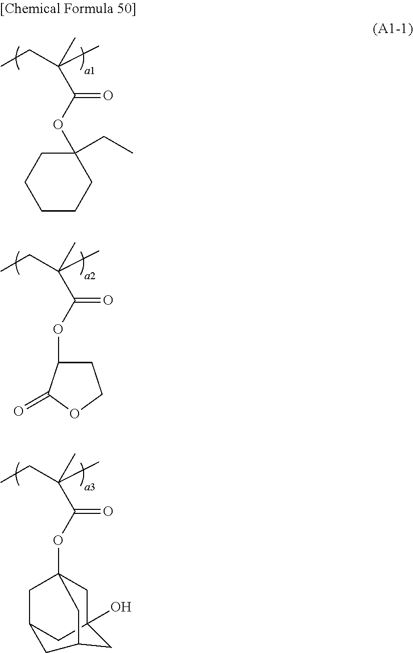

(B)-1: the photo-acid generator represented by the aforementioned chemical formula (PAG-2)

(D)-1: tri-n-pentylamine

(S)-1: a mixed solvent of PGMEA and PGME (PGMEA:PGME=6:4 (weight ratio))

### <Miniaturization of Resist Pattern>

### Comparative Example 3

[Step (1)]

An organic antireflective film composition ARC29 (a product name, manufactured by Brewer Science Ltd.) was applied onto an 8-inch silicon wafer using a spinner, and the composition was then baked and dried on a hotplate at 205° C. for 60 seconds, thereby forming an organic antireflective film having a film thickness of 82 nm.

Next, using a coating apparatus (product name: Clean Track Act8, manufactured by Tokyo Electron Co., Ltd.), the chemically amplified positive-type resist composition described above was spin-coated onto the surface of the organic antireflective film, and a prebake (PAB) treatment was then conducted on a hotplate at 90° C. for 60 seconds to dry the composition, thereby forming a resist film having a thickness of 150 nm.

Subsequently, using an ArF exposure apparatus NSR-S302A (manufactured by Nikon Corporation, NA (numerical aperture)=0.60, ⅔ annular illumination), the resist film was selectively irradiated with an ArF excimer laser (193 nm) through a photomask (6% halftone) targeting a line and space resist pattern (hereafter referred to as an “LS pattern”) having a line width of 140 nm and a pitch of 280 nm.

The resist film was then subjected to a post exposure bake (PEB) treatment at 105° C. for 60 seconds, was subsequently subjected to alkali developing for 30 seconds at 23° C. in a 2.38% by weight aqueous solution of tetramethylammonium hydroxide (TMAH) (NMD-3, a product name, manufactured by Tokyo Ohka Kogyo Co., Ltd.), and was then rinsed for 30 seconds in pure water and shaken dry.

As a result, an LS pattern composed of lines having a width of 140 nm disposed at equal intervals (pitch: 280 nm) was formed on the resist film.

### Comparative Example 4

An LS pattern composed of lines having a width of 140 nm disposed at equal intervals (pitch: 280 nm) was formed in the same manner as that described in [Step (1)].

Subsequently, the LS pattern was subjected to alkali developing for 30 seconds at 23° C. in a 2.38% by weight aqueous solution of tetramethylammonium hydroxide (TMAH) (NMD-3, a product name, manufactured by Tokyo Ohka Kogyo Co., Ltd.).

### Comparative Example 5

An LS pattern composed of lines having a width of 140 nm disposed at equal intervals (pitch: 280 nm) was formed in the same manner as that described in [Step (1)].

Subsequently, the LS pattern was subjected to a bake treatment at 130° C. for 60 seconds, was then subjected to alkali developing for 30 seconds at 23° C. in a 2.38% by weight aqueous solution of tetramethylammonium hydroxide (TMAH) (NMD-3, a product name, manufactured by Tokyo Ohka Kogyo Co., Ltd.), and was then rinsed for 30 seconds in pure water and shaken dry.

### Comparative Example 6

An LS pattern composed of lines having a width of 140 nm disposed at equal intervals (pitch: 280 nm) was formed in the same manner as that described in [Step (1)].

Subsequently, the LS pattern was subjected to a bake treatment at 100° C. for 60 seconds.

### Comparative Example 7

An LS pattern composed of lines having a width of 140 nm disposed at equal intervals (pitch: 280 nm) was formed in the same manner as that described in [Step (1)].

[Step (2′)]

Subsequently, using the coating apparatus described above (product name: Clean Track Act8, manufactured by Tokyo Electron Co., Ltd.), the pattern miniaturization agent of the comparative example 1 was spin-coated onto the LS pattern.

As a result, the LS pattern detached from the silicon wafer, and the resist pattern was unable to be resolved.

### Comparative Example 8

An LS pattern composed of lines having a width of 140 nm disposed at equal intervals (pitch: 280 nm) was formed in the same manner as that described in [Step (1)].

[Step (2′)]

Subsequently, using the coating apparatus described above (product name: Clean Track Act8, manufactured by Tokyo Electron Co., Ltd.), the pattern miniaturization agent of the comparative example 2 was spin-coated onto the LS pattern.

[Step (3′)]

The LS pattern having the pattern miniaturization agent of the comparative example 1 coated thereon was subjected to a bake treatment at 90° C. for 60 seconds.

[Step (4′)]

Following the bake treatment, the LS pattern was subjected to alkali developing for 30 seconds at 23° C. in a 2.38% by weight aqueous solution of tetramethylammonium hydroxide (TMAH) (NMD-3, a product name, manufactured by Tokyo Ohka Kogyo Co., Ltd.), and was then rinsed for 30 seconds in pure water and shaken dry.

As a result, collapse of the LS pattern occurred across the entire surface of the silicon wafer, and the resist pattern could not be resolved.

### Comparative Example 9

An LS pattern composed of lines having a width of 140 nm disposed at equal intervals (pitch: 280 nm) was formed in the same manner as that described in [Step (1)].

Subsequently, using an ArF exposure apparatus NSR-S302A (manufactured by Nikon Corporation, NA (numerical aperture)=0.60, ⅔ annular illumination), the entire surface of the LS pattern was irradiated with an ArF excimer laser (193 nm) without using a photomask (irradiation dose: 5 mJ/cm²).

### Example 5

[Step (I-1)]

An LS pattern composed of lines having a width of 140 nm disposed at equal intervals (pitch: 280 nm) was formed in the same manner as that described above in [Step (1)].

[Step (I-2)]

Subsequently, using the coating apparatus described above (product name: Clean Track Act8, manufactured by Tokyo Electron Co., Ltd.), the pattern miniaturization agent of the example 1 was spin-coated onto the LS pattern.

[Step (I-3)]

The LS pattern having the pattern miniaturization agent of the example 1 coated thereon was subjected to a bake treatment at 130° C. for 60 seconds.

[Step (I-4)]

Following the bake treatment, the LS pattern was subjected to alkali developing for 30 seconds at 23° C. in a 2.38% by weight aqueous solution of tetramethylammonium hydroxide (TMAH) (NMD-3, a product name, manufactured by Tokyo Ohka Kogyo Co., Ltd.), and was then rinsed for 30 seconds in pure water and shaken dry.

### Example 6

With the exception of using the pattern miniaturization agent of the example 2 instead of the pattern miniaturization agent of the example 1, resist pattern miniaturization was performed in the same manner as that described for the example 5.

### Example 7

[Step (II-1)]

An LS pattern composed of lines having a width of 140 nm disposed at equal intervals (pitch: 280 nm) was formed in the same manner as that described in [Step (1)].

[Step (II-2)]

Subsequently, using the coating apparatus described above (product name: Clean Track Act8, manufactured by Tokyo Electron Co., Ltd.), the pattern miniaturization agent of the example 3 was spin-coated onto the LS pattern, and was then subjected to a prebake (PAB) treatment on a hotplate at 80° C. for 60 seconds.

[Step (II-5)]

Subsequently, using an ArF exposure apparatus NSR-S302A (manufactured by Nikon Corporation, NA (numerical aperture)=0.60, ⅔ annular illumination), the LS pattern that had been subjected to the PAB treatment was selectively irradiated with an ArF excimer laser (193 nm) through a photomask (6% halftone) targeting a line and space resist pattern (hereafter referred to as an “LS pattern”) having a line width of 140 nm and a pitch of 280 nm.

[Step (II-3)]

Following irradiation with the ArF excimer laser (193 nm), the LS pattern was subjected to a PEB treatment at 100° C. for 60 seconds.

[Step (II-4)]

Following the PEB treatment, the LS pattern was subjected to alkali developing for 30 seconds at 23° C. in a 2.38% by weight aqueous solution of tetramethylammonium hydroxide (TMAH) (NMD-3, a product name, manufactured by Tokyo Ohka Kogyo Co., Ltd.), and was then rinsed for 30 seconds in pure water and shaken dry.

### Example 8

With the exception of performing the irradiation in the step (II-5) without using the photomask (6% halftone), resist pattern miniaturization was performed in the same manner as that described for the example 7.

### Example 9

With the exception of using the pattern miniaturization agent of the example 4 instead of the pattern miniaturization agent of the example 3, resist pattern miniaturization was performed in the same manner as that described for the example 7.

### <Evaluations>

For each of the LS patterns formed by resist pattern miniaturization in the above examples, the sensitivity during LS pattern formation, the thickness loss within the formed LS pattern, the slimming rate, the line width roughness (LWR), pattern collapse, the resist pattern shape, and the resolution were each evaluated. The results of these evaluations are shown in Table 2 and Table 3.

### [Sensitivity]

The optimum exposure dose (EOP, mJ/cm²) for formation of the LS pattern in each example was determined as an indicator of the sensitivity.

### [Thickness Loss]

The thickness of the LS pattern formed in each example was measured using a Nanospec 6100A (manufactured by Nanometrics Incorporated).

This measured thickness was then compared with the thickness of the LS pattern formed in the comparative example 1. When the measured thickness was thinner than that of the LS pattern formed in the comparative example 1, the thickness loss was recorded as a negative value (−), whereas when the thickness was greater, the thickness loss was recorded as a positive value (+).

### [Slimming Rate]

The line width at a prescribed position in the LS pattern formed in each example was measured using a measuring SEM (scanning electron microscope, accelerating voltage: 800 V, product name: S-9220, manufactured by Hitachi, Ltd.).

Then, the change (slimming rate) relative to the line width of the LS pattern formed in the comparative example 1 was calculated based on the following equation.

Slimming rate (%)=(line width in comparative example 1−line width in example)/line width in comparative example 1×100

A larger value for this slimming rate indicates the formation of a line of narrower dimensions compared with the line width of the LS pattern formed in the comparative example 1, meaning miniaturization of the resist pattern has been achieved favorably.

### [Line Width Roughness (LWR)]

For the LS pattern formed in each of the examples at the aforementioned EOP value, the line width of the pattern was measured at 400 points along the lengthwise direction of the line using a measuring SEM (scanning electron microscope, accelerating voltage: 800 V, product name: S-9220, manufactured by Hitachi, Ltd.), and from these results, the value of 3 times the standard deviation (s) (namely, 3 s) was determined. The average value of 3 s determined at 5 points was calculated as an indicator of the LWR.

The smaller the value of 3 s, the lower the level of roughness in the line width, indicating an LS pattern of more uniform width.

### [Pattern Collapse]

For each example, with the exception of varying the exposure dose used in the aforementioned [Step (1)] across a range from 5 to 55 mJ/cm², LS patterns were formed in the same manner as that described above, and the line width and the exposure dose at the point immediately prior to collapse of the LS pattern were measured. The results are recorded in the table below as “Pattern collapse (nm)/exposure dose (mJ/cm²)”.

### [Resist Pattern Shape]

The LS pattern formed in each of the examples at the aforementioned EOP value was inspected using a scanning electron microscope SEM, and the cross-sectional shape of the LS pattern was evaluated.

### [Resolution]

For each example, the critical resolution at the aforementioned EOP value was evaluated using a scanning electron microscope S-9220 (manufactured by Hitachi, Ltd.).

The evaluation was performed by performing resist pattern formation at the aforementioned EOP value, and measuring the line width at the point immediately prior to pattern collapse.

TABLE 2

| | Comparative | Comparative | Comparative | Comparative | Comparative | Comparative | Comparative |
|---|---|---|---|---|---|---|---|
| | example | example | example | example | example | example | example |
| | 1 | 2 | 3 | 4 | 5 | 6 | 7 |
| EOP | 29.0 | 27.0 | 27.0 | 29.0 | Not | Not | 26.0 |
| (mJ/cm²) | | | | | resolved | resolved | |
| Thickness | 0 | −1.3 | +1.1 | −0.7 | | | −2.2 |
| loss (nm) | | | | | | | |
| Slimming | 0 | 9.18 | 6.57 | −4.5 | | | 10.2 |
| rate (%) | | | | | | | |
| LWR (nm) | 14.74 | 15.58 | 13.34 | 17.32 | | | 18.14 |
| Collapse | 105.8/34 | 98.2/35 | 93.2/35 | 105.2/36 | | | 140.1/33 |
| (nm)/ | | | | | | | |
| exposure | | | | | | | |
| dose | | | | | | | |
| (mJ/cm²) | | | | | | | |
| Resist | inverse | inverse | inverse | inverse | | | inverse |
| pattern | taper | taper | taper | taper | | | taper |
| shape | | | | | | | |
| Critical | 130 | 130 | 130 | 130 | | | 130 |
| resolution | | | | | | | |
| (nm) | | | | | | | |

TABLE 3

| | Exam- | Exam- | Exam- | Exam- | Exam- |
|---|---|---|---|---|---|
| | ple 1 | ple 2 | ple 3 | ple 4 | ple 5 |
| EOP (mJ/cm²) | 24.0 | 20.0 | 22.0 | 22.0 | 23.0 |
| Thickness loss (nm) | −0.8 | −1.3 | −2.3 | −1.9 | −2.1 |
| Slimming rate (%) | 37.4 | 49.2 | 37.0 | 40.2 | 85.0 |
| LWR (nm) | 12.18 | 13.20 | 9.60 | 10.81 | 10.82 |
| Collapse (nm)/expo- | 60.5/35 | 69.7/26 | 64.4/33 | 62.8/33 | 127.1/24 |
| sure dose (mJ/cm²) | | | | | |
| Resist pattern shape | rectan- | rectan- | rectan- | rectan- | rectan- |
| | gular | gular | gular | gular | gular |
| Critical resolution | 130 | 130 | 130 | 130 | 130 |
| (nm) | | | | | |

The comparative examples 2 to 4 and 7 were performed for the purpose of confirming the effects on the resist pattern of the operations of alkali developing, baking and exposure respectively.

From the results shown in Tables 2 and 3, it is evident that in the examples 1 to 5, the effect of the pattern miniaturization agent resulted in an increase in the slimming rate.

Further, it was also confirmed that, compared with the LS patterns of the comparative examples, the final LS patterns obtained in the examples 1 to 5 exhibited smaller LWR values, narrower line widths immediately prior to collapse of the LS pattern, and superior rectangularity of the resist pattern shape.

Accordingly, it was found that by employing the resist pattern formation method of the present invention, the resist pattern was able to be miniaturized favorably, and a resist pattern having finer dimensions and a superior shape was able to be formed.

In each of the comparative examples 5 and 6, the final resist pattern was not able to be resolved.

Although the reasons for these results are not entirely clear, the pattern miniaturization agents used in the comparative examples 5 and 6 each contained an acidic compound (methanesulfonic acid and methacrylic acid respectively), and therefore from the time when the pattern miniaturization agent was applied to the resist pattern, the resist pattern was in contact with an acid, and thus prone to pattern loss. In contrast, in the case of the pattern miniaturization agents used in the examples 1 and 2 and the pattern miniaturization agents used in the examples 3 to 5, the bake treatment in the step (I-3) or the exposure treatment in the step (II-5) respectively resulted in the generation of acid from the acid generator, thus causing contact of the resist pattern with an acid. It is thought that because of this difference, in the comparative examples 5 and 6, the resist pattern was prone to pattern loss (particularly in the vicinity of the interface with the substrate), the resist pattern was more likely to detach from the silicon substrate, and the resist pattern underwent collapse, making it impossible to resolve the pattern.

1. A resist pattern formation method comprising:
(1) forming a resist pattern on a support using a chemically amplified positive-type resist composition;
(2) applying a pattern miniaturization agent to the resist pattern;
(3) performing a bake treatment of the resist pattern to which the pattern miniaturization agent has been applied; and
(4) subjecting the resist pattern that has undergone the bake treatment to alkali developing, wherein
the pattern miniaturization agent comprises an acid generator component, and an organic solvent that does not dissolve the resist pattern formed in (1).

2. The resist pattern formation method according to claim 1, wherein
a temperature in the bake treatment of the step (3) is 130° C. or higher, and
the acid generator component comprises a component that generates acid upon heating at 130° C. or higher.

3. The resist pattern formation method according to claim 1,
further comprising between (2) and (3):
(5) conducting exposure of the resist pattern to which the pattern miniaturization agent has been applied, wherein
the acid generator component comprises a component that generates acid upon exposure.

4. The resist pattern formation method according to claim 1,
wherein
the organic solvent that does not dissolve the resist pattern formed in (1) is at least one organic solvent selected from the group consisting of alcohol-based organic solvents, fluorine-based organic solvents, and ether-based organic solvents not having a hydroxyl group.

5. The resist pattern formation method according to claim 1, wherein
the chemically amplified positive-type resist composition comprises a resin component having a structural unit (a1), which is derived from an acrylate ester in which an atom other than a hydrogen atom or a substituent may be bonded to a carbon atom on an α-position, and contains an acid-dissociable, dissolution-inhibiting group.

6. A pattern miniaturization agent, which is used in the resist pattern formation method according to claim 1, and comprises an acid generator component, and an
organic solvent that does not dissolve the resist pattern formed in (1).
